(19) United States
(12) Patent Application Publication
(10) Pub. No.: US 2024/0077798 A1
(43) Pub. Date: Mar. 7, 2024

(54) EUVL PRECISION COMPONENT WITH SPECIFIC THERMAL EXPANSION BEHAVIOR

(71) Applicant: Schott AG, Mainz (DE)

(72) Inventors: Florian Kanal, Mainz (DE); Ralf Jedamzik, Griesheim (DE); Ina Mitra, Stadecken-Elsheim (DE)

(73) Assignee: Schott AG, Mainz (DE)

(21) Appl. No.: 18/468,183

(22) Filed: Sep. 15, 2023

Related U.S. Application Data
(63) Continuation of application No. PCT/EP2022/056660, filed on Mar. 15, 2022.

(30) Foreign Application Priority Data
Mar. 16, 2021 (DE) 10 2021 106 417.1
Mar. 16, 2021 (DE) 10 2021 106 419.8
Dec. 22, 2021 (DE) 10 2021 134 308.9
Mar. 15, 2022 (WO) PCT/EP2022/056660

(51) Int. Cl. G03F 1/24

(52) U.S. Cl. CPC G03F 1/24

(57) ABSTRACT

A precision extreme ultraviolet lithography (EUVL) component having an average coefficient of thermal expansion (CTE) in a range from 0 to 50° C. of at most 0±0.1×10⁻⁶/K, and a thermal hysteresis of <0.1 ppm at least in the temperature range from 19 to 25° C., and an index F of <1.2. F=TCL (0; 50° C.)/|expansion (0; 50° C)|, where TCL is a total change of length.

### CROSS REFERENCE TO RELATED APPLICATIONS

This is a continuation of International Patent Application No. PCT/EP2022/056660 filed on Mar. 15, 2022, which is incorporated in its entirety herein by reference. International Patent Application No. PCT/EP2022/056660 claims priority to German Patent Application No. 10 2021 134 308.9 filed on Dec. 22, 2021, which is incorporated in its entirety herein by reference. International Patent Application No. PCT/EP2022/056660 also claims priority to German Patent Application No. 10 2021 106 419.8 filed on Mar. 16, 2021, which is incorporated in its entirety herein by reference. International Patent Application No. PCT/EP2022/056660 also claims priority to German Patent Application No. 10 2021 106 417.1 filed on Mar. 16, 2021, which is incorporated in its entirety herein by reference.

### BACKGROUND OF THE INVENTION

### 1. Field of the Invention

The present invention relates to a precision EUVL component featuring specific thermal expansion characteristics.

### 2. Description of the Related Art

EUV lithography (also called EUVL hereinafter) is a photolithography process utilizing electromagnetic radiation between typically 5 nm and 50 nm (soft x-ray radiation), more particularly electromagnetic radiation having a wavelength of 13.5 nm (91.82 eV). This is the so-called extreme ultraviolet radiation (EUV). This region of the electromagnetic spectrum is absorbed completely by virtually all materials. In contrast to DUV lithography (deep ultraviolet, for example 248 nm and/or 193 nm), therefore, it is not possible to use optically transparent photomasks; instead, reflective multilayer stack systems have to be used, on a photomask substrate of low thermal expansion (also called reticle substrate or mask substrate or reticle mask blank or photomask blank or mask blank or substrate hereinafter) as photomasks (also called reticles, reticle masks, photomasks or masks hereinafter). A disadvantage when using reflective photomasks, however, is the comparatively poor maximum reflectivity of the multilayer stack in the EUV radiation range, of typically less than 70%. The radiation that the photomask does not reflect, is absorbed by the the photomask and conducted in the form of heat into the photomask substrate and also, where relevant, into the photomask carrier (also called reticle carrier or mask carrier or reticle stage or photomask stage or mask stage hereinafter), possibly raising the temperature thereof, especially with increasing irradiation time.

Even slight thermally induced deformations in the photomask, however, can lead to imaging errors on the illuminated wafer and hence to yield losses during chip production. To prevent the described local deformations or distortions in the photomask substrate, therefore, it is necessary, for photomask substrates, to use materials of low thermal expansion or of low CTE (coefficient of thermal expansion).

This is all the more important because the average power of the EUV beam sources used in EUV lithography will increase in future in order to boost the throughput, via higher repetition rates and/or higher individual pulse energies, for example, with a consequent increase in the thermal load on the photomask and also, where relevant, on the photomask carrier. As a result, active cooling concepts for the photomask and for the photomask carrier will gain in importance, possibly leading to further temperature changes particularly in the photomask and the photomask carrier. In this context, it must also be borne in mind that the thermal load on the photomask and/or photomask carrier is not constant, but may instead fluctuate due to a variety of factors. These factors include temporally nonuniform illumination times, resulting, for example, from the loading of the photomask carrier with a new photomask or from downtimes due to faltering operations. The stated thermally induced deformations may be compensated in part by compensation mechanisms within the overall optical system of an EUVL lithography unit, such as in the beam shaping of the illumination, for example; however, this compensation is limited, and it is therefore useful to minimize the individual contributions to (imaging) errors. Here it is necessary to consider not only thermally induced deformations of the material during illumination, but also the thermal characteristics over time (thermal hysteresis). Materials having comparatively high thermal hysteresis, however, hinder the stated compensation and hence also the prevention of unwanted thermal imaging errors on the part of the photomask.

Further precision EUVL components with exacting requirements in terms of their thermal properties are, in particular, EUVL mirrors in the optical system of the EUVL apparatus, and also wafer carriers (also called wafer stages hereinafter) onto which the (Si-) wafers are placed for exposure.

Materials and precision components featuring low thermal expansion or low CTE (coefficient of thermal expansion) are already known in the prior art.

Known materials for precision components featuring low thermal expansion in the temperature range around room temperature are ceramics, Ti-doped quartz glass, and glass-ceramics. Glass-ceramics featuring low thermal expansion are, in particular, lithium aluminum silicate glass-ceramics (LAS glass-ceramics), which are described, for example, in U.S. Pat. Nos. 4,851,372, 5,591,682, EP 587979 A, U.S. Pat. Nos. 7,226,881, 7,645,714, DE 102004008824 A, and DE 102018111144 A. Further materials for precision components are cordierite ceramics or cordierite glass-ceramics.

Such materials are frequently used for precision components that are required to meet particularly stringent requirements in relation to their properties (e.g., mechanical, physical, optical properties). They are employed especially in terrestrial and space-based astronomy and Earth observation, LCD lithography, microlithography and EUV lithography, metrology, spectroscopy, and measurement technology. A requirement here is that the components, according to specific application, have extremely low thermal expansion, in particular.

In general, the thermal expansion of a material is determined by a static method in which the length of a test specimen is determined at the start and at the end of the specific temperature interval, and the difference in length is used to calculate the average expansion coefficient α or CTE (coefficient of thermal expansion). The CTE is then reported as the average for this temperature interval—for example, for the temperature interval from 0° C. to 50° C., as CTE(0;50) or α(0;50).

To meet the constantly rising requirements, materials have been developed that have a CTE better matched to the field of use of a component formed from the material. For example, the average CTE may be optimized not just for the standard temperature interval CTE(0;50) but also, for example, for a temperature interval around the actual application temperature, as for example the interval from 19° C. to 25° C., i.e. CTE(19;25) for particular lithography applications such as EUV lithography. As well as determining the average CTE, it is possible to determine the thermal expansion of a test specimen in very small temperature intervals as well and so to represent it as a CTE-T curve. A CTE-T curve of this kind may preferably have a zero crossing at one or more temperatures, optionally at or close to the planned application temperature. At a zero crossing of this CTE-T curve, the relative change in length with changing temperature is particularly small. For certain glass-ceramics, such a zero crossing of the CTE-T curve may be shifted to the application temperature of the component by suitable temperature treatment. As well as the absolute CTE value, the slope of the CTE-T curve around the application temperature ought also to be at a minimum in order to produce a minimal change in length of the component in the event of slight temperature changes. The above-described optimizations of the CTE or of the thermal expansion, in the case of these specific zero-expansion glass-ceramics, take place in general by variation of the ceramization conditions, for constant composition.

An adverse effect in the case of the known precision components and materials, especially the glass-ceramics such as LAS glass-ceramics, is the “thermal hysteresis”, called “hysteresis” hereinafter for short. Hysteresis here means that the change in length of a test specimen on heating at constant heating rate differs from the change in length of the test specimen on subsequent cooling at constant cooling rate, even if the magnitude of cooling rate and heating rate is the same. If the change in length is represented as a graph as a function of the temperature for heating or cooling, the result is a classic hysteresis loop. The shaping of the hysteresis loop here is dependent on factors including the rate of temperature change. The faster the change in temperature, the more marked the hysteresis effect. The hysteresis effect makes it clear that the thermal expansion of an LAS glass-ceramic is dependent on temperature and on time, i.e., for example, on the rate of temperature change; this has also already been described in isolated cases in the specialist literature, as for example O. Lindig and W. Pannhorst, “Thermal expansion and length stability of ZERODUR® in dependence on temperature and time”, APPLIED OPTICS, Vol. 24, No. 20, October 1985; R. Haug et al., “Length variation in ZERODUR® M in the temperature range from −60° C. to +100° C.”, APPLIED OPTICS, Vol. 28, No.19, October 1989; R. Jedamzik et al., “Modeling of the thermal expansion behavior of ZERODUR® at arbitrary temperature profiles”, Proc. SPIE Vol. 7739, 2010; D. B. Hall, “Dimensional stability tests over time and temperature for several low—expansion glass ceramics”, APPLIED OPTICS, Vol. 35, No. 10, April 1996.

Since the change in length of a glass-ceramic exhibiting thermal hysteresis is delayed or advanced with respect to the change in temperature, the material, or a precision component manufactured from it, exhibits a disruptive isothermal change in length, meaning that, after a change in temperature, a change in length of the material occurs even at the time when the temperature is already being held constant (called “isothermal hold”), until a stable state is attained. If the material is subsequently again heated and cooled, the same effect occurs again.

With the LAS glass-ceramics known to date, in spite of variation of the ceramization conditions with consistent composition, it has not been possible to eliminate the thermal hysteresis effect without detriment to other properties.

In relation to the properties of materials, especially glass-ceramics, for use in precision components, especially precision EUVL components, a temperature range from 0° C. to 50° C., especially from 10° C. to 35° C. or from 10° C. to 25° C. or from 19° C. to 25° C., is frequently relevant, with a temperature of 22° C. being referred to generally as room temperature. Given that many applications of precision components take place in the temperature range from greater than 0° C. to room temperature, materials having thermal hysteresis effects and isothermal change in length are disadvantageous, since there may be optical faults and imaging errors in the case, for example, of optical components such as EUVL photomasks, EUVL photomask carriers, lithography mirrors or EUVL minors, EUVL wafer carriers, and astronomical or space-based mirrors. With other precision components made from glass-ceramic that are employed in measurement technology (e.g., precision rules, reference plates in interferometers), this may cause inaccuracies in measurement.

Certain known materials such as ceramics, Ti-doped quartz glass, and particular glass-ceramics feature an average coefficient of thermal expansion CTE (0;50) of 0±0.1×10⁻⁶/K (corresponding to 0±0.1 ppm/K). Materials having such a low average CTE in the stated temperature range are referred to as zero-expansion materials in the context of this invention. However, glass-ceramics, especially LAS glass-ceramics, whose average CTE is thus optimized generally have a thermal hysteresis in the temperature range of 10° C. to 35° C. In other words, specifically in applications around room temperature such as EUV lithography (i.e., 22° C.), a disruptive hysteresis effect occurs with these materials, which impairs the accuracy of precision components produced with such a material. Therefore, a glass-ceramic material was developed (see U.S. Pat. No. 4,851,372) that exhibits no significant hysteresis at room temperature; however, rather than being eliminated, the effect is merely shifted to lower temperatures, and so this glass-ceramic at temperatures of 10° C. and below exhibits a marked hysteresis, which can likewise still be disruptive. This may become all the more relevant if, for example, owing to the increase in the power in EUVL applications, it may be necessary to carry out cooling to temperatures of less than room temperature, as for example to around 10° C., around 12° C., around 14° C., around 16° C. or 18° C., of certain precision EUVL components, examples being photomask carriers or photomasks. The cooling of EUVL photomasks and/or photomasks carriers is described for example in EP 1411391 A2, US 2015/0241796 A1, and US 20212/0026474 A1. To characterize the thermal hysteresis of a material in a particular temperature range, therefore, in this invention the thermal characteristics of the materials are considered for different temperature points within this range. There are even glass-ceramics which at 22° C. and at 5° C. exhibit no significant hysteresis; however, these glass-ceramics have an average CTE (0;50) of >0±0.1 ppm/K, and are therefore not zero-expansion glass-ceramics in the sense of the definition stated above.

A further requirement imposed on a glass-ceramic material is for good meltability of the glass components and also for easy melt guiding and homogenization of the underlying glass melt in industrial-scale production plants, in order—on completion of ceramization of the glass—to meet the exacting requirements on the glass-ceramic or a precision component comprising the glass-ceramic in respect of CTE homogeneity, internal quality—in particular, a low number of inclusions (especially bubbles), low level of streaks—and polishability, etc.

What is needed in the art is a way to provide a precision EUVL component and also a glass-ceramic which in particular at the application temperatures prevailing in EUV lithography, more particularly at least in a temperature range from 19° C. to 25° C., optionally at least in a temperature range from 10° C. to 25° C., optionally at least in a temperature range from 10° C. to 35° C., optionally at or around 22° C., exhibit improved thermal characteristics in relation, for example, to their thermal expansion characteristics and/or their thermal hysteresis, and/or their CTE homogeneity. What is also needed in the art is a way to provide a precision EUVL component—also called precision component herein—featuring improved expansion characteristics. What is also needed in the art is a way to provide a glass-ceramic which can be produced industrially and has zero expansion and reduced thermal hysteresis, optionally at least in the temperature range from 19 to 25° C., optionally at least in the temperature range from 10° C. to 25° C., and optionally at least in the temperature range from 10° C. to 35° C., particularly for a precision EUVL component. What is also needed in the art is a way to provide a glass-ceramic which can be produced industrially and has zero expansion and reduced thermal hysteresis more particularly at least in the temperature range from 19 to 25° C., optionally at least in the temperature range from 10° C. to 25° C., and optionally at least in the temperature range from 10° C. to 35° C., particularly for a precision EUVL component.

### SUMMARY OF THE INVENTION

According to some aspects, the invention relates to a precision EUVL component

having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an index F of <1.2, where F=TCL (0; 50° C.)/|expansion (0; 50° C.)|.

According to some aspects, the invention relates to a precision EUVL component having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an alternative index f_{T.i.} selected from the group consisting of alternative index f_{(20;40)}<0.024 ppm/K, alternative index f_{(20;70)}<0.039 ppm/K and alternative index f_{(-10;30)}<0.015 ppm/K, optionally an alternative index f_{(20;40)}<0.024 ppm/K.

According to some aspects, the invention relates to a precision EUVL component having an average coefficient of thermal expansion CTE in the range from 0 to 50° C. of at most 0 ±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an index F of <1.2, where F=TCL (0; 50° C.)/|expansion (0; 50° C.)|, and at least one inorganic material selected from the group consisting of doped quartz glass, glass-ceramic and ceramic, optionally Ti-doped quartz glass, LAS glass-ceramic and cordierite.

According to some aspects, the invention relates to a precision EUVL component having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an alternative index f_{T.i.} selected from the group consisting of alternative index f_{(20;40)}<0.024 ppm/K, alternative index f_{(20;70)}<0.039 ppm/K and alternative index f_{(-10;30)}<0.015 ppm/K, optionally an alternative index f_{(20;40)}<0.024 ppm/K, and comprising at least one inorganic material selected from the group consisting of doped quartz glass, glass-ceramic and ceramic, optionally Ti-doped quartz glass, LAS glass-ceramic and cordierite.

According to some aspects, the invention relates to a precision EUVL component having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an index F of <1.2, where F=TCL (0; 50° C.)/|expansion (0; 50° C.)|, wherein the precision component comprises an LAS glass-ceramic provided according to the invention.

According to some aspects, the invention relates to a precision EUVL component having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an alternative index f_{T.i.} selected from the group consisting of alternative index f_{(20;40)}<0.024 ppm/K, alternative index f_{(20;70)}<0.039 ppm/K and alternative index f_{(-10;30)}<0.015 ppm/K, optionally an alternative index f_{(20;40)}<0.024 ppm/K, wherein the precision component comprises an LAS glass-ceramic provided according to the invention.

According to some aspects, the invention relates to a precision EUVL component provided according to the invention which is selected from the group consisting of photomasks or reticles, photomask substrates or reticle mask blanks or mask blanks, photomask carriers or reticle stages, mirrors, mirror carriers and wafer carriers or wafer stages, more particularly to a photomask or reticle, and/or a photomask substrate or reticle mask blank or mask blank and/or a photomask carrier or reticle stage.

According to some aspects, the invention relates to a substrate for an EUV (micro)lithography mirror (also called “EUVL mirror”) comprising a precision component provided according to the invention.

According to some aspects, the invention relates to a substrate for an EUV photomask (also called “(EUVL) photomask blank” or “reticle mask blank”) comprising a precision EUVL component provided according to the invention.

According to some aspects, the invention relates to an EUV photomask carrier (also called “reticle stage”) comprising a precision EUV component provided according to the invention.

According to some aspects, the invention relates to a substrate for an EUVL photomask and/or an EUVL photomask carrier, comprising a precision component provided according to the invention, wherein said component has a relative change in length (dl/l₀) of ≤|0.10| ppm, optionally of ≤|0.09| ppm, optionally of ≤|0.08| ppm and optionally of ≤|0.07| ppm in the temperature range from 20° C. to 30° C. and/or a relative change in length (dl/l₀) of ≤|0.17| ppm, optionally of ≤|0.15| ppm, optionally of ≤|0.131ppm and optionally of ≤|0.11| ppm in the temperature range from 20° C. to 35° C. and/or wherein it has a relative change in length (dl/l₀) of ≤|0.30| ppm, optionally of ≤|0.25| ppm, optionally of ≤|0.20| ppm and optionally of ≤|0.15| ppm in the temperature range from 20° C. to 40° C.

According to some aspects of the invention, an LAS glass-ceramic is provided, especially for a precision EUVL component provided according to the invention, which has an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C. and which comprises the following components (in mol % based on oxide):

| | |
|---|---|
| SiO₂ | 60-71 |
| Li₂O | 7-9.4 |
| MgO + ZnO | 0-<0.6, |

at least one component selected from the group consisting of P₂O₅, R₂O, where R₂O may be Na₂O and/or K₂O and/or Cs₂O and/or Rb₂O, and RO, where RO may be CaO and/or BaO and/or SrO,
   nucleating agent with a content of 1.5 to 6 mol %, where nucleating agent is at least one component selected from the group consisting of TiO₂, ZrO₂, Ta₂O₅, Nb₂O₅, SnO₂, MoO₃ and WO₃.

### BRIEF DESCRIPTION OF THE DRAWINGS

The above-mentioned and other features and advantages of this invention, and the manner of attaining them, will become more apparent and the invention will be better understood by reference to the following description of embodiments of the invention taken in conjunction with the accompanying drawings, wherein:

FIG. 1 shows CTE-T curves of materials known from the prior art that have low thermal lengthwise expansion, for precision components, for example;

FIG. 2 shows the hysteresis characteristics of three glass-ceramic samples ascertained by the same method also used in the present invention, which diagram comes from R. Jedamzik et al., “Modeling of the thermal expansion behavior of ZERODUR® at arbitrary temperature profiles”, Proc. SPIE Vol. 7739, 2010;

FIGS. 3 to 8 show hysteresis curves of known materials of glass-ceramics which can be used for producing known precision components and which have a thermal hysteresis at least in the temperature range of 10-35° C. of >0.1 ppm (dashed=cooling curve, dotted=heating curve);

FIG. 9 shows the hysteresis curve (dashed =cooling curve, dotted =heating curve) of a prior art glass-ceramic which can be used for producing a precision component and which has a thermal hysteresis at least in the temperature range of 10-35° C. of <0.1 ppm, but the steep curve profile shows that the glass-ceramic does not have zero expansion;

FIGS. 10 and 11 show hysteresis curves of precision components provided according to the invention or glass-ceramics provided according to the invention (compositions according to Ex. 6 and 7 in Table 1a) which have a thermal hysteresis at least in the temperature range of 10-35° C. of <0.1 ppm (dashed=cooling curve, dotted=heating curve);

FIGS. 12 and 13 show normalized Δl/l₀-T curves (also called dl/lo curves) of precision components provided according to the invention and glass-ceramics (compositions according to Ex. 6 and 7 in Table 1a) and reference lines for ascertaining the index F as a measure of the flatness of the expansion curve in the temperature range from 0° C. to 50° C.;

FIGS. 14 to 17 show normalized Δl/l₀-T curves of known materials which can be used for producing known precision components, and reference lines for ascertaining the index F as a measure of the flatness of the expansion curve in the temperature ranges from −20° C. or −10° C. to 70° C. or 80° C.;

FIG. 18 shows normalized Δl/l₀-T curves of the precision components or glass-ceramics of FIGS. 12 and 13 in the temperature range from −30° C. to +70° C.;

FIG. 19 shows normalized Δl/l₀-T curves of known materials in the temperature range from −30° C. to +70° C.;

FIGS. 20 and 21 show that the CTE-T curves of precision components or glass-ceramics of FIGS. 12 and 13 advantageously have a CTE plateau;

FIGS. 22 and 23 show the slopes of CTE-T curves from FIGS. 24 and 25;

FIGS. 24 and 25 show different CTE profiles, established by different ceramization parameters, for two composition examples provided according to the invention;

FIGS. 26 shows the slope of a CTE-T curve of a precision component or glass-ceramic, the glass-ceramic having a composition according to Ex. 17 in Table 1a;

FIG. 27 shows a normalized Δl/l₀-T curve of a precision component provided according to the invention or glass-ceramic (composition according to Ex. 17 in Table 1a) and reference lines for ascertaining the alternative index f_{(20;40)} as a measure of the flatness of the expansion curve in the temperature range from 20° C. to 40° C.;

FIG. 28 shows a normalized Δl/l₀-T curve of the precision component or glass-ceramic of FIG. 13 and reference lines for ascertaining the alternative index f_{(-10;30)} as a measure of the flatness of the expansion curve in the temperature range from −10° C. to 30° C.;

FIG. 29 shows a normalized Δl/l₀-T curve of the precision component or glass-ceramic of FIG. 13 and reference lines for ascertaining the alternative index f_{(20;70)} as a measure of the flatness of the expansion curve in the temperature range from 20° C. to 70° C.;

FIG. 30 shows a normalized Δl/l₀-T curve of a precision component provided according to the invention or glass-ceramic (composition according to Ex. 14 in Table 1a) and reference lines for ascertaining the alternative index f_{(-10;30)} as a measure of the flatness of the expansion curve in the temperature range from −10° C. to 30° C.;

FIGS. 31 to 33 show hysteresis curves of precision components provided according to the invention or glass-ceramics provided according to the invention (compositions according to Ex. 2b, Ex. 6b and Ex. 7b in Table 1b), having a thermal hysteresis at least in the temperature range of 10-35° C. of <0.1 ppm (dashed=cooling curve, dotted=heating curve);

FIG. 34 shows a normalized Δl/l₀-T curve (also called dl/l₀ curves) of a precision component provided according to the invention or glass-ceramic (composition according to Ex. 7b in Table 1b) and reference lines for ascertaining the index F as a measure of the flatness of the expansion curve in the temperature range from 0° C. to 50° C.;

FIG. 35 shows another normalized Δl/l₀-T curve of a precision component provided according to the invention or glass-ceramic (composition according to Ex. 7b in Table 1b) based on a different ceramization, and reference lines for ascertaining the alternative index f_{(20;70)} as a measure of the flatness of the expansion curve in the temperature range from 20° C. to 70° C.;

FIG. 36 shows a normalized Δl/l₀-T curve (also called dl/l₀ curves) of a precision component provided according to the invention or glass-ceramic (composition according to Ex. 6b in Table 1b) and reference lines for ascertaining the alternative index f_{(-10;30)} as a measure of the flatness of the expansion curve in the temperature range from −10° C. to 30° C.;

FIGS. 37, 39 and 41 show that the CTE-T curves of precision components or glass-ceramics (compositions according to Ex. 6b, Ex. 7b and Ex. 9b in Table 1b) which can be used for producing precision EUVL components that advantageously have a CTE “plateau”;

FIGS. 38 and 40 show details from FIGS. 37 and 39, respectively;

FIGS. 42 and 43 show slopes of CTE-T curves of precision components or glass-ceramics having compositions according to Ex. 6b and Ex. 7b in Table 1b; and

FIGS. 44 and 45 show different expansion curves, established by different ceramization parameters, for precision components or glass-ceramics having compositions according to Ex. 6b and Ex. 7b in Table 1b;

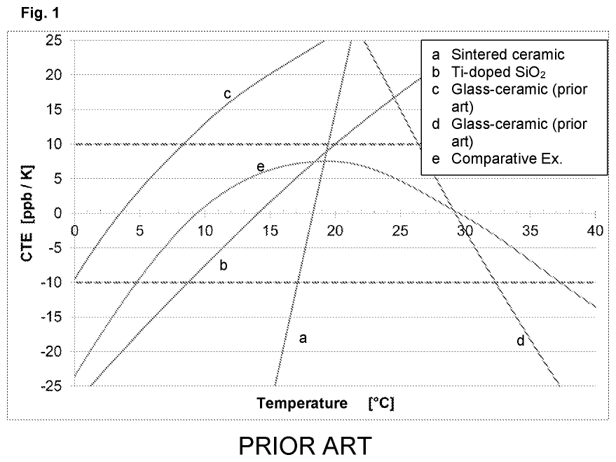

Corresponding reference characters indicate corresponding parts throughout the several views. The exemplifications set out herein illustrate embodiments of the invention and such exemplifications are not to be construed as limiting the scope of the invention in any manner.

### DETAILED DESCRIPTION OF THE INVENTION

Described first is the precision EUVL component provided according to the invention

and its properties, and subsequently an LAS glass-ceramic provided according to the invention which can be used in particular for producing a precision EUVL component; the description of inventive and advantageous properties of the precision EUVL component is also valid correspondingly for the LAS glass-ceramic provided according to the invention (“glass-ceramic” for short below) and advantageous developments thereof.

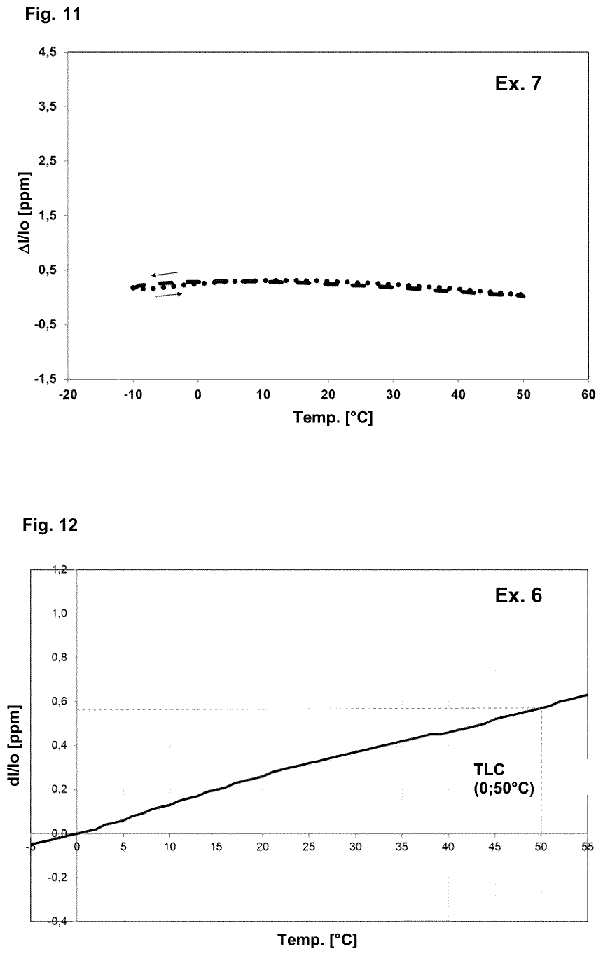

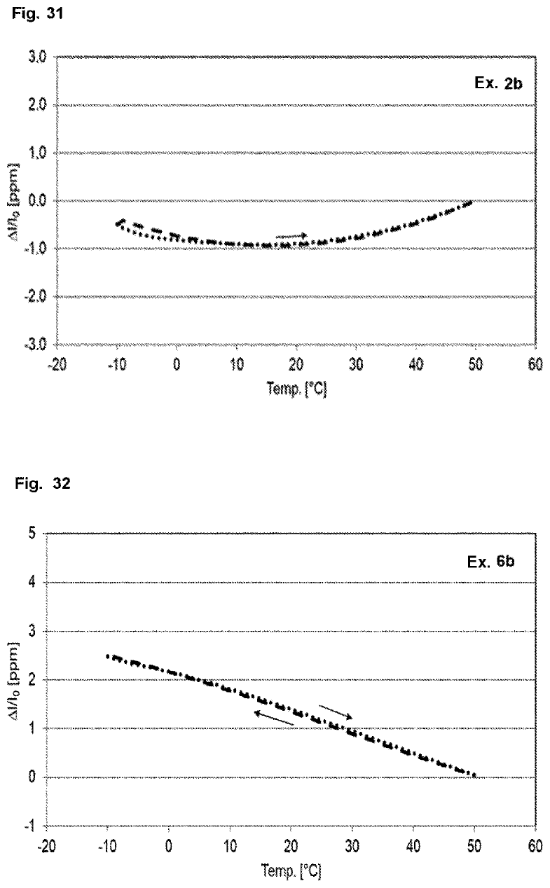

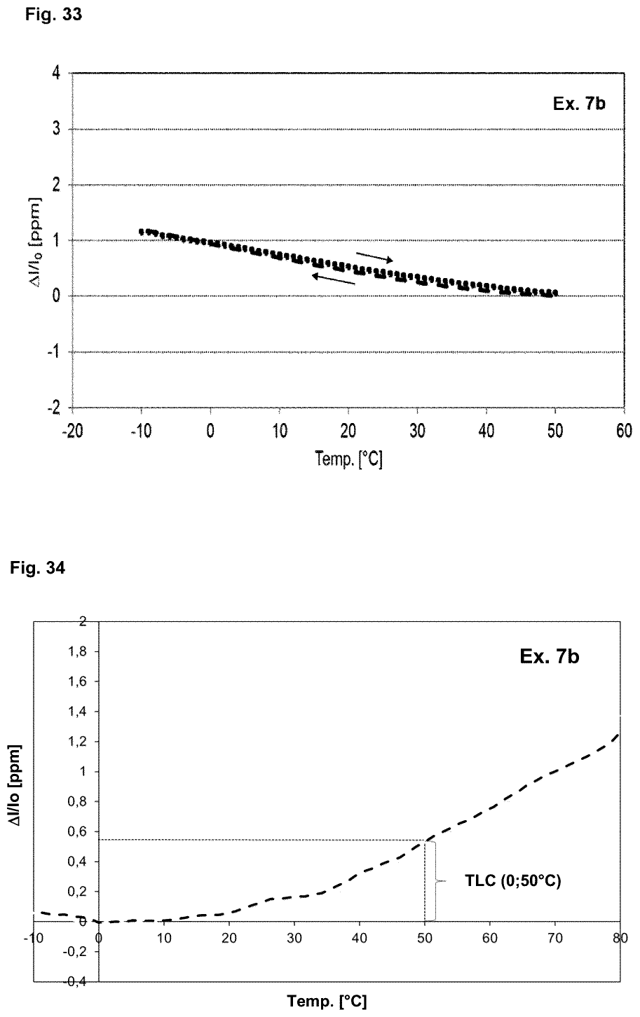

In the scope of the invention, a precision EUVL component is provided for the first time that combines a number of relevant properties: It has an average coefficient of thermal expansion CTE in the range from 0 to 50° C. of at most 0±0.1×10⁻⁶/K, i.e., it has zero expansion. Moreover, it has a thermal hysteresis of <0.1 ppm at least in the temperature range from 19 to 25° C., optionally at least in the temperature range from 10° C. to 25° C., optionally at least in the temperature range from 10° C. to 35° C., based on a heating rate and cooling rate of 36 K/h in each case, corresponding to 0.6 K/min (see FIGS. 10 and 11 and also FIGS. 31 to 33). A precision EUVL component with such a low hysteresis effect is referred to as hysteresis-free.

Corresponding precision components which have a thermal hysteresis of <0.1 ppm at least in the temperature range from 19 to 25° C., optionally at least in the temperature range from 10° C. to 25° C., and are thus hysteresis-free, may also be used advantageously in other applications, especially in applications in measurement technology that take place at or around room temperature, as for example in precision rules or positioning systems.

According to some embodiments provided according to the invention, the precision EUVL component, based on a temperature range of 0° C. to 50° C., also has an index F of <1.2, where F=TCL (0; 50° C.)/|expansion (0; 50° C.)|. In other words, in this temperature range, the expansion curve (that is, the Δl/l₀-T curve) shows a flat profile (see, for example, FIGS. 12, 13, 27 and 34).

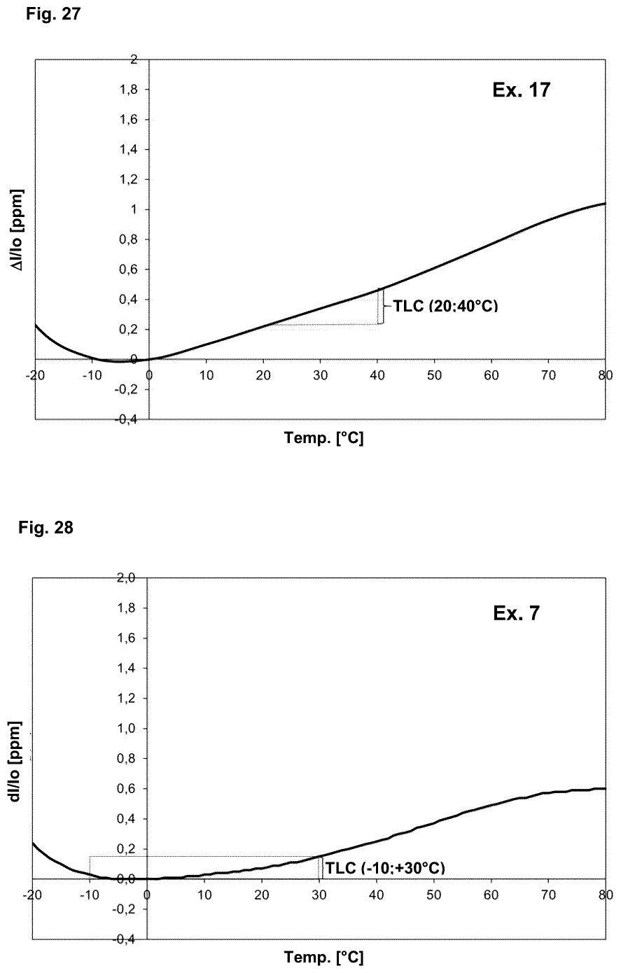

According to some embodiments provided according to the invention, the precision EUVL component also has an alternative index f_{T.i.} selected from the group consisting of alternative index f_{(20;40)}<0.024 ppm/K, alternative index f_{(20;70)}<0.039 ppm/K, and alternative index f_{(-10;30)}<0.015 ppm/K (see, for example, FIGS. 27 to 30, 35 and 36).

### CTE

The precision EUVL components and glass-ceramics provided according to the invention have zero expansion, meaning that they have an average coefficient of thermal expansion CTE in the range from 0 to 50° C. of at most 0±0.1×10⁻⁶/K. Some variants even have an average CTE in the range from 0 to 50° C. of at most 0±0.05×10⁻⁶/K. For particular applications, it may be advantageous if the average CTE within a larger temperature range, for example, in the range from −30° C. to +70° C., optionally in the range from −40° C. to +80° C., is at most 0±0.1×10⁻⁶/K, i.e., there is zero expansion.

For the determination of the CTE-T curve of the glass-ceramics and precision EUVL components provided according to the invention, and also of the comparative examples, the differential CTE(T) is determined first of all. The differential CTE(T) is determined as a function of the temperature. The CTE is then defined according to the following formula (1):

CTE (T)=(1/l₀)×(∂1/∂T) (1)

For the creation of a Δl/l₀-T curve or an expansion curve or plot of the change in length Δl/l₀-T of a test specimen (precision component or glass-ceramic) against the temperature, it is possible to measure the temperature-dependent change in length of the length of a test specimen from the starting length to at the initial temperature to to the length I t at the temperature t. Here, optionally, small temperature intervals of 5° C. or 3° C. or 1° C., for example, are chosen for determining a measurement point. Such measurements may be carried out, for example, by dilatometry methods, interferometry methods, as for example the Fabry-Perot method, i.e., the evaluation of the shift in the resonance peak of a laser beam injected into the material, or other suitable methods. In the context of the invention, the dilatometry method was chosen for ascertaining the CTE, with a temperature interval of 1° C. on rod-shaped samples of the test specimens with length 100 mm and a diameter of 6 mm.

The chosen method of determining the CTE has an accuracy of optionally at least ±0.05 ppm/K, optionally of at least ±0.03 ppm/K. The CTE may of course, however, also be determined by methods having an accuracy of at least ±0.01 ppm/K, optionally at least ±0.005 ppm/K or, according to some embodiments, even of at least ±0.003 ppm/K or at least ±0.001 ppm/K.

The Δl/l₀-T curve is used to calculate the average CTE for a particular temperature interval, as for example for the temperature range from 0° C. to 50° C.

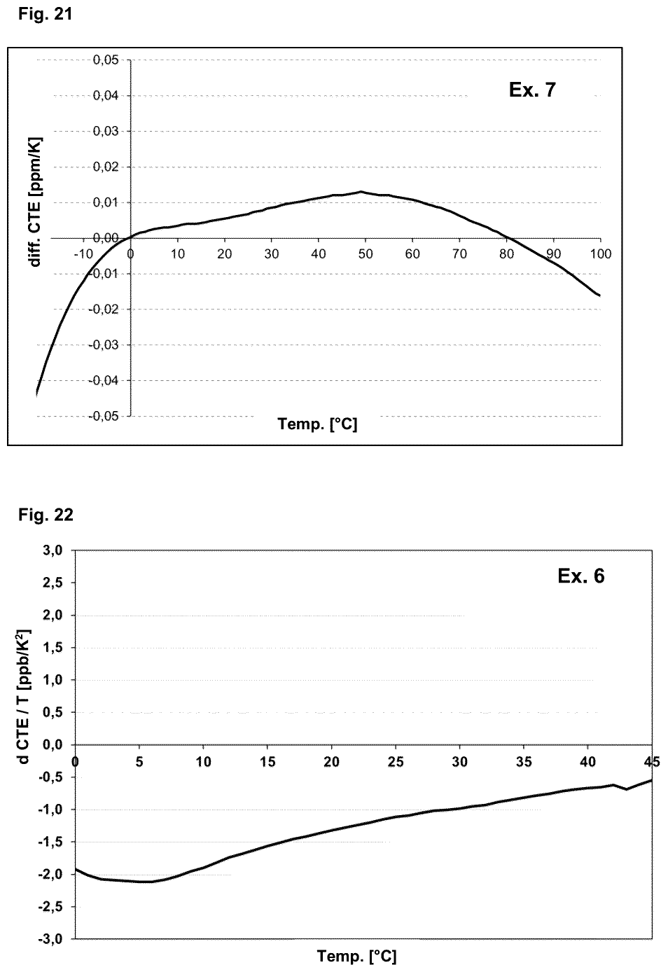

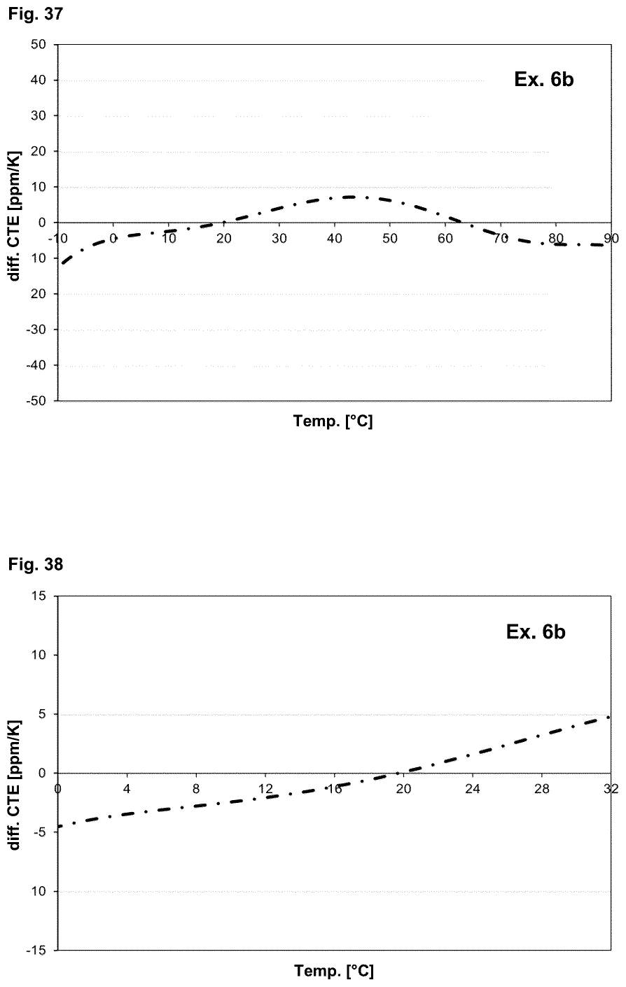

A CTE-T curve is obtained through the derivative of the Δl/l₀-T curve. The CTE-T curve can be used for determining the zero crossing, the slope of the CTE-T curve within a temperature interval. The CTE-T curve is used to determine the shaping and position of an advantageous CTE plateau which is formed in the case of some variants (see below and FIGS. 20 and 21 and also FIGS. 37, 39 and 41).

Some embodiments of the precision EUVL component have a high CTE homogeneity. The value of the CTE homogeneity (“total spatial variation of CTE”) is understood to be what is called the peak-to-valley value, i.e., the difference between the respective highest and lowest CTE values of the samples taken from a precision component.

CTE homogeneity is determined by taking a multiplicity of samples—for example, at least 5, at least 10, at least 20, at least 30, at least 40 or at least 50 samples—from different sites on a precision component and determining in each case the CTE value for a defined temperature range—for example, the CTE for the temperature range from 0° C. to 50° C. or for the temperature range from 19° C. to 25° C., which is reported in ppb/K, where 1 ppb/K=0.001×10⁻⁶/K.

The thermal expansion or CTE value of a sample taken is typically determined by the static method already stated above, in which the length of a test specimen is determined at the start and at the end of the specific temperature interval and the difference in length is used to calculate the average expansion coefficient a or CTE (coefficient of thermal expansion). The CTE is then reported as the average for this temperature interval—for example, for the temperature interval from 0° C. to 50° C., as CTE(0;50) or α(0;50), or, for the temperature interval from 19° C. to 25° C., as CTE(19;25).

The CTE homogeneity therefore relates not to the CTE of the material of the component, but rather to the spatial variation of the CTE over the section under consideration or the entire precision component. If the CTE homogeneity of a particular component is to be ascertained for multiple temperature ranges, such as for the 19° C. to 25° C. and also 0° C. to 50° C. range, for example, it is then possible generally to ascertain the CTE homogeneities for both temperature ranges on the same samples. In this case, however, it may be advantageous first to determine, on the respective sample, the CTE of the narrower temperature range, e.g., the CTE(19;25), and then to determine the CTE of the wider temperature range, e.g., the CTE(0;50). It may be advantageous, however, if CTE homogeneities of one component for different temperature ranges are ascertained on the basis of different samples of these components.

The CTE homogeneity for the temperature range from 0° C. to 50° C., i.e., the spatial variation of the CTE(0;50), is also called CTE homogeneity(0;50) below. The CTE homogeneities for other temperature ranges may be identified analogously. Thus, for example, the CTE homogeneity for the temperature range from 19° C. to 25° C., i.e., the spatial variation of the CTE(19;25), is also called CTE homogeneity(19;25) below.

In some embodiments, the precision EUVL component provided according to the invention has a CTE homogeneity(0;50) over the entire position component of at most 5 ppb/K, optionally at most 4 ppb/K, optionally at most 3 ppb/K and/or a CTE homogeneity(19;25) over the entire precision component of at most 5 ppb/K, optionally at most 4.5 ppb/K, optionally at most 4 ppb/K, optionally at most 3.5 ppb/K, optionally at most 3 ppb/K, optionally at most 2.5 ppb/K. A method for ascertaining the CTE homogeneity and measures for achieving the CTE homogeneity are described in WO 2015/124710 A, the disclosure content of which is incorporated in full into the present patent application.

### Thermal Hysteresis

The precision EUVL components and glass-ceramics for the purposes of the invention have a thermal hysteresis of <0.1 ppm at least in the temperature range from 19 to 25° C., optionally at least in the temperature range from 10° C. to 25° C., optionally at least in the temperature range from 10 to 35° C. At any temperature within the temperature interval from 19° C. to 25° C., therefore, optionally at least in the temperature range from 10° C. to 25° C., optionally at least in the temperature range from 10° C. to 35° , the glass-ceramic, after having been subjected to a change in temperature, shows an isothermal change in length of less than 0.1 ppm at subsequent constant temperature. In some embodiments, this freedom from hysteresis is present at least in a temperature range from 5° C. to 35° C., optionally at least in the temperature range from 5° C. to 45° C., optionally at least in the temperature range from >0° C. to 45° C., optionally at least in the temperature range from −5° C. to 50° C. In some embodiments, the temperature range of the freedom from hysteresis is even broader. Exemplary application temperatures are in the −60° C. to 100° C. range, optionally from −40° C. to +80° C. Some variants provided according to the present invention relate to glass-ceramics and precision EUVL components for application temperatures T_{A} for example in the 5° C. to 20° C. range or T_{A} of 22° C., 40° C., 60° C., 80° C. and 100° C., which are optionally hysteresis-free at these temperatures as well. Some variants provided according to the present invention relate to glass-ceramics and precision EUVL components for application temperatures T_{A} for example in the range from 5° C. to 40° C., optionally from 10° C. to 35° C., optionally from 10° C. to 25° C., optionally in the range from 19° C. to 25° C. or T_{A} of 22° C.

The thermal hysteresis for the precision EUVL components and glass-ceramics provided according to the invention and also for the comparative examples was determined using a precision dilatometer capable of ascertaining the CTE with a reproducibility of ±0.001 ppm/K and±0.003 ppm/K absolutely, with a temperature interval of 1° C. on rod-shaped samples of length 100 mm and a diameter of 6 mm of the test specimens (i.e., sample of the precision component or sample of the glass-ceramic), in accordance with the method and apparatus construction disclosed in DE 10 2015 113 548 A, the disclosure content of which is incorporated in full into the present patent application. For each sample analyzed, the change in length Δl/l₀ was determined as a function of the temperature between 50° C., cooling at a cooling rate of 36 K/h, to −10° C. After an isothermal hold time of 5 hours at −10° C., the sample was heated at a heating rate of 36 K/h to 50° C. and the change in length Δl/l₀ was recorded as a function of the temperature. The thermal hysteresis characteristics of a test specimen are considered at −5° C., 0° C., 5° C., 10° C., 22° C., 35° C., 40° C. These points are representative of the temperature range from −10° C. to 50° C., since the hysteresis decreases with rising temperature within the stated temperature interval. Hence a sample which is hysteresis-free at 22° C. or 35° C. also shows no hysteresis in the range up to 50° C. Depending on the usage temperature and the material from which a precision EUVL component is produced, it is possible advantageously to consider further temperature points, especially 19° C. and/or 25° C.

For determination of the thermal hysteresis at 10° C., the individual measurements of the change in length for the five temperatures 8° C., 9° C., 10° C., 11° C. and 12° C., i.e., two temperature points above and two temperature points below 10° C., were recorded both on heating and on cooling of the sample in the range of −10° C. to 50° C. at a rate of 36 K/h. The differences in the measurements for heating curve and cooling curve at these five temperature measurement points were used to form the average, which has been listed as “Hyst.@10° C.” in the unit [ppm] in the tables.

For determination of the thermal hysteresis at 35° C., correspondingly, the individual measurements of the change in length for the five temperatures 33° C., 34° C., 35° C., 36° C. and 37° C., i.e., two temperature points above and two temperature points below 35° C., were recorded both on heating and on cooling of the sample in the range of −10° C. to 50° C. at a rate of 36 K/h. The differences in the measurements for heating curve and cooling curve at these five temperature measurement points were used to form the average, which has been listed as “Hyst.@35° C.” in the unit [ppm] in the tables.

Corresponding procedures were followed for the other temperature points stated above.

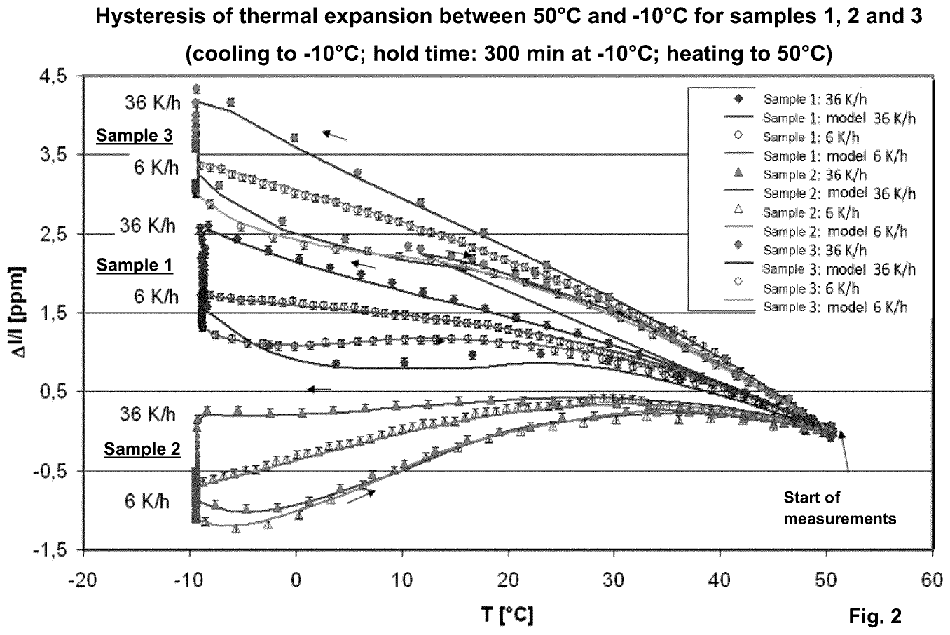

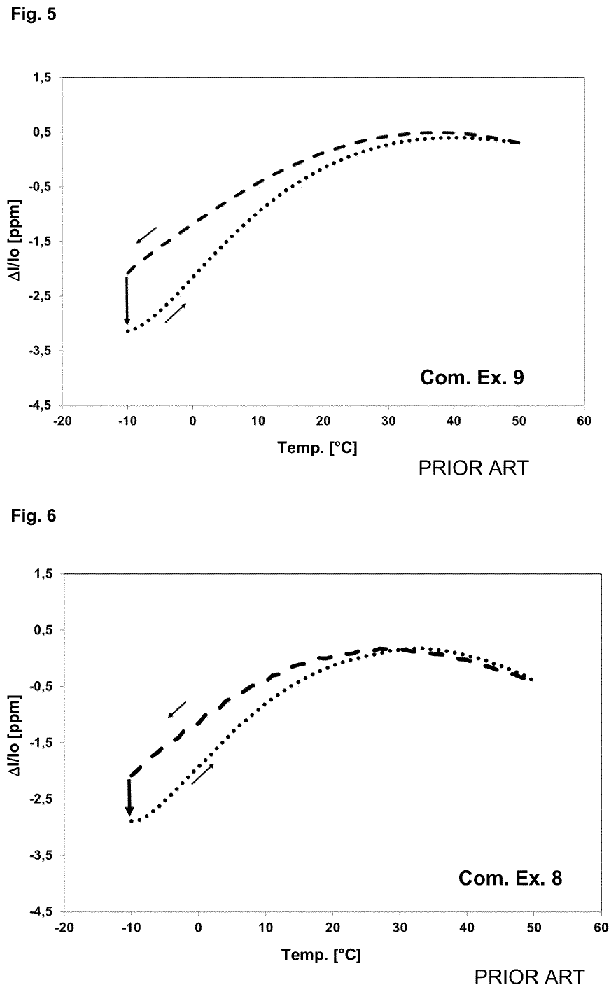

FIGS. 2 to 8 show the thermal hysteresis curves of known materials used for precision components. For better compatibility, in each case an extent of 6 ppm on the y-axis was chosen for representation in the figures. The cooling curves (dashed) and heating curves (dotted) are each clearly spaced apart from one another specifically at lower temperatures, meaning that they have a clearly separate profile. At 10° C., the difference is more than 0.1 ppm, up to around 1 ppm according to comparative example. In other words, the materials and the precision components manufactured from them show considerable thermal hysteresis in the relevant temperature range from at least 10° to 35° C.

Precision EUVL components and glass-ceramics provided according to the invention, conversely, are hysteresis-free (see, for example, FIGS. 10 and 11 and also FIGS. 31 to 33, likewise represented with an extent of 6 ppm on the y-axis), not only in the range from 19° C. to 25° C. and from 10° C. to 35° C., but also, optionally, at least in the range from 5° C. to 35° C. or at least in the range from 5° C. to 45° C., optionally at least in the range >0° C. to 45° C., optionally at least in the temperature range from −5° C. to 50° C., optionally also at even higher and even lower temperatures.

### Index F

For the description of the expansion characteristics of a test specimen (precision component as per embodiments provided according to the invention, or glass-ceramic), a TCL value is frequently reported, with TCL meaning “total change of length”. In the context of the invention, the TCL value is reported for the 0° C. and 50° C. temperature range. It is ascertained from the normalized Δl/l₀-T curve (in the diagrams, also called dl/l₀ -T curve) of the respective test specimen, with “normalized” meaning that the change in length at 0° C. is 0 ppm. The Δl/l₀-T curve for determining TCL is created by the same method as described above in connection with the determination of CTE in the context of the invention.

The TCL value is the difference between the highest dl/l₀ value and the lowest dl/l₀ value within this temperature range:

TCL (0;50° C.)=|dl/l₀ max.|+|dl/l₀ min.| (2)

where “dl” denotes the change in length at the respective temperature and “l₀” denotes the length of the test specimen at 0° C. The calculation is based in each case on the magnitudes of the dl/l₀ values.

FIGS. 14 to 17 show expansion curves of known materials, from which the dl/l₀ max values and dl/l₀ min values can each be read off for calculating the TCL value (see also below). The expansion curves each show a curved profile in the temperature range of 0° C. to 50° C.

In the context of the present invention, conversely, a flat profile of the expansion curve in the temperature range of 0° C. to 50° C. is a further feature of some embodiments of the precision EUVL component provided in accordance with the invention and is an advantageous feature of the glass-ceramic, especially of a glass-ceramic for a precision EUVL component of this kind. As a statement of the extent to which the curve profile of the thermal expansion deviates from a simple linear profile, the index F is introduced, as a measure of the flatness of the expansion curve, thereby enabling a classification of CTE curves:

F=TCL (0; 50° C.)/|expansion (0; 50° C.)| (3)

The index F is calculated by forming the quotient of the TCL (0;50) value [in ppm] (see above) and the difference in expansion between the temperature points of 0° C. and 50° C. [in ppm]. Since the expansion curve for the TCL determination is by definition normalized in such a way that the change in length at 0° C. is 0 ppm, the “difference in expansion between the temperature points of 0° C. and 50° C.” corresponds to the “expansion at 50° C.”, as stated in the tables. The index F is calculated using the magnitude of the expansion at 50° C.

It is advantageous here if the index F is <1.2, optionally <1.1, optionally at most 1.05. The closer the index F is to 1, the flatter the profile of the expansion curve.

FIG. 12 shows by way of example of the invention the expansion curve of a precision component or of an glass-ceramic with reference to an advantageous ceramization of composition example 6. For the representation, a section of 1.6 ppm on the y-axis was chosen. The highest expansion value (dl/l₀ max) is at +50° C. (dl/l₀ is +0.57 ppm, i.e. |0.57 ppm|), the lowest expansion value (dl/l₀ min) is 0 ppm. The difference in expansion between the temperature points of 0° C. and 50° C., corresponding to the magnitude of the “expansion at 50° C.”, is 0.57 ppm. This is used to calculate the index F for this material as follows: F (example 6 from Table 1a)=0.57 ppm/0.57 ppm=1.

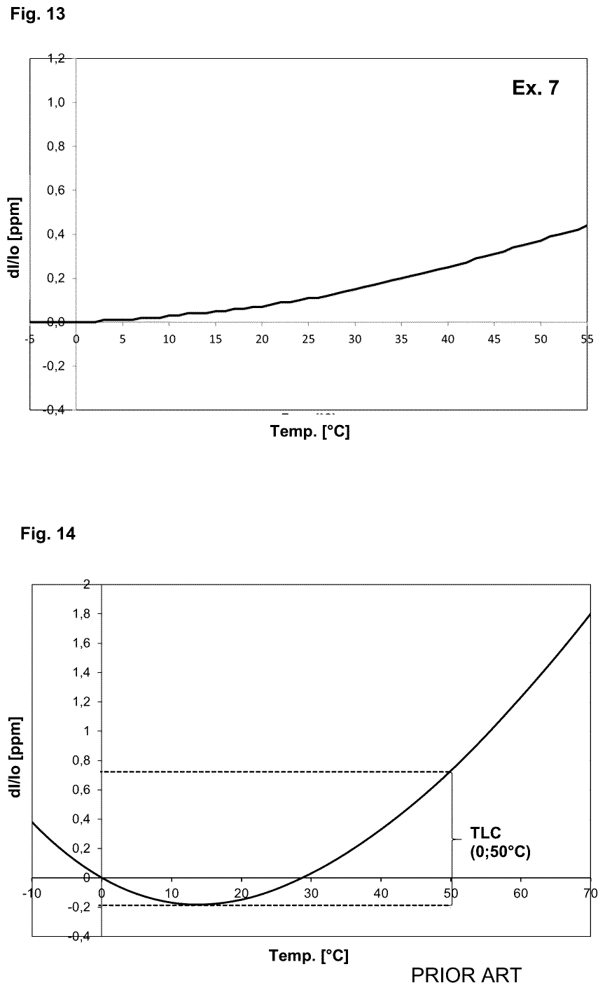

FIG. 13 shows a further example of the invention (composition according to example 7 from Table 1a), for which the index F is likewise 1.

FIG. 34 shows by way of example the expansion curve of a further precision component or glass-ceramic with reference to an advantageous ceramization (temperature not more than 830° C., time 3 days) of example 7b. For the representation, a section of 2.4 ppm on the y-axis was chosen. The highest expansion value (dl/l₀ max) is at +50° C. (dl/l₀ is +0.57 ppm, i.e., |0.57 ppm|), the lowest expansion value (dl/l₀ min) is 0 ppm. The difference in expansion between the temperature points at 0° C. and 50° C., corresponding to the magnitude of “expansion at 50° C.”, is 0.57 ppm. This is used to calculate the index F for this material as follows: F (example 7b from Table 1b)=0.57 ppm/0.57 ppm=1.

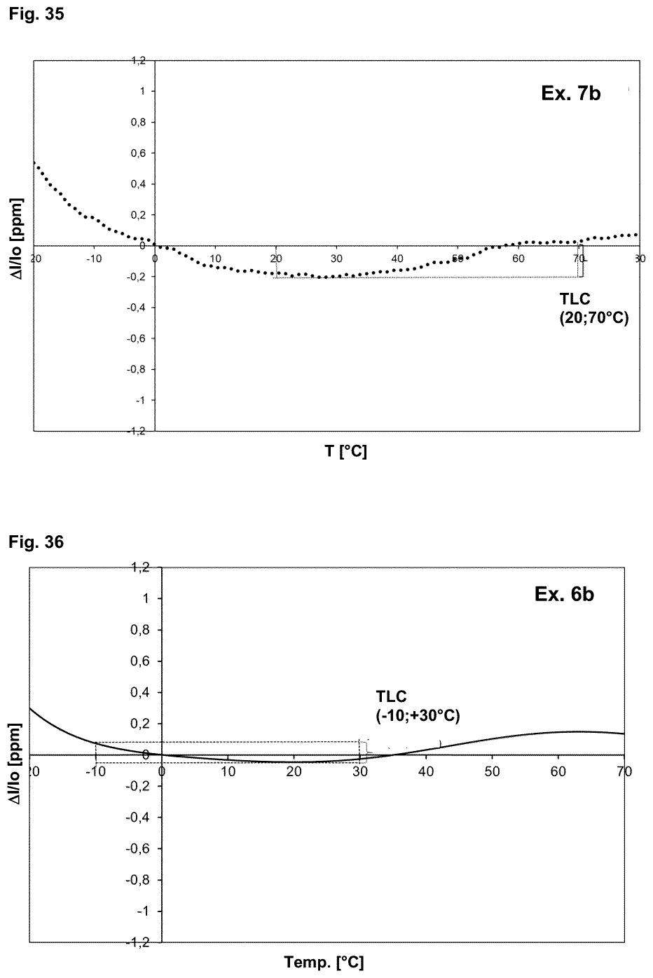

FIG. 35 likewise shows an advantageously flat profile of the expansion curve in the temperature range of −10° C. to 80° C. for a different precision component or glass-ceramic with a different ceramization of the glass-ceramic of example 7b from Table 1b (temperature not more than 825° C., time 3 days).

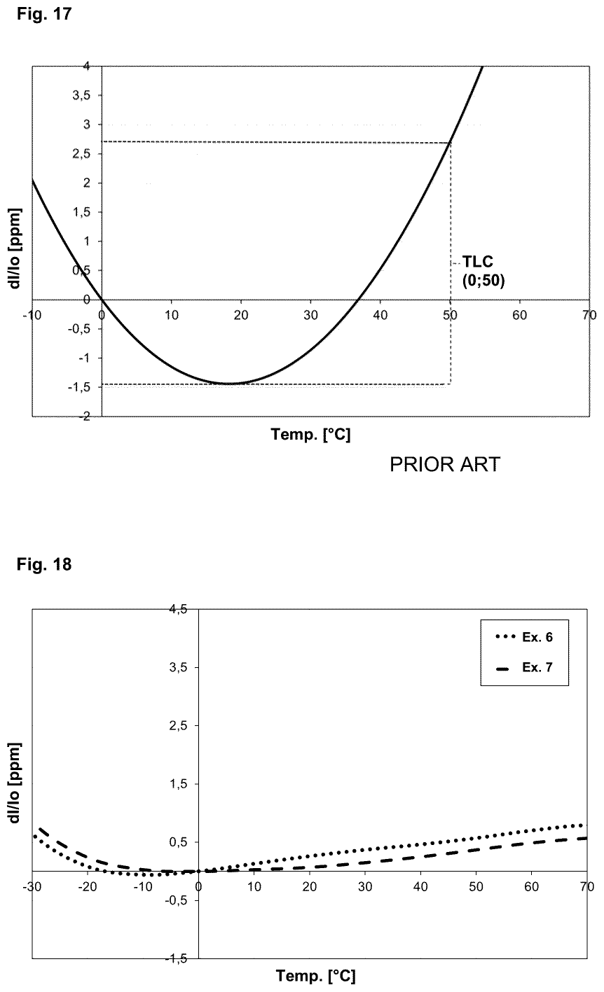

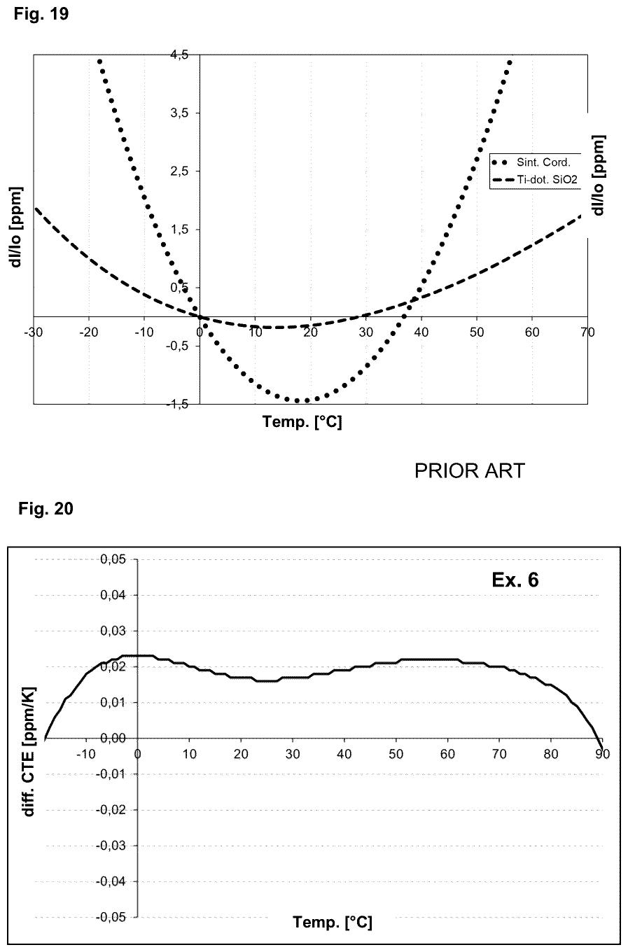

The precision EUVL components and glass-ceramics of some embodiments provided according to the invention therefore have a very flat profile of their expansion curves in the temperature range from 0° C. to 50° C., meaning that within the temperature range under consideration they not only have zero expansion but also exhibit a low fluctuation in the change in lengthwise expansion and hence in the differential CTE in this range. As evident from FIG. 18, some examples provided according to the invention also have a flat profile of their expansion curves over an even broader temperature range (here, by way of example, from −30° C. to +70° C.). In comparison with this, see the substantially steeper profiles of the expansion curves of known materials relative to the same temperature range in FIG. 19.

In comparison to the precision EUVL components and glass-ceramics provided according to the invention, FIGS. 14 to 17 show the expansion characteristics of known materials and of precision EUVL components manufactured from them, from which the index F may be calculated in each case. The expansion characteristics of the materials or precision EUVL components, as represented in FIGS. 14 to 17 and 19, were ascertained using the same dilatometer and under comparable conditions as for the expansion characteristics of the precision EUVL components and glass-ceramics provided according to the invention, represented for example in FIGS. 12, 13, 18 and 27 to 30 and also in FIGS. 34 to 36. Overall, the known materials show a curved profile of the expansion curves:

FIG. 14 shows the expansion curve of a commercially available, titanium-doped quartz glass in the same dl/l₀ section as in FIGS. 34 to 36. As is evident, the sum total of the magnitudes of the expansion value here, at +50° C. (dl/l₀ max is +0.73 ppm, i.e. |0.73 ppm|) and of the expansion value at 14° C. (dl/l₀ min is −0.19 ppm, i.e., |0.19 ppm|), produces a TCL(0;50) value of circa 0.92 ppm. The difference in expansion between the temperature points of 0° C. and 50° C., corresponding to the magnitude of the “expansion at 50° C.”, is 0.73 ppm. This data is used to calculate the index F for this material as follows: F (titanium-doped SiO₂)=0.92 ppm/0.73 ppm=1.26.

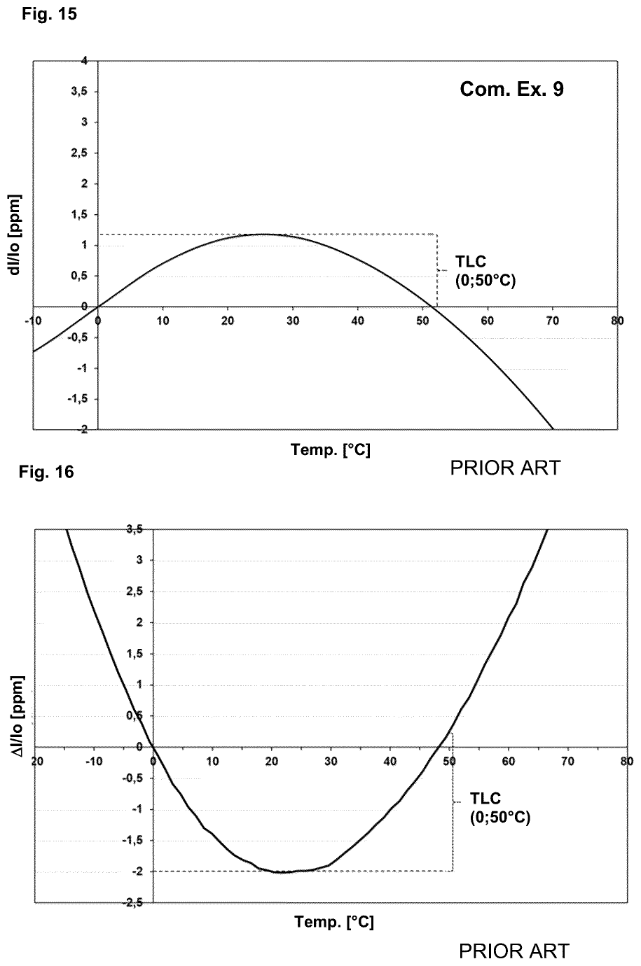

The index F is calculated correspondingly for a known LAS glass-ceramic or a corresponding precision component (see FIG. 15) as follows: F (known LAS glass-ceramic)=1.19 ppm/0.11 ppm=10.82.

The index F is calculated correspondingly for a known cordierite glass-ceramic or a corresponding precision component (see FIG. 16) as follows: F (known cordierite glass-ceramic)=2.25 ppm/0.25 ppm=9.

The index F is calculated correspondingly for a known sintered cordierite ceramic or a corresponding precision component (see FIG. 17) as follows: F (known sintered cordierite ceramic)=4.2 ppm/2.71 ppm=1.55.

The precision EUVL components and glass-ceramics provided according to the invention with a flat profile to their expansion curves are very advantageous, as then a component not only can be optimized for the later application temperature but also has a similarly low thermal expansion at higher and/or lower temperature loads as well, for example, such as during production. Precision components for microlithography, EUV (extreme UV) lithography and microlithography (also “EUV lithography” or “EUVL” for short) and metrology are used typically under standard cleanroom conditions, particularly a room temperature of 22° C. The CTE may be matched to this application temperature. However, such components are subjected to various process steps, examples being coating with metallic layers, and cleaning, patterning and/or exposure operations, in which temperatures may occur that are higher or, in some cases, lower than the temperatures prevailing during the subsequent cleanroom usage. Also, when using the EUVL components, temperatures higher or lower than the typical T_{A} of 22° C. may occur—for example, higher temperatures in photomask and/or photomask carrier when illuminating the photomask with EUVL radiation, or lower temperatures when cooling the photomask and/or photomask carrier. The precision EUVL components and glass-ceramics provided according to the invention which have an index F of <1.2 and therefore an optimized zero expansion not only at application temperature but also at any higher and/or lower temperatures during production are therefore very advantageous. Properties such as freedom from hysteresis and an index F <1.2 are particularly advantageous because the precision EUVL component or a glass-ceramic is used in EUV lithography, i.e. if, for example, the precision component is an EUV lithography mirror (also “EUVL mirror” for short) or EUVL photomask or a corresponding substrate therefor or a photomask carrier, since in EUV lithography in particular the mirrors or photomasks or photomask carriers are heated very nonuniformly, locally or in beam direction, as a result of being irradiated with high-energy radiation. In the case of the photomasks, the diversion of heat into the photomask carrier may also result in this carrier becoming hot as well. For such usage conditions, it is advantageous if the precision EUVL component or glass-ceramic has a low slope of the CTE-T curve in a temperature range around the application temperature (see below).

Exemplary precision EUVL components and glass-ceramics particularly for the precision EUVL component that are even better optimized for a subsequent application temperature in the range from 20° C. to 25° C., such as at 20 or 22° C., for example, have the feature that they have a relative change in length (dl/l₀) of ≤|0.10| ppm, optionally of ≤|0.09| ppm, optionally of ≤|0.08| ppm and optionally of ≤|0.07| ppm in the temperature range from 20° C. to 30° C. and/or a relative change in length (dl/l₀) of ≤|0.17| ppm, optionally of ≤|0.15| ppm, optionally of ≤|0.13| ppm and optionally of ≤|0.11| ppm in the temperature range from 20° C. to 35° C. Alternatively or additionally, a feature of such optimized glass-ceramics and precision components may be that they have a relative change in length (dl/l₀) of ≤|0.30| ppm, optionally of ≤|0.25| ppm, optionally of ≤|0.20| ppm and optionally of ≤|0.15| ppm in the temperature range from 20° C. to 40° C. The features relating to the relative change in length based on the different temperature intervals may be taken optionally from the dl/l₀ curves of FIGS. 12 to 19, for example. In reference to the relative change in length (dl/l₀), the data are of course based on the magnitude of the respective value.

A zero-expansion, hysteresis-free precision EUVL component having such advantageous expansion characteristics is suitable particularly for use as an EUVL mirror or as a substrate for an EUVL mirror which in operation is heated up to different extents, owing for example to the respective exposure mask, in regions of light and of shadow. A zero-expansion, hysteresis-free precision EUVL component having such advantageous expansion characteristics is likewise particularly suitable for use as an EUVL photomask substrate and/or as a photomask carrier which is heated up to different extents in operation. Owing to the above-stated low relative change in length, the precision EUVL components recited, formed from the glass-ceramic, have lower local gradients (or local slopes) in the topography of the surface than corresponding precision EUVL components manufactured using known materials.

The invention further relates to an EUVL photomask substrate and an EUVL photomask carrier comprising a precision component provided according to the invention, where EUVL photomask substrate and EUVL photomask carrier have an advantageous relative change in length as described above.

### Alternative Index f_{T.i}

Another precision EUVL component provided according to the invention and glass-ceramics especially for such a precision component are characterized by an alternative index f_{T.i.}, as described below.

For the description of the expansion characteristics of a test specimen (precision component or glass-ceramic), provided according to the invention of the precision EUVL component and of an glass-ceramic, a TCL_{(T.i.)} value is reported, where TCL denotes “Total Change of Length” and where T.i. describes the particular temperature interval under consideration.

With the alternative index f_{T.i.} it is possible to consider the expansion characteristics in a temperature interval (T.i.), optionally in the (20;40), (20;70) and/or (−10; 30) temperature range. As a result, the expansion characteristics can be classified more effectively in relation to the subsequent fields of application. Particularly in the case of a precision EUVL component comprising a glass-ceramic which within the temperature range under consideration exhibits a very flat expansion curve profile of close to 0 ppm or fluctuating around 0 ppm (see, for example, FIGS. 35, 36)—these being advantageous expansion characteristics over all—it may be advantageous, alternatively or additionally to the index F, to introduce a further measure of the flatness of the expansion curve. The alternative index f_{T.i.} has the unit (ppm/K) and is defined as:

f_{T.i.}=TCL_{(T.i.)}/width of the temperature interval (T.i.) (4)
where T.i. describes the particular temperature interval under consideration.

The TCL_{(T.i.)} value is the difference between the highest dl/l₀ value and the lowest dl/l₀ value within the temperature range (T.i.) under consideration in each case, where the expansion curve for the TCL_{(T.i.)} determination as well is by definition normalized in such a way that the change in length at 0° C. is 0 ppm. In other words, for example:

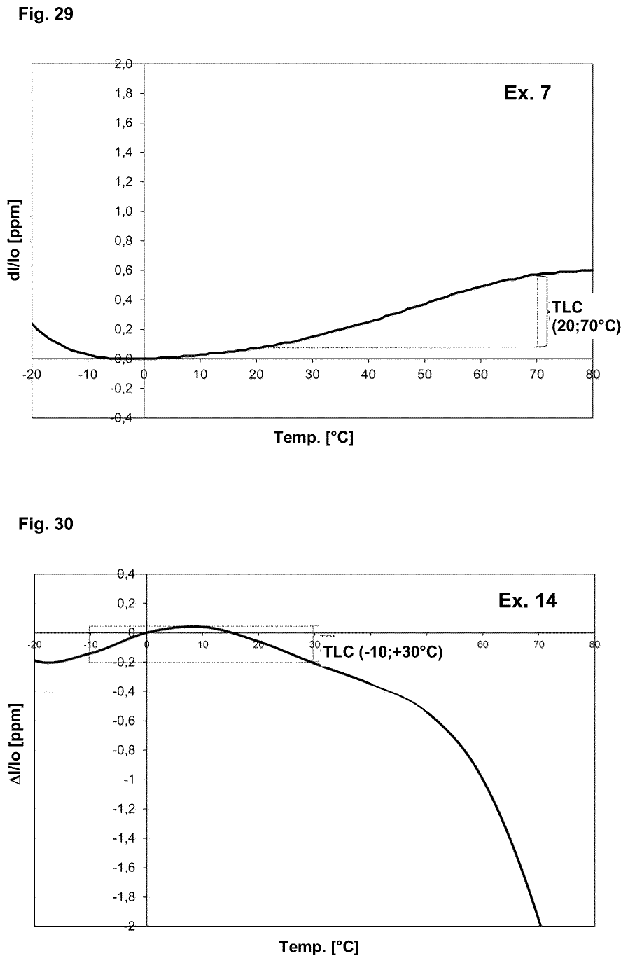

TCL_{(20,40° C.)}=|dl/l₀ max.|+|dl/l₀ min.| (5)
where “dl” denotes the change in length at the respective temperature and “l₀” denotes the length of the test specimen at 0° C. The calculation is based in each case on the magnitudes of the dl/l₀ values, if in the temperature interval in question the curve fluctuates around zero (e.g., FIGS. 30, 35, 36). Otherwise, the TCL_{(T.i.)} is the difference ascertained from the difference between the highest dl/l₀ value and the lowest dl/l₀ value in the particular temperature interval (T.i.) under consideration, this being self-evident and apparent from the diagrams (e.g., FIGS. 27, 29). Expressed generally, the TCL_{(T.i.)} may be calculated as follows:

TCL_{(T.i.)}=dl/l₀ max.−dl/l₀ min. (6)

The alternative index f_{T.i.} is calculated according to formula (4) by forming the quotient of the TCL_{(T.i.)} value [in ppm] (see above) and the width of the temperature interval (T.i.) in which the difference in expansion is being considered, reported in [K]. The width of the temperature interval under consideration between 20° C. and 40° C. amounts to 20 K. If, conversely, the profile of the expansion curve in the interval T.i.=(20;70) or (−10;30) is under consideration, the divisor for formula (4) is 50 K or 40 K, respectively.

Precision EUVL components and glass-ceramics provided according to the invention with a very flat profile of the expansion curves are very advantageous, since then the precision EUVL component not only can be optimized for the later application temperature but also, for example, for higher and/or lower temperature loads that may be anticipated. The alternative index f_{T.i.} is suitable, in accordance with the specifications required for particular component applications, for defining a suitable material and providing a corresponding precision EUVL component. Specific precision components and their applications are described later on below and are included here.

A precision EUVL component provided according to the invention or a glass-ceramic may have an alternative index f_{(20;40)}<0.024 ppm/K, optionally <0.020 ppm/K, optionally <0.015 ppm/K. A hysteresis-free, zero-expansion component or glass-ceramic having such expansion characteristics in the (20;40) temperature range can be used to particularly good effect as a precision EUVL component at room temperature. Examples of such precision components and glass-ceramics are represented in FIG. 27 and are also evident, for example, in FIG. 35.

A precision EUVL component provided according to the invention or a glass-ceramic may have an alternative index f_{(20;70)}<0.039 ppm/K, optionally <0.035 ppm/K, optionally <0.030 ppm/K, optionally <0.025 ppm/K, optionally <0.020 ppm/K. A hysteresis-free, zero-expansion component or glass-ceramic having such expansion characteristics in the (20;70) temperature range can likewise be used to particularly good effect as a precision EUVL component. It may be particularly advantageous if the component also has a similarly low thermal expansion under higher temperature loads, which may occur, for example, during the production of the precision EUVL component, but also in operation, these loads occurring locally or extensively. Further details regarding the temperature loads occurring in the context of precision EUVL components have already been described above in connection with the index F, and reference is made here to those details in order to avoid repetition. An example of such a precision component and glass-ceramic is represented in FIG. 29, and also in FIG. 35.

A precision EUVL component provided according to the invention or a glass-ceramic may have an alternative index f_{(-10;30)}<0.015 ppm/K, optionally <0.013 ppm/K, optionally <0.011 ppm/K. A hysteresis-free, zero-expansion component or glass-ceramic having such expansion characteristics in the (−10;30) temperature range can be used to particularly good effect as a precision component, especially as minor substrates for applications in which temperatures lower than room temperature may also occur, for example as mirror sub states in astronomy or Earth observation from space and, in the sense of the present invention, especially in cooled EUVL photomasks or photomask carriers. Corresponding components are described later on below. Examples of such precision components and glass-ceramics are represented in FIGS. 28 and 30, and also in FIG. 36.

An exemplary embodiment of a precision EUVL component or glass-ceramic has at least 2 alternative indices f_{(T.i.)}.

An exemplary embodiment of a precision component or glass-ceramic has the index F and at least one alternative index f_{(T.i.)}.

### Further Features

Some precision EUVL components and glass-ceramics may even have what is referred to as a CTE-plateau (see FIGS. 20 and 21 and also FIGS. 37, 39 and 41). It may be advantageous if the differential CTE has a plateau close to 0 ppm/K, i.e., in a temperature interval T_{P} having a width of at least 40 K, optionally at least 50 K, the differential CTE is less than 0±0.025 ppm/K. The temperature interval of the CTE plateau is referred to as T_{P}.

A CTE plateau is therefore understood to be a region extending over a portion of the CTE-T curve, in which the differential CTE does not exceed a value of 0±0.025 ppm/K, optionally 0±0.015 ppm/K, optionally 0±0.010 ppm/K, optionally 0±0.005 ppm/K, i.e., a CTE of close to 0 ppb/K.

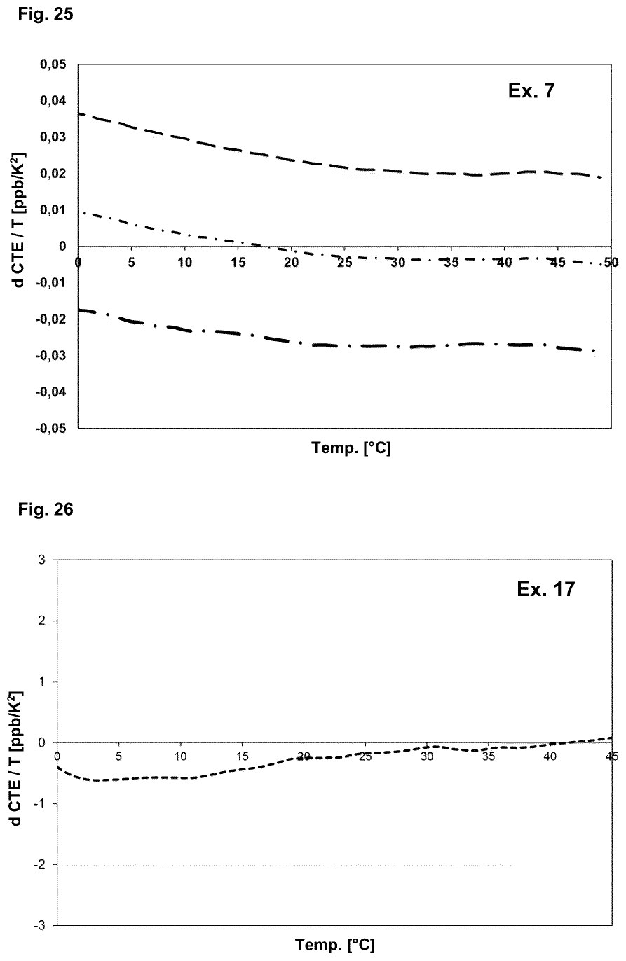

The differential CTE in a temperature interval T_{P} having a width of at least 40 K may advantageously be less than 0±0.015 ppm/K, i.e., 0±15 ppb/K. In some embodiments, a CTE plateau of 0±0.01 ppm/K, i.e., 0±10 ppb/K, may be formed over a temperature interval of at least 50 K. In FIG. 25, indeed, the middle curve between 7° C. and 50° C., i.e., over a width of more than 40 K, shows a CTE plateau of 0±0.005 ppm/K, i.e., 0±5 ppb/K.

It may be advantageous if the temperature interval T_{P} is in a range from −10 to +100° C., optionally 0 to 80° C.

The position of the CTE plateau is optionally matched to the application temperature T_{A} of the precision component. Exemplary application temperatures for precision components, T_{A}, are in the range of −60° C. to +100° C., optionally from −40° C. to +80° C. Some variants provided according to the present invention relate to precision EUVL components and glass-ceramics for application temperatures T_{A} of 0° C., 5° C., 10° C., 22° C., 40° C., 60° C., 80° C. and 100° C., optionally T_{A} 22° C., or in the temperature range from 10° C. to 35° C., optionally from 10° C. to 25° C., optionally from 19° C. to 25° C. The CTE plateau, i.e., the curve region with the low deviation of the differential CTE in the temperature interval T_{P}, may also lie in the temperature range of [40;100]; [0;80], [0;30° C.], [10;40° C.], [20;50° C.], [30;60° C.], [40;70° C.]; and/or [50;80° C.]. In some precision EUVL components or glass-ceramics, the CTE plateau may also lie in the temperature range of [40;30], [0;50], [10;25° C.], [19;25° C.]; [20;40] and/or [20;70].

FIG. 37 shows, with reference to example 6b from Table 1b, that this precision component or glass-ceramic has a CTE of 0±0.010 ppm/K throughout the represented temperature range from −10° C. to 90° C., i.e., has a 10-ppb plateau. On detailed consideration of a section of this curve (see FIG. 38), it is apparent that the glass-ceramic in the temperature range from −5° C. to 32° C. has a CTE of 0±0.005 ppm/K. This glass-ceramic meets the requirements for the average CTE (19;25), that are stated in standard SEMI P37−1109 for EUVL substrates and blanks.

FIG. 39 shows, for example 7b from Table 1b, ceramized at temperatures of not more than 825° C. for 3 days, that the precision component or glass-ceramic from 12° C. onward has a CTE of 0±0.010 ppm/K, i.e., a 10-ppb plateau with a width >40K. As evident in FIG. 40, the example in fact has a CTE of 0±0.005 ppm/K in the range between 16° C. and 40° C. and so likewise meets the requirements for the average CTE (19;25), which are stated in standard SEMI P37−1109 for EUVL substrates and blanks.

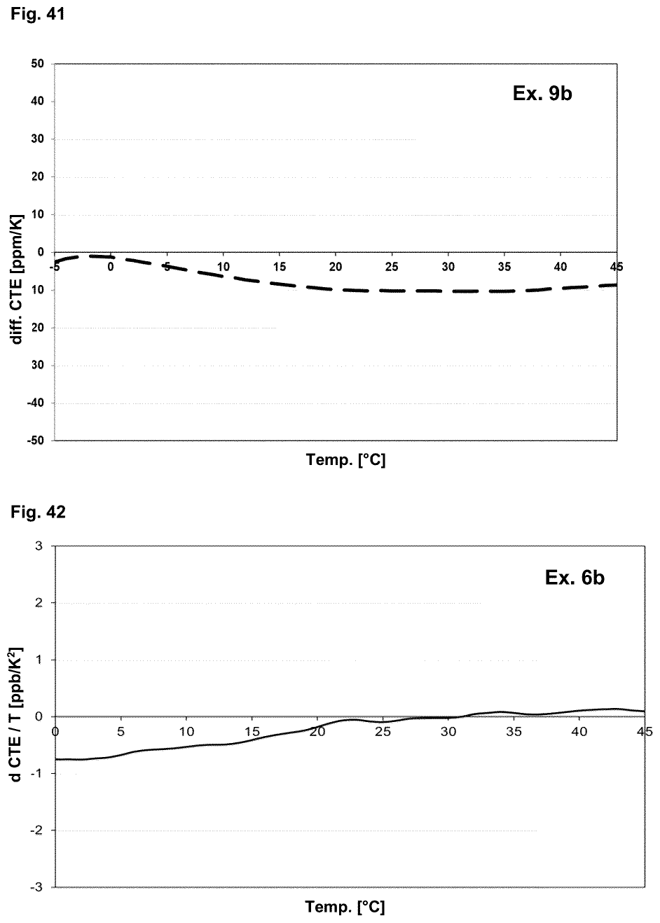

FIG. 41, for example 9b from Table 1b, ceramized at temperatures of not more than 830° C. for 3 days, shows that the precision component or glass-ceramic in the region represented between −5° C. and 45° C. has a CTE of 0±0.010 ppm/K, i.e., a 10-ppb plateau.

Precision EUVL components and glass-ceramics with a plateau, i.e., with optimized zero expansion, offer the same advantages already described above in connection with the flat profile of the expansion curves and the index F and/or the alternative index f_{(T.i.}.

According to some embodiments provided according to the invention, the CTE-T curve of the precision EUVL component or glass-ceramic, in a temperature interval, having at least a width of 30 K, optionally at least a width of 40 K, optionally at least a width of 50 K, has at least one curve portion with low slope, more particularly a slope of at most 0±2.5 ppb/K², optionally of at most 0±2 ppb/K², optionally of at most 0±1.5 ppb/K², optionally of at most 0±1 ppb/K², optionally of at most 0±0.8 ppb/K², and even, according to some variants, of at most 0±0.5 ppb/K².

The temperature interval with low slope is optionally matched to the application temperature T_{A} of the precision EUVL component. Exemplary application temperatures T_{A} for precision components are in the range of −60° C. to +100° C., optionally from −40° C. to +80° C. Some variants provided according to the present invention relate to precision EUVL components and glass-ceramics for application temperatures in the temperature range from 10 to 35° C., optionally from 10° C. to 25° C., optionally from 19° C. to 25° C., and T_{A} of 0° C., 5° C., 10° C., 22° C., 40° C., 60° C., 80° C. and 100° C. The temperature interval with low slope may also lie in the temperature range of [40;100]; [0;80], [0; 30° C.], [10;40° C.], [20;50° C.], [30;60° C.], [40;70° C.], [10;25° C.], [19;25° C.] and/or [50; 80° C.]. In other precision components or glass-ceramics, the temperature interval with low slope may also lie in the temperature range of [40;30], [0;50], [10;25° C.], [19;25° C.]; [20;40] and/or [20;70].

FIG. 22 shows the slope of the CTE-T curve in the temperature range from 0° C. to 45° C. for a precision EUVL component or glass-ceramic using the composition of example 6 from Table 1a. The CTE slope in the entire temperature range is below 0±2.5 ppb/K² and in an interval with a width of at least 30 K is even below 0±1.5 ppb/K².

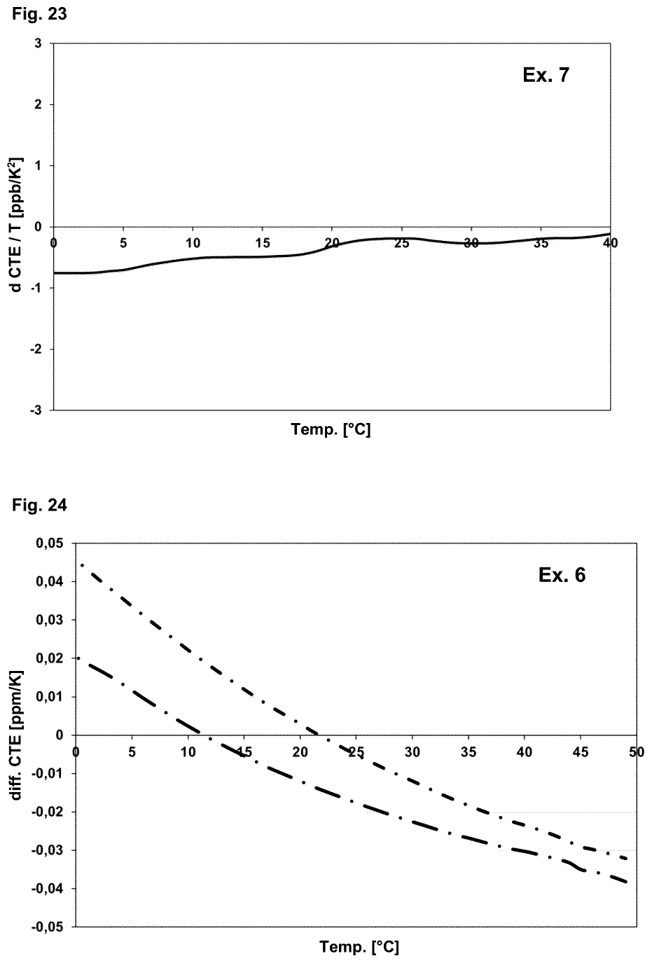

In FIG. 23, it is apparent that the CTE slope of a precision EUVL component or glass-ceramic corresponding to composition example 7 from Table 1a in the entire temperature range from 0° C. to 40° C. with a width of at least 40 K is below 0±1.0 ppb/K² and in an interval of at least 30 K in width is even below 0±0.5 ppb/K².

In FIG. 26, it is apparent that the CTE slope of a precision EUVL component or glass-ceramic corresponding to example 17 from Table 1a in the entire temperature range from 0° C. to 45° C. with a width of at least 45 K is below 0±1.0 ppb/K² and in an interval of at least 30 K in width is even below 0±0.5 ppb/K².

FIG. 42 shows the slope of a CTE-T curve in the temperature range from 0° C. to 45° C. for a precision EUVL component or glass-ceramic, using the composition from example 6b to Table 1b. The CTE slope in the entire temperature range is below 0±1 ppb/K² and in an interval of at least 30 K in width (from around 12° C. onward) is even below 0±0.5 ppb/K².

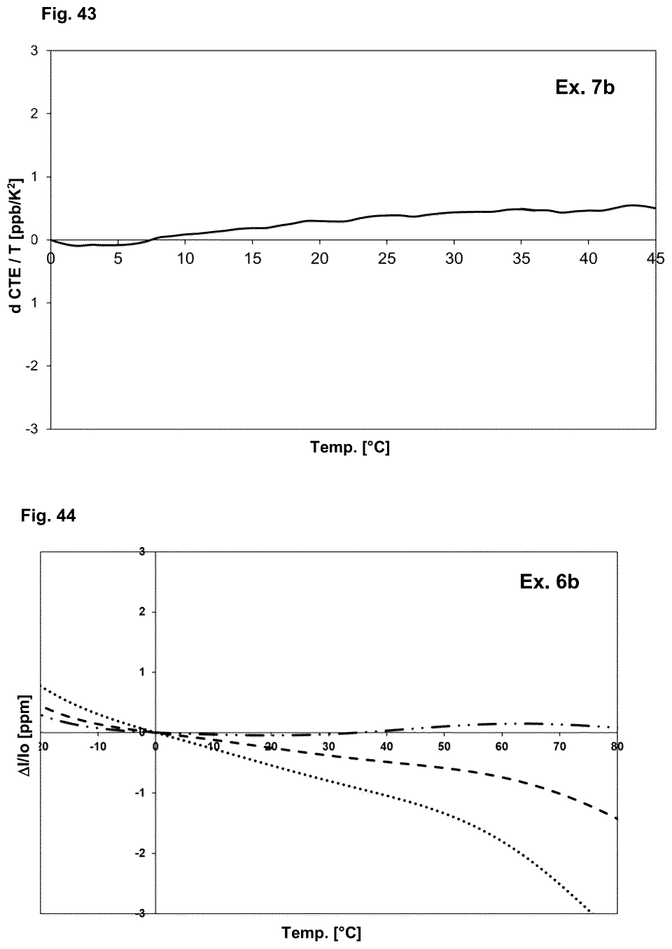

In FIG. 43, it is apparent that the CTE slope of an precision component or glass-ceramic corresponding to example 7b from Table 1b in the entire temperature range from 0° C. to 45° C. with a width of at least 45 K is below 0±1.0 ppb/K² and in an interval of at least 40 K in width (in the represented region between 0 and 42° C.) is even below 0±0.5 ppb/K².

Glass-ceramics and precision components having such expansion characteristics are especially suitable for EUV lithography applications (e.g., as mirrors or substrates for minors or masks or mask blanks or as photomask carriers or wafer carriers), since in this sector the requirements imposed on the precision components and materials used for the optical components are becoming ever higher with regard to extremely low thermal expansion, a zero crossing of the CTE-T curve at close to the application temperature, and, in particular, a low slope of the CTE-T curve. In the context of the invention, some embodiments of a precision EUVL component or glass-ceramic have a very flat CTE profile, with the profile exhibiting both a zero crossing and a very low CTE slope, and possibly a very flat plateau.

The feature of the low slope may be present with or without the formation of an advantageous CTE plateau.

FIGS. 24 and 25 show how the CTE profile can be matched to different application temperatures through variation of ceramization temperature and/or ceramization time. As apparent from FIG. 24, the zero crossing of the CTE-T curve can be shifted from 12° C., for example, to a value of 22° C. by raising the ceramization temperature by 10 K. As an alternative to increasing the ceramization temperature, the ceramization time can also be extended accordingly. FIG. 25 demonstrates by way of example that the very flat profile of the CTE-T curve can be raised for example by raising the ceramization temperature by 5 or 10 K. As an alternative to increasing the ceramization temperature, it is also possible for the ceramization time to be extended accordingly.

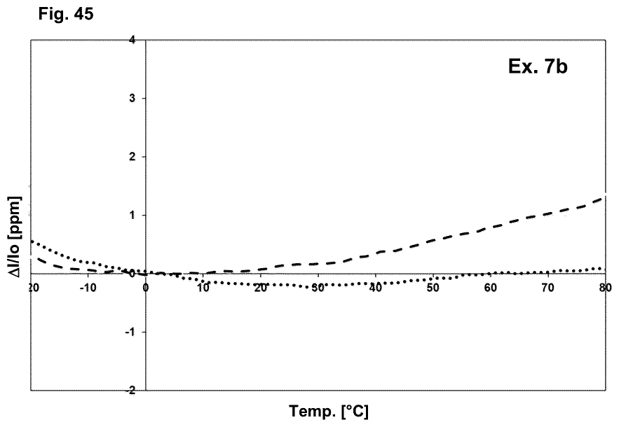

FIGS. 44 and 45 show how the expansion curve can be matched to different application temperatures through variation of ceramization temperature and/or ceramization time.

FIG. 44 shows, with reference to example 6b from Table 1b, that the resulting expansion curves of the precision component or glass-ceramic may be influenced in a targeted manner through the choice of the maximum ceramization temperature with which the starting green glass is treated. The dotted curve shows the expansion curve of a glass-ceramic whose parent green glass has been ceramized at not more than 810° C. for 2.5 days, whereas the dashed and dotted curve shows the expansion curve of a glass-ceramic whose parent green glass has been ceramized at not more than 820° C. for 2.5 days. Moreover, FIG. 44 demonstrates by way of example that the glass-ceramics provided according to the invention are post-ceramizable, which means that a targeted fine-tuning of the expansion curve of the glass-ceramic is possible, by subjecting material that has already been ceramized to a further temperature treatment. In this case, material of the glass-ceramic ceramized at not more than 810° C. for 2.5 days was post-ceramized again at 810° C. for 1.25 days, in other words with a shortened hold time. The effect of this post-ceramization is represented in the form of the dashed expansion curve. Comparison of the expansion curves shows that the expansion curves and hence the average CTE (0;50) are different before and after the post-ceramization. However, XRD analyses of the samples before and after the post-ceramization, within the bounds of measurement accuracy, each show the same results in terms of the average crystal size and the crystal phase fraction.

FIG. 45, for example 7b from Table 1b, shows the adjustability of the expansion curve via different maximum ceramization temperatures in the ceramization of the same starting green glass. Represented with a dashed line: ceramization at not more than 830° C. for 3 days; represented as a dotted line: ceramization at not more than 825° C. for 3 days.

As an alternative to an increase in the ceramization temperature, it is also possible for the ceramization time to be extended correspondingly.

Some precision EUVL components and glass-ceramics also have good internal quality. They optionally have at most 5 inclusions per 100 cm³, optionally at most 3 inclusions per 100 cm³, optionally at most 1 inclusion per 100 cm³. The invention understands inclusions to comprehend both bubbles and crystallites having a diameter of more than 0.3 mm.

According to some embodiments provided according to the invention, precision EUVL components, for example photomask substrates, photomask carriers, EUVL mirrors and/or wafer stages, are provided that have a diameter or edge length of at most 800 mm and a thickness of at most 250 or 100 mm and that have at most 5, optionally at most 3, optionally at most 1 inclusion in each case per 100 cm³ with a diameter of a size of more than 0.03 mm.

As well as the number of inclusions, the maximum diameter of the inclusions detected also serves as a measure of the level of internal quality. The maximum diameter of individual inclusions in the total volume of a precision component having a diameter of less than 500 mm, or edge lengths of less than 500 mm, is optionally at most 0.6 mm, and in the critical volume for the application, at close to the surface, for example, is optionally at most 0.4 mm.

The maximum diameter of individual inclusions in glass-ceramic components having a diameter of 500 mm to less than 2 m, or edge lengths of 500 mm to less than 2 m, is optionally at most 3 mm, and optionally at most 1 mm in the volume critical for the application, such as close to the surface, for example. This may be advantageous for achieving the surface quality necessary for the application.

Some embodiments relate to precision EUVL components having relatively low dimensions, especially in the case of (rect)angular shapes having edge lengths (width and/or depth) or, in the case of round areas, having diameters of at least 50 mm, optionally at least 100 mm and/or not more than 1500 mm, optionally not more than 1000 mm and/or a thickness of less than 50 mm, optionally less than 10 mm and/or at least 1 mm, optionally at least 2 mm. Such precision components may be employed, for example, in microlithography and EUV lithography, as—for example—a photomask substrate and/or reticle stage and/or spacer and/or as mounts for measurement technology/sensors and/or grating substrates and/or covers.

Some embodiments relate to precision components having very small dimensions, especially having edge lengths (width and/or depth) or diameters and/or thickness of a few mm (for example, at most 20 mm or at most 10 mm or at most 5 mm or at most 2 mm or at most 1 mm). Such precision components may be employed, for example, in microlithography and EUV lithography, as a cover for lightweight structures.

But very large precision components can also be produced. Hence some embodiments of the invention relate to components of high volume. In the context of this patent application, this term is intended to comprehend a component having a mass of at least 300 kg, optionally at least 400 kg, optionally at least 500 kg, optionally at least 1 t, optionally at least 2 t, according to some embodiments provided according to the invention at least 5 t, and/or having edge lengths (width and/or depth) in the case of (rect)angular shapes of at least 0.5 m, optionally at least 1 m or at most 2 m, optionally at most 1.5 m, and/or a thickness (height) of at least 50 mm, optionally at least 100 mm, optionally at least 200 mm, optionally at least 250 mm, or, in the case of round shapes, having a diameter of at least 0.5 m, optionally at least 1 m, optionally at least 1.5 m, and/or having a thickness (height) of at least 50 mm, optionally at least 100 mm, optionally at least 200 mm, optionally at least 250 mm. Such precision components may be employed for example in EUV lithography as well as low-NA systems as so-called second-generation mirrors in high-NA systems.

With a glass-ceramic provided according to the invention, precision EUVL components in the sizes described above can be produced.

In some embodiments provided according to the invention, the components may also be even larger, having for example a diameter of at least 1 m or at least 2 m or greater, and/or a thickness of 50 mm to 400 mm, optionally 100 mm to 300 mm. According to some variants, the invention also relates to rectangular components where optionally at least one surface has an area of at least 1 m², optionally at least 1.2 m², optionally at least 1.4 m², optionally at least 3 m² or at least 4 m² and/or a thickness of 50 mm to 400 mm, optionally 100 mm to 300 mm. In general, large-volume components are produced that have a significantly larger base area than height. However, the large-volume components in question may also have a shape approximated to a cube or a sphere.

In some embodiments of the precision EUVL component, it comprises at least one inorganic material selected from the group consisting of doped quartz glass, glass-ceramic and ceramic, optionally Ti-doped quartz glass, LAS glass-ceramic and cordierite.

The invention also relates to a precision EUVL component having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an index F of <1.2, where F=TCL (0; 50° C.)/|expansion (0; 50° C.)|, and at least one inorganic material selected from the group consisting of doped quartz glass, glass-ceramic and ceramic, optionally Ti-doped quartz glass, LAS glass-ceramic and cordierite.

The invention also relates to a precision EUVL component having an average coefficient of thermal expansion CTE in the range from 0 to 50° C. of at most 0±0.1×10⁻⁶/K and a thermal hysteresis of <0.1 ppm at least in the temperature range from 19 to 25° C., optionally at least in the temperature range from 10° C. to 25° C., optionally at least in the temperature range from 10° C. to 35° C., and an alternative index f_{T.i.} selected from the group consisting of alternative index f_{(20;40)}<0.024 ppm/K, alternative index f_{(20;70)}<0.039 ppm/K and alternative index f_{(-10;30)}<0.015 ppm/K, and at least one inorganic material selected from the group consisting of doped quartz glass, glass-ceramic and ceramic, optionally Ti-doped quartz glass, LAS glass-ceramic and cordierite.

In some embodiments, the inorganic material is a hysteresis-free, zero-expansion LAS glass-ceramic. It may be advantageous if the LAS glass-ceramic contains less than 0.6 mol % of MgO and/or ZnO. There may advantageously be 60-71 mol % of SiO₂ and 7 to 9.4 mol % of Li₂ O present. One exemplary variant of the precision component comprises an LAS glass-ceramic provided according to the invention whose inventive features and advantageous developments are described in detail below. The statements made for the LAS glass-ceramic below and for advantageous developments thereof are valid correspondingly for the precision component comprising such an LAS glass-ceramic, and so, in terms of the advantageous composition and advantageous features of the material, reference is made to the observations below.

The invention, moreover, also relates to a precision EUVL component provided according to the invention, selected from the group consisting of photomasks or reticles, photomask substrates or reticle mask blanks or mask blanks, photomask carriers or reticle stages, mirrors, mirror carriers and wafer carriers or wafer stages, more particularly to a photomask or reticle, and/or a photomask substrate or reticle mask blank or mask blank and/or a photomask carrier or reticle stage.

The invention also relates to the use of the precision EUVL component provided according to the invention.

The precision EUVL component provided according to the invention may advantageously, therefore, be used in EUV lithography.

EUV lithography in the sense of the present invention also encompasses EUV microlithography.

The invention therefore also relates to the use of a precision EUVL component provided according to the invention, advantageously in EUVL lithography, especially as a photomask or reticle, photomask substrate or reticle mask blank or mask blank, photomask carrier or reticle stage, minor, minor carrier and/or wafer carrier or wafer stage.

Precision EUVL components may for example be optical components, and specifically what is called a normal-incidence mirror, i.e., a mirror which is operated close to the perpendicular impingement of radiation, or what is called a grazing-incidence mirror, i.e., a mirror which is operated at a grazing impingement of radiation. Such a mirror comprises not only the substrate but also a coating which reflects the incident radiation. Especially in the case of a minor for x-radiation, the reflective coating is, for example, a multilayer system or multilayer having a multiplicity of layers of high reflectivity in the x-ray range in the case of non-grazing incidence. A multilayer system of this kind of a normal-incidence mirror optionally comprises 40 to 200 pairs of layers, consisting of alternating layers of, for example, one of the material pairings Mo/Si, Mo/Bi, Ru/Si and/or MoRu/Be.

In particular, the optical elements of the invention may be x-ray-optical elements, i.e., optical elements which are used in conjunction with x-radiation, more particularly soft x-radiation or EUV radiation, especially reticle masks operated in reflection or photomasks, particularly for EUV (micro)lithography. They may advantageously be mask blanks. The precision component may also be used as a mirror or as a substrate for a minor for EUV lithography.

As already maintained, some embodiments of the precision EUVL component or glass-ceramic provided according to the invention feature a flat CTE profile over a wide temperature range. These embodiments are therefore advantageous on use in EUVL applications in which temperatures above and/or below the typical application temperature may prevail, because, for example, the photomask and/or the photomask carrier is being actively cooled and/or as a result of the use of EUV beam sources of relatively high power and/or the use of relatively small photomasks and carriers, possibly leading to a local increase in temperature in the photomask or the photomask carrier. Furthermore, precision EUVL components with the described flat CTE profile over a wide temperature range are advantageous in terms of the adhesion and/or robustness of the reflective multilayer system applied to the photomask substrate, since here it is possible for a reduced tensile stress to occur in the event of temperature changes during production and also during use of the photomask.

Further advantages, especially in terms of the resultant imaging quality, may arise if in the case of EUV lithography, the individual precision EUVL components are harmonized with one another or matched to one another in their thermal properties, such as CTE, CTE profile, thermal hysteresis, etc., especially by the various precision EUVL components having very similar or virtually identical thermal properties. Hence it may be advantageous to use the same material in particular for the photomask substrate and for the photomask carrier.

On the basis of their high mechanical stability, the precision EUVL components provided according to the invention, composed of glass-ceramics, may be used in “high-NA” EUVL units or in other EUVL units with increased wafer throughput. Because of the higher elasticity modulus of LAS glass-ceramics relative to other materials, Ti-doped quartz glass for example, it is possible here to achieve, among other things, an increase in the dynamic positioning accuracy of the photomask.

The precision EUVL component provided according to the invention, especially in the case of photomask carriers and/or wafer carriers, may be a lightweight structure. The component provided according to the invention may further comprise a lightweight structure. This means that in certain regions of the component, cavities are provided to lighten the weight. The weight of a component is reduced by lightweight working by optionally at least 80%, optionally at least 90%, in comparison to the unworked component.

The invention further comprises an LAS glass-ceramic particularly for a precision EUVL component provided according to the invention, where the glass-ceramic has an average coefficient of thermal expansion CTE in the range from 0 to 50° C. of at most 0±0.1×10⁻⁶/K and a thermal hysteresis at least in the temperature range from 19 to 25° C., optionally at least in the temperature range from 10° C. to 25° C., optionally at least in the temperature range of 10° C.-35° C., of <0.1 ppm, and comprises the following components (in mol % based on oxide):

| | |
|---|---|
| SiO₂ | 60-71 |
| Li₂O | 7-9.4 |
| MgO + ZnO | 0-<0.6 |

at least one component selected from the group consisting of P₂O₅, R₂O, where R₂O may be Na₂O and/or K₂O and/or Cs₂O and/or Rb₂O, and RO, where RO may be CaO and/or BaO and/or SrO,
nucleating agent with a content of 1.5 to 6 mol %, where nucleating agent is at least one component selected from the group consisting of TiO₂, ZrO₂, Ta₂O₅, Nb₂O₅, SnO₂, MoO₃ and WO₃.

In some embodiments, the precision EUVL component may comprise a substrate which comprises the glass-ceramic provided according to the invention. In some embodiments, the precision EUVL component may comprise or consist of the glass-ceramic provided according to the invention.

The invention for the first time provides a zero-expansion glass-ceramic that exhibits an extremely low thermal hysteresis at least in the temperature range from 19 to 25° C., optionally at least in the temperature range from 10° C. to 25° C., optionally at least in the temperature range from 10° C. to 35° C., of <0.1 ppm. A material having such a small hysteresis effect in the stated temperature ranges, of <0.1 ppm, is referred to below as “hysteresis-free”. Since, as already mentioned above, the extent of the hysteresis is dependent on the rate of temperature change used for ascertaining it, the statements on hysteresis in the context of the invention relate to a heating rate/cooling rate of 36 K/h, i.e., 0.6 K/min. In some embodiments, the LAS glass-ceramic may be hysteresis-free at least in the temperature range from 5° C. to 35° C. or at least from 5° C. to 40° C., optionally at least in the temperature range from >0° C. to 45° C., optionally at least in the temperature range from −5° C. to 50° C.

CTE and thermal hysteresis have already been described in detail above in connection with the precision EUVL component. All of the elucidations—including the differences shown relative to the prior art—are also valid correspondingly for the LAS glass-ceramic provided according to the invention.

A glass-ceramic is understood in the invention to refer to non-porous inorganic materials having a crystalline phase and a vitreous phase, with the matrix, i.e., the continuous phase, generally being a glass phase. To produce the glass-ceramic, first of all the components of the glass-ceramic are mixed, melted and refined, and a so-called green glass is cast. After cooling, the green glass is crystallized in a controlled manner by reheating (“controlled volume crystallization”). The chemical composition (analysis) of the green glass and of the glass-ceramic produced from it are the same; ceramization alters solely the internal structure of the material. Therefore, any reference below to the composition of the glass-ceramic applies equally to the precursor article for the glass-ceramic, i.e., to the green glass.

In the context of the invention, it has been recognized for the first time that the two components MgO and ZnO promote the occurrence of thermal hysteresis in the temperature range under consideration and that for the provision of a zero-expansion LAS glass-ceramic which is hysteresis-free at least in the 10° C. to 35° C. temperature range it is therefore essential to limit the MgO and ZnO content, as indicated below. Conversely, it was assumed to date that these glass components in combination or each individually are necessary specifically in zero-expansion LAS glass-ceramics in order to achieve the zero expansion and to make the shaping of the CTE-T curve for the material “flat”, i.e., with a low slope of the CTE-T curve in the relevant temperature range. There was therefore a conflict of objectives in that an LAS glass-ceramic could be either zero-expansion or hysteresis-free.

This conflict of objectives is resolved with the invention if not only is the use of MgO and ZnO largely shunned but additionally the SiO₂ and Li₂O contents as well are chosen from the ranges dictated by the invention. In the context of the invention, it has been established that, in the range dictated by the contents for SiO₂ (60−71 mol %) and for Li₂O (7-9.4 mol %), surprisingly, zero-expansion and hysteresis-free glass-ceramics can be obtained.

LAS glass-ceramics contain a negatively expanding crystal phase which, in the invention, may comprise or consist of high-quartz solid solution, also called β-eucryptite, and a positively expanding glass phase. As well as SiO₂ and Al₂O₃, Li₂O is a main constituent of the solid solution. If present, ZnO and/or MgO are likewise incorporated into the solid solution phase, and together with Li₂O they influence the expansion characteristics of the crystal phase. This means that the above-stated mandates of the invention (reduction in, optionally exclusion of, MgO and ZnO) have a significant effect on the nature and the properties of the solid solution formed in the course of ceramization. Unlike the known zero-expansion glass-ceramics in which MgO and ZnO in particular are used for establishing the desired expansion characteristics of the glass-ceramic, embodiments provided according to the invention for this purpose employ at least one component selected from the group consisting of P₂O₅, R₂O, where R₂O may be Na₂O and/or K₂O and/or Rb₂O and/or Cs₂O, and RO, where RO may be CaO and/or BaO and/or SrO. In contrast to MgO and ZnO, the stated alkaline earth metal oxides and alkali metal oxides, if present, nevertheless remain in the glass phase and are not incorporated into the high-quartz solid solution.

Within the scope of the invention, it has been found that it can be advantageous for the provision of a zero-expansion and hysteresis-free glass-ceramic if the composition satisfies the condition: molar content SiO₂+(5× molar content Li₂O)≥106 or optionally ≥106.5, optionally molar content SiO₂+(5× molar content Li₂O)≥107 or ≥107.5. Alternatively or in addition, an advantageous upper limit of ≤115.5 or of ≤114.5 or of ≤113.5 can apply to the condition “molar content SiO₂+(5× molar content Li₂O)”.

In some embodiments, the glass-ceramic can comprise the following components, either individually or in any combination in mol %:

| | |
|---|---|
| Al₂O₃ | 10 to 22 |
| P₂O₅ | 0 to 6 |
| MgO | 0 to 0.35 |
| ZnO | 0 to 0.5 |
| R₂O | 0 to 6 |
| RO | 0 to 6 |
| TiO₂ + ZrO₂ | 1.5 to 6. |

In some embodiments, the glass-ceramic can comprise the following components, either individually or in any combination in mol %:

| | |
|---|---|
| Al₂O₃ | 10 to 22 |
| P₂O₅ | 0 to 6 |
| MgO | 0 to 0.3 |
| ZnO | 0 to 0.4 |
| R₂O | 0 to 6 |
| RO | 0 to 6 |
| TiO₂ + ZrO₂ | 1.5 to 6. |

In some embodiments, the following components may be present in the glass-ceramic, individually or in any combination in mol %, within the limits mentioned above for the sum totals of R₂O, RO and TiO₂+ZrO₂:

| | |
|---|---|
| Na₂O | 0 to 3 |
| K₂O | 0 to 3 |
| Cs₂O | 0 to 2 |
| Rb₂O | 0 to 2 |
| CaO | 0 to 5 |
| BaO | 0 to 4 |
| SrO | 0 to 3 |
| TiO₂ | 0 to 5 |
| ZrO₂ | 0 to 3. |

In some embodiments, the LAS glass-ceramic comprises (in mol % on an oxide basis):

| | |
|---|---|
| Al₂O₃ | 10 to 22 |
| P₂O₅ | 0 to 6 |
| MgO | 0 to 0.35 |
| ZnO | 0 to 0.5 |
| R₂O | 0 to 6 |
| RO | 0 to 6 |
| Nucleating | 1.5 to 6, |
| agent | |

wherein the nucleating agent is optionally TiO₂ and/or ZrO₂.

In some embodiments, the LAS glass-ceramic comprises (in mol % on an oxide basis):

| | |
|---|---|
| Al₂O₃ | 10 to 22 |
| P₂O₅ | 0 to 6 |
| MgO | 0 to 0.3 |
| ZnO | 0 to 0.4 |
| R₂O | 0 to 6 |
| RO | 0 to 6 |
| Nucleating | 1.5 to 6, |
| agent | |

wherein the nucleating agent is optionally TiO₂ and/or ZrO₂.

In some embodiments, the LAS glass-ceramic comprises (in mol % on an oxide basis):

| | |
|---|---|
| SiO₂ | 60.50 to 69 |
| Li₂O | 8 to 9.4 |
| Al₂O₃ | 11 to 21 |
| P₂O₅ | 0.5 to 6 |
| MgO | 0 to 0.2 |
| ZnO | 0 to 0.3 |
| R₂O | 0 to 4 |
| RO | 0.2 to 4.5 |
| Nucleating | 2.5 to 5, |
| agent | |

wherein the nucleating agent is optionally TiO₂ and/or ZrO₂.

The glass-ceramic contains a proportion of silicon dioxide (SiO₂) of at least 60 mol %, optionally at least 60.5 mol %, also optionally at least 61 mol %, also optionally at least 61.5 mol %, optionally at least 62.0 mol %. The proportion of SiO₂ is at most 71 mol % or less than 71 mol %, optionally at most 70 mol % or less than 70 mol %, optionally at most 69 mol %, and also optionally at most 68.5 mol %. In the case of relatively large proportions of SiO₂, the mixture is more difficult to melt and the viscosity of the melt is higher, which can lead to problems with the homogenization of the melts in large-scale industrial production plants. Therefore, a content of 71 mol %, optionally 70 mol %, should not be exceeded. If the viscosity of a melt is high, the processing temperature Va of the melt increases. Very high temperatures are required for refining and homogenizing the melt, but they lead to corrosion of the linings of the melting equipment owing to the increasing aggressiveness of the melt with temperature. Moreover, even relatively high temperatures may not be sufficient to produce a homogeneous melt, with the result that the green glass may have streaks and inclusions (in particular bubbles and particles originating from the lining of the melting equipment), such that, after ceramization, the requirements on the homogeneity of the properties of the glass-ceramic produced, for example the homogeneity of the coefficient of thermal expansion, are not met. For this reason, lower SiO₂ contents than the stated upper limit may be preferred.

The proportion of A1 2 0 3 may be at least 10 mol %, optionally at least 11 mol %, optionally at least 12 mol %, optionally at least 13 mol %, also optionally at least 14 mol %, also optionally at least 14.5 mol %, optionally at least 15 mol %. If the content is too low, no or too little low-expansion solid solution is formed. The proportion of A1 2 0 3 may be at most 22 mol %, optionally at most 21 mol %, optionally at most 20 mol %, optionally at most 19.0 mol %, optionally at most 18.5 mol %. An excessively high A1 2 0 3 content leads to an increased viscosity and promotes the uncontrolled devitrification of the material.

The glass-ceramic provided according to the invention can contain 0 to 6 mol % of P₂O₅, in some embodiments 0.1 to 6 mol %. The phosphate content P₂O₅ of the glass-ceramic can be at least 0.1 mol %, optionally at least 0.3 mol %, optionally at least 0.5 mol %, also optionally at least 0.6 mol %, optionally at least 0.7 mol %, optionally at least 0.8 mol %. P₂O₅ is incorporated essentially into the crystal phase of the glass-ceramic and has a positive effect on the expansion behavior of the crystal phase and hence of the glass-ceramic. In addition, the melting of the components and refining behavior of the melt are improved. However, if the P₂O₅ content is too high, the profile of the CTE-T curve in the temperature range of from 0° C. to 50° C. does not show an advantageous flat profile. Therefore, a maximum of 6 mol %, optionally a maximum of 5 mol %, optionally a maximum of 4 mol %, optionally less than 4 mol %, of P₂O₅ should be present in the glass-ceramic. According to some embodiments, the glass-ceramics can be free from P₂O₅.

Within the scope of the invention, certain sums and ratios of the components SiO₂, A1203 and/or P₂O₅, i.e. of the components which form the high quartz solid solution, may be conducive to the formation of a glass-ceramic according to the invention.

The total proportion in mol % of the base constituents of the LAS glass-ceramic, SiO₂ and Al₂O₃, may be at least 75 mol %, optionally at least 78 mol %, optionally at least 79 mol %, optionally at least 80 mol % and/or optionally at most 90 mol %, optionally at most 87 mol %, optionally at most 86 mol %, optionally at most 85 mol %. If this total is too high, the viscosity curve of the melt is shifted to higher temperatures, which is disadvantageous, as already explained above in connection with the component SiO₂. If the total is too low, too little solid solution is formed.

The total proportion in mol % of the base constituents of the LAS glass-ceramic, SiO₂, Al₂O₃ and P₂O₅, is optionally at least 77 mol %, optionally at least 81 mol %, optionally at least 83 mol %, optionally at least 84 mol % and/or optionally at most 91 mol %, optionally at most 89 mol %, optionally at most 87 mol %, optionally at most 86 mol %.

The ratio of the mol % proportions of P₂O₅ to SiO₂ is optionally at least 0.005, optionally at least 0.01, optionally at least 0.012 and/or optionally at most 0.1, optionally at most 0.08, optionally at most 0.07.

As a further constituent, the glass-ceramic contains at least 7 mol %, optionally at least 7.5 mol %, optionally at least 8 mol %, optionally at least 8.25 mol %, of lithium oxide (Li₂O). The proportion of Li₂O is limited to at most 9.4 mol %, optionally at most 9.35 mol %, optionally at most or less than 9.3 mol %. Li₂O is a constituent of the solid solution phase and contributes substantially to the thermal expansion of the glass-ceramic. The stated upper limit of 9.4 mol % should not be exceeded since otherwise glass-ceramics with a negative coefficient of thermal expansion CTE (0;50) result. If the Li₂O content is less than 7 mol %, too little solid solution is formed and the CTE of the glass-ceramic remains positive.

The glass-ceramic can contain at least one alkaline earth metal oxide selected from the group consisting of CaO, BaO, SrO, this group being referred to collectively as “RO”. The components from the group RO remain substantially in the amorphous glass phase of the glass-ceramic and can be important for maintaining the zero expansion of the ceramized material. If the sum of CaO+BaO+SrO is too high, the desired CTE (0;50) according to the invention is not achieved. Therefore, the proportion of RO is optionally at most 6 mol % or at most 5.5 mol %, optionally at most 5 mol %, optionally at most 4.5 mol %, optionally at most 4 mol %, optionally at most 3.8 mol %, optionally at most 3.5 mol %, and also optionally at most 3.2 mol %. If the glass-ceramic contains RO, an advantageous lower limit can be at least 0.1 mol %, optionally at least 0.2 mol %, optionally at least 0.3 mol %, also optionally at least 0.4 mol %. According to some embodiments, the glass-ceramics can be free from RO.

The proportion of CaO can optionally be at most 5 mol %, optionally at most 4 mol %, optionally at most 3.5 mol %, optionally at most 3 mol %, optionally at most 2.8 mol %, optionally at most 2.6 mol %. The glass-ceramic can advantageously contain at least 0.1 mol %, optionally at least 0.2 mol %, optionally at least 0.4 mol %, optionally at least 0.5 mol % of CaO. The glass-ceramic can advantageously contain at least 0.1 mol %, optionally at least 0.2 mol % and/or at most 4 mol %, optionally at most 3 mol %, optionally at most 2.5 mol %, optionally at most 2 mol %, optionally at most 1.5 mol %, also optionally at most 1.4 mol %, of the component BaO, which is a good glass former. The glass-ceramic can contain at most 3 mol %, optionally at most 2 mol %, optionally at most 1.5 mol %, optionally at most 1.3 mol %, optionally at most 1.1 mol %, optionally at most 1 mol %, also optionally at most 0.9 mol % and/or optionally at least 0.1 mol %, of SrO. According to some embodiments, the glass-ceramics are free from CaO and/or BaO and/or SrO.

Sodium oxide (Na₂O) and/or potassium oxide (K₂O) and/or cesium oxide (Cs₂O) and/or rubidium oxide (Rb₂O) are optionally contained in the glass-ceramic, i.e. Na₂O-free and/or K₂O-free and/or Cs₂O-free and/or Rb₂O-free variants are possible. The proportion of Na₂O can be at most 3 mol %, optionally at most 2 mol %, optionally at most 1.7 mol %, optionally at most 1.5 mol %, optionally at most 1.3 mol %, optionally at most 1.1 mol %. The proportion of K₂O can be at most 3 mol %, optionally at most 2.5 mol %, optionally at most 2 mol %, optionally at most 1.8 mol %, optionally at most 1.7 mol %. The proportion of Cs₂O can be at most 2 mol %, optionally at most 1.5 mol %, optionally at most 1 mol %, optionally at most 0.6 mol %. The proportion of Rb₂O can be at most 2 mol %, optionally at most 1.5 mol %, optionally at most 1 mol %, optionally at most 0.6 mol %. According to some embodiments, the glass-ceramics are free from Na₂O and/or K₂O and/or Cs₂O and/or Rb₂O.

Na₂O, K₂O, Cs₂O, Rb₂O can in each case and independently of one another be present in the glass-ceramic in a proportion of at least 0.1 mol %, optionally at least 0.2 mol %, optionally at least 0.5 mol %. The components Na₂O, K₂O, Cs₂O and Rb₂O remain substantially in the amorphous glass phase of the glass-ceramic and can be important for maintaining the zero expansion of the ceramized material.

Therefore, the sum R₂O of the contents of Na₂O, K₂O, Cs₂O and Rb₂O can be at least 0.1 mol %, optionally at least 0.2 mol %, optionally at least 0.3 mol %, optionally at least 0.4 mol %. A low R 2 0 content of optionally at least 0.2 mol % can help to increase the temperature range in which the expansion curve of the glass-ceramic exhibits a flat profile. The sum R 2 0 of the contents of Na₂O, K₂O, Cs₂O and Rb₂O can be at most 6 mol %, optionally at most 5 mol %, optionally at most 4 mol %, optionally at most 3 mol %, optionally at most 2.5 mol %. If the sum of Na₂O+K₂O+Cs₂O+Rb₂O is too small or too great, it may be possible that the CTE (0;50) desired according to the invention is not achieved. According to some embodiments, the glass-ceramics can be free from R20.

The glass-ceramic can contain a maximum of 0.35 mol % of magnesium oxide (MgO). A further upper limit can be a maximum of 0.3 mol %, a maximum of 0.25 mol %, a maximum of 0.2 mol %, a maximum of 0.15 mol %, a maximum of 0.1 mol % or a maximum of 0.05 mol %. In some embodiments, the glass-ceramics provided according to the invention are free from MgO. As already described above, the component MgO in the glass-ceramic causes thermal hysteresis in the temperature range of from 0° C. to 50° C. The less MgO the glass-ceramic contains, the less the hysteresis in the temperature range mentioned.

The glass-ceramic can contain a maximum of 0.5 mol % of zinc oxide (ZnO). A further upper limit can be a maximum of 0.45 mol %, a maximum of 0.4 mol %, a maximum of 0.35 mol %, a maximum of 0.3 mol %, a maximum of 0.25 mol %, a maximum of 0.2 mol %, a maximum of 0.15 mol %, a maximum of 0.1 mol % or a maximum of 0.05 mol %. In some embodiments, the glass-ceramics provided according to the invention are free from ZnO. As already described above as a finding of the inventors, the component ZnO in the glass-ceramic causes thermal hysteresis in the temperature range of from 0° C. to 50° C. The less ZnO the glass-ceramic contains, the less the hysteresis in the temperature range mentioned.

With regard to the hysteresis-free nature of the glass-ceramic provided according to the invention, it is important that the condition MgO+ZnO less than 0.6 mol % is satisfied. A further upper limit for the sum of MgO+ZnO can be a maximum of 0.55 mol %, a maximum of 0.5 mol % or less than 0.5 mol %, a maximum of 0.45 mol %, a maximum of 0.4 mol %, a maximum of 0.35 mol %, a maximum of 0.3 mol %, a maximum of 0.25 mol %, a maximum of 0.2 mol %, a maximum of 0.15 mol %, a maximum of 0.1 mol % or a maximum of 0.05 mol %.

The glass-ceramic also contains at least one crystal nucleating agent selected from the group consisting of TiO₂, ZrO₂, Ta₂O₅, Nb₂O₅, SnO₂, MoO₃, WO₃. The nucleating agent can be a combination of two or more of the components mentioned. Another exemplary nucleating agent can be HfO₂. In some embodiments, the glass-ceramic therefore comprises HfO₂ and at least one crystal nucleating agent selected from the group consisting of TiO₂, ZrO₂, Ta₂O₅, Nb₂O₅, SnO₂, MoO₃, WO₃. The sum of the proportions of the nucleating agents is optionally at least 1.5 mol %, optionally at least 2 mol % or more than 2 mol %, optionally at least 2.5 mol %, according to some variants at least 3 mol %. An upper limit can be a maximum of 6 mol %, optionally a maximum of 5 mol %, optionally a maximum of 4.5 mol % or a maximum of 4 mol %. In some variants, the stated upper and lower limits apply to the sum of TiO2 and ZrO2

The glass-ceramic can contain titanium oxide (TiO2), optionally in a proportion of at least 0.1 mol %, optionally at least 0.5 mol %, optionally at least 1.0 mol %, optionally at least 1.5 mol %, optionally at least 1.8 mol % and/or optionally at most 5 mol %, optionally at most 4 mol %, optionally at most 3 mol %, optionally at most 2.5 mol %, optionally 2.3 mol %. TiO₂ -free variants of the glass-ceramic provided according to the invention are possible.

The glass-ceramic can also contain at most 3 mol %, optionally at most 2.5 mol %, optionally at most 2 mol %, optionally at most 1.5 mol % or at most 1.2 mol %, of zirconium oxide (ZrO₂). ZrO₂ can optionally be present in a proportion of at least 0.1 mol %, optionally at least 0.5 mol %, at least 0.8 mol % or at least 1.0 mol %. ZrO₂-free variants of the glass-ceramic provided according to the invention are possible.

According to some variants, from 0 to 5 mol %, individually or in total, of Ta₂O₅ and/or Nb₂O₅ and/or SnO₂ and/or MoO₃ and/or WO₃ can be present in the glass-ceramic and can be used, for example, as alternative or additional nucleating agents or for modulating the optical properties, for example the refractive index. HfO₂ can likewise be an alternative or additional nucleating agent. For modulation of the optical properties, some variants can contain Gd₂O₃, Y₂O₃, HfO₃, Bi₂O₃, and/or GeO₂, for example.

The glass-ceramic can further comprise one or more conventional refining agents selected from the group consisting of As₂O₃, Sb₂O₃, SnO₂, SO₄²⁻, F⁻, Cl⁻, Br⁻, or a mixture thereof, in a proportion of more than 0.05 mol % or at least 0.1 mol % and/or at most 1 mol %. However, the refining agent fluorine can reduce the transparency of the glass-ceramic, and therefore this component, if it is present, may be limited to a maximum of 0.5 mol %, optionally a maximum of 0.3 mol %, optionally a maximum of 0.1 mol %. The glass-ceramic is optionally free from fluorine.

Some embodiments provided according to the invention provide an LAS glass-ceramic, in particular for a precision EUVL component or an EUVL precision component, wherein the glass-ceramic has As₂O₃ as refining agent.

In some embodiments of the LAS glass-ceramic or of the precision EUVL component, the LAS glass-ceramic contains a maximum of 0.05 mol % of As₂O₃ as refining agent. In some embodiments, the As₂O₃ content in the glass-ceramic is ≤0.04 mol %, optionally ≤0.03 mol %, optionally ≤0.025 mol %, optionally ≤0.02 mol %, optionally ≤0.015 mol %. It is advantageous if the glass-ceramic contains as little As₂O₃ as possible. Some variants of the glass-ceramic are substantially As₂O₃-free, wherein “substantially As₂O₃-free or As-free” means that the component As₂O₃ is not intentionally added to the composition as a component but is at most contained as an impurity, wherein for As₂O₃-free glass-ceramics an impurity limit for As₂O₃ is ≤0.01 mol %, optionally □0.005 mol %. According to some embodiments, the glass-ceramic is free from As₂O₃.

It has been found that in the ranges specified by the invention it is surprisingly possible to obtain zero-expansion and hysteresis-free glass-ceramics, even if the glass-ceramic is refined in a more environmentally friendly manner according to some embodiments, i.e. contains a maximum of 0.05 mol % of As₂O₃ and is optionally substantially free from As₂O₃.

In order to provide the embodiments of the hysteresis-free and zero-expansion glass-ceramic despite the reduced As₂O₃ content or in the desired internal quality even without the use of As₂O₃, in particular with a low number of bubbles and few streaks, some embodiments use at least one chemical refining agent.

In some embodiments, the glass-ceramic can have at least one alternative redox refining agent and/or at least one evaporation refining agent and/or at least one decomposition refining agent instead of As₂O₃ or in addition to the small proportion of As₂O₃ (a maximum of 0.05 mol %) as a chemical refining agent. Since As₂O₃ is also a redox refining agent, redox refining agents which are used as an alternative or in addition to As₂O₃ are referred to within the scope of the invention as “alternative redox refining agents”.

In some variants, the total content of the chemical refining agents that can be detected in the glass-ceramic (without the content of As₂O₃- if As₂O₃ is present in the glass-ceramic) can be in the range of from 0 mol % to 1 mol %. In some embodiments, the total content of the refining agents that can be detected in the glass-ceramic (without As₂O₃) is more than 0.01 mol %, optionally at least 0.05 mol %, optionally at least 0.1 mol %, optionally at least 0.15 mol %, optionally at least 0.2 mol % and/or at most 1 mol %, optionally at most 0.7 mol %, optionally at most 0.5 mol %, optionally at most 0.4 mol %. Some variants can also contain at most 0.3 mol %, optionally at most 0.25 mol % or at most 0.2 mol % of refining agent. The proportions of the respective components can be detected in an analysis of the glass-ceramic. This applies especially to all the refining agents mentioned below with the exception of the sulfate component described.

Redox refining agents contain multivalent or polyvalent ions, which can occur in at least two oxidation states, which are in a temperature-dependent equilibrium with one another, wherein a gas, usually oxygen, is released at high temperatures. Certain multivalent metal oxides can therefore be used as redox refining agents. In some variants, the alternative redox refining agent can be at least one component selected from the group consisting of Sb₂O₃, SnO₂, CeO₂. MnO₂, Fe₂O₃. In principle, however, other redox compounds are also suitable if they release their refining gas in the temperature range relevant for refining and either change into an oxide having a different valence state of the metal ion or into a metallic form. Numerous such compounds are described in DE 19939771 A, for example. Preference may be given to an alternative redox refining agent which gives off refining gas, in particular oxygen, at a temperature of less than 1700° C., such as, for example, Sb₂O₃, SnO₂, CeO₂.

An analysis of the glass-ceramic can be used to determine the content of As₂O₃ and/or the content of the at least one alternative redox refining agent, from which experts can draw conclusions as to the type and quantity of refining agent used. The alternative redox refining agents can be added to the mixture as oxides, for example.

In some variants, the total content of the alternative redox refining agents can be in the range of from 0 mol % to 1 mol %. In some embodiments, the total content of the alternative redox refining agents that can be detected in the glass-ceramic is more than 0.01 mol %, optionally at least 0.05 mol %, optionally at least 0.1 mol %, optionally at least 0.15 mol %, optionally at least 0.2 mol % and/or at most 1 mol %, optionally at most 0.7 mol %, optionally at most 0.5 mol %, optionally at most 0.4 mol %. Some variants can also contain at most 0.3 mol %, optionally at most 0.25 mol % or at most 0.2 mol % of an alternative redox refining agent.

The glass-ceramic can contain 0 mol % to 1 mol % of antimony oxide (Sb₂O₃) as an alternative redox refining agent. In some embodiments, the glass-ceramic contains more than 0.01 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %, of Sb₂O₃. Since Sb₂O₃ is considered to be environmentally hazardous, it may be advantageous to use as little Sb₂O₃ as possible for the refining process. One exemplary embodiment of the glass-ceramic is substantially Sb₂O₃-free or Sb-free, wherein “substantially Sb₂O₃-free” means that Sb₂O₃ is not intentionally added to the composition as a raw material component but is at most contained as an impurity, wherein, for Sb₂O₃-free glass-ceramics, an impurity limit is a maximum of 0.01 mol %, optionally a maximum of 0.005 mol %. According to some embodiments, the glass-ceramic is Sb₂O₃-free.

The glass-ceramic can contain 0 mol % to 1 mol % of tin oxide (SnO₂) as an alternative redox refining agent. In some embodiments, the glass-ceramic contains more than 0.01 mol %, optionally at least 0.05 mol %, optionally at least 0.1 mol %, optionally at least 0.15 mol %, optionally at least 0.2 mol %, optionally at least 0.3 mol % and/or optionally at most 1 mol %, optionally at most 0.7 mol %, optionally at most 0.6 mol %, of SnO₂. In some variants, an upper limit of at most 0.5 mol %, optionally at most 0.4 mol %, optionally at most 0.3 mol % can be advantageous. If the content of SnO₂ is too high, it may be possible that the ceramization process of the green glass is more difficult to control since, at higher contents, SnO₂ acts not only as a refining agent but also as a crystal nucleating agent. SnO₂-free or Sn-free variants of the glass-ceramic provided according to the invention are possible and advantageous, i.e. no Sn-containing raw material was added to the mixture to refine the underlying green glass, wherein a limit for contamination by SnO₂ introduced by raw materials or the process is a maximum of 0.01 mol %, optionally a maximum of 0.005 mol %.

The glass-ceramic can contain 0 mol % to 1 mol % of CeO₂ and/or MnO₂ and/or Fe₂O₃as an alternative redox refining agent. These components can be present in each case and independently of one another, optionally in a proportion of more than 0.01 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %. Some variants of the glass-ceramic are free from CeO₂ and/or MnO₂ and/or Fe₂O₃, i.e. no Ce-containing raw material and/or Mn-containing raw material and/or Fe-containing raw material was added to the mixture to refine the underlying green glass, wherein a limit for contamination by CeO₂ and/or MnO₂ and/or Fe₂O₃ introduced by raw materials or the process is a maximum of 0.01 mol %, optionally a maximum of 0.005 mol %.

Evaporation refining agents are components which are volatile at high temperatures on account of their vapor pressure, with the result that the gas formed in the melt develops a refining action.

In some variants, the evaporation refining agent can have a halogen component.

In some variants, the evaporation refining agent can comprise at least one halogen with a refining action, in particular one selected from the group consisting of chlorine (Cl), bromine (Br) and iodine (I). Fluorine is not a halogen with a refining action since it is already volatile at excessively low temperatures. The glass-ceramic can nevertheless contain fluorine. However, the fluorine may reduce the transparency of the glass-ceramic, and therefore this component, if it is present, is optionally limited to a maximum of 0.5 mol %, optionally a maximum of 0.3 mol %, optionally a maximum of 0.1 mol %. The glass-ceramic is optionally free from fluorine.

The halogen with a refining action can be added in different forms. In some embodiments, it is added to the mixture as a salt with an alkali metal cation or alkaline earth metal cation or as aluminum halogen. In some embodiments, the halogen is used as a salt and the cation in the salt corresponds to a cation present as an oxide in the glass-ceramic. The halogen with a refining action can be used in the form of a halogen compound, in particular a halide compound. Suitable halide compounds are, in particular, salts of chlorine anions, bromine anions and/or iodine anions with alkali metal cations or alkaline earth metal cations or aluminum cations. Examples are chlorides such as LiCl, NaCl, KCl, CaCl₂, BaCl₂, SrCl₂, AlCl₃ and combinations thereof. Corresponding bromides and iodides such as LiBr, LiI, NaBr, NaI, KBr, KI, CaI₂, CaBr₂ and combinations thereof are also possible. Other examples are BaBr₂, BaI₂, SrBr₂, SrI₂ and combinations thereof.

In some variants, the total content of halogen with a refining action (that is to say Cl and/or Br and/or I) can be in the range of from 0 mol % to 1 mol %. In some embodiments, the total content of halogen with a refining action which can be detected in the glass-ceramic is more than 0.03 mol %, optionally at least 0.04 mol %, optionally at least 0.06 mol %, optionally at least 0.08 mol %, optionally at least 0.1 mol %, optionally at least 0.15 mol %, optionally at least 0.2 mol % and/or at most 1 mol %, optionally at most 0.7 mol %, optionally at most 0.5 mol %, optionally at most 0.4 mol %. Some variants can also contain at most 0.3 mol %, optionally at most 0.25 mol % or at most 0.2 mol %, of halogen with a refining action. The contents stated refer to the quantities of halogen detectable in the glass-ceramic. It is a matter of routine for those skilled in the art to use these data to calculate the amount of halogen or halide compound required for refining.

The glass-ceramic can contain from 0 mol % to 1 mol % of chlorine (determined atomically and indicated as Cl). In some embodiments, the glass-ceramic contains more than 0.03 mol %, optionally at least 0.04 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %, of Cl. Some glass-ceramics can be free from Cl, i.e. no Cl-containing raw material was added to the mixture to refine the underlying green glass. Cl is at most present as an impurity, wherein the limit for Cl contamination is a maximum of 0.03 mol %.

The same stated ranges and limits apply to Br as a halogen with a refining action. The same stated ranges and limits apply to I as a halogen with a refining action. Some variants of the glass-ceramic are free from Br and/or I.

As an alternative or in addition to an evaporation refining agent and/or an alternative redox refining agent, the chemical refining agent can contain at least one decomposition refining agent. A decomposition refining agent is an inorganic compound which decomposes at high temperatures, releasing refining gas, and the decomposition product has a sufficiently high gas pressure, in particular greater than 10⁵ Pa. The decomposition refining agent can optionally be a salt containing an oxo anion, in particular a sulfate component. The decomposition refining agent optionally comprises a sulfate component. Decomposition of the component added as a sulfate results in the release of SO₂ and O₂ at high temperatures, which contribute to the refining of the melt.

A sulfate component can be added in different forms. In some embodiments, it is added to the mixture as a salt with an alkali metal cation or alkaline earth metal cation. In some embodiments, the sulfate is used as a salt and the cation in the salt corresponds to a cation present as an oxide in the glass-ceramic. By way of example, the following components can be used as a sulfate source: Li₂SO₄, Na₂SO₄, K₂SO₄, CaSO₄, BaSO₄, SrSO₄.

Within the scope of the invention, sulfate is determined as SO₃ in material analysis. However, since LAS glass-ceramics have only a very low solubility for sulfate, the sulfate component (i.e. SO₃) in the melt product can no longer be detected after melting by the usual X-ray fluorescence analysis. Therefore, in the case of sulfate-refined exemplary embodiments (see below), it is indicated how many mol % of SO₄²⁻ or mol % of SO₃ have been used, based on the synthesis of the glass melt. The fact that a sulfate component has been used as refining agent can be determined, for example, by analyzing the residual gas content (SO₂) in the glass-ceramic.

During synthesis, more than 0.01 mol %, optionally at least 0.05 mol %, optionally at least 0.1 mol %, optionally at least 0.15 mol %, optionally at least 0.2 mol % and/or optionally at most 1 mol %, optionally at most 0.7 mol %, optionally at most 0.5 mol %, optionally at most 0.4 mol %, optionally at most 0.3 mol %, of SO₃, were added by way of at least one corresponding sulfate compound to an glass-ceramic which has been refined with a sulfate component. Sulfate-free (i.e. SO₃-free or SO₄²⁻-free) refined glass-ceramics are possible and may be advantageous. The proportion of refining sulfate added in the synthesis of a glass-ceramic can thus be in the range of from 0 mol % to 1 mol % of SO₃.

According to some embodiments provided according to the invention, the glass-ceramic or the underlying glass can be refined using a suitable metal sulfide as a decomposition refining agent, as described, for example, in US 2011/0098171 A. In some embodiments, the cation in the sulfide corresponds to a cation present as an oxide in the glass-ceramic. Examples of suitable metal sulfides are alkali metal sulfide, alkaline earth metal sulfide and/or aluminum sulfide, which release SO₃ in the melt under oxidizing conditions. In order for a metal sulfide to be able to fulfill the role as a refining agent well, it may be advantageously used in combination with an oxidizing agent, optionally a nitrate, and/or sulfate.

Glass-ceramics having a reduced As₂O₃ content, or As₂O₃-free glass-ceramics, can have a combination of chemical refining agents. In this context, the following combinations can be advantageous, the respective glass-ceramic optionally having the stated refining agents within the abovementioned limits for the individual components and/or the sums. Exemplary embodiments comprise:
SnO₂ and/or Sb₂O₃ each with a maximum of 0.05 mol % of As₂O₃; or
As₂O₃-free combinations such as: Sb₂O₃ with SnO₂; Sb₂O₃ with Cl, Sb₂O₃ with SO₃; or
As₂O₃-free and Sb₂O₃-free combinations such as: SnO₂ with Cl, SnO₂ with SO₃, Cl with SO₃.

Alternatively, glass-ceramics refined with only one refining agent can also be advantageous, for example glass-ceramics which contain only Sb₂O₃ or only SnO₂ as a refining agent.

Alternatively or in addition to the above-described refining of the melt with chemical refining agents, the principle of which lies in the addition of compounds which decompose and release gases or which are volatile at higher temperatures or which give off gases in an equilibrium reaction at higher temperatures, it is also possible to use known physical refining processes, e.g. reducing the viscosity of the glass melt by increasing the temperature, vacuum refining, high-pressure refining, etc.

In some embodiments provided according to the invention, the batch can contain nitrates (NO₃), which act as oxidizing agents in the melting and refining process and ensure that oxidizing conditions are present in the melt in order to increase the effectiveness of the refining agents used, in particular of the alternative redox refining agents. In some embodiments, the nitrate is used as a salt and the cation in the salt corresponds to a cation present as an oxide in the glass-ceramic. Examples thereof can be: aluminum nitrate, alkali metal nitrate, alkaline earth metal nitrate, zirconium nitrate, but ammonium nitrate can also serve as a nitrate source. A nitrate compound or a mixture of several nitrate compounds can be used. If the batch contains a nitrate compound or a mixture of nitrate compounds to support the refining process, the total NO₃ is optionally at least 0.4 mol %, optionally at least 0.5 mol %, optionally at least 0.8 mol %, optionally at least 1 mol % and/or optionally at most 5 mol %, optionally at most 4 mol %. In some variants, at most 3 mol % of nitrate can also be used. Nitrate can no longer be detected in the glass or glass-ceramic owing to the volatility. The above glass compositions may optionally contain additions of coloring oxides,

such as, for example, Nd₂O₃, Fe₂O₃, CoO, NiO, V₂O₅, MnO₂, CuO, CeO₂, Cr₂O₃, or rare earth oxides, in amounts of in each case individually or in total 0−3 mol %. Some variants are free from coloring oxides.

B₂O₃ can have a negative effect on the transparency of the glass-ceramic. Therefore, in some variants, the content of this component is limited to <0.2 mol %, optionally at most 0.1 mol %. Some variants are free from B₂O₃.

According to some embodiments provided according to the present invention, the composition is free from components which have not been mentioned above.

According to some embodiments provided according to the present invention, the glass-ceramic according to the invention or the green glass optionally comprises at least 90 mol %, optionally at least 95 mol %, optionally at least 99 mol % of the abovementioned components or optionally of the components SiO₂, Al₂O₃, Li₂O, P₂O₅, R₂O, RO and nucleating agents.

According to some embodiments of the glass-ceramic, it is substantially free from one or more glass components selected from the group consisting of MgO, ZnO, PbO, B₂O₃, CrO₃, F, Cd compounds.

According to the invention, the expression “X-free” or “free from a component X” means that the glass-ceramic essentially does not contain this component X, i.e. that such a component is present at most as an impurity in the glass but is not added to the composition as an individual component. With regard to contamination, in particular with MgO and/or ZnO, a limit of 0.03 mol %, optionally 0.01 mol %, based on a single component in each case, should not be exceeded in the case of MgO-free and/or ZnO-free variants. In the case of other glass components, higher impurity contents of up to a maximum of 0.1 mol %, optionally a maximum of 0.05 mol %, optionally a maximum of 0.01 mol %, optionally a maximum of 0.005 mol %, for some components optionally a maximum of 0.003 mol %, may be possible, based in each case on one component. Here, X stands for any desired component, such as, for example, PbO. These stated limits do not refer to the refining agents, for which separate contamination limits are described above.

The glass-ceramics provided according to the invention have high quartz solid solution as the main crystal phase. The main crystal phase is the crystalline phase which has the largest proportion by volume in the crystal phase. High quartz solid solution is a metastable phase which, depending on the crystallization conditions, changes its composition and/or structure or is converted into another crystal phase. The high quartz-containing solid solutions have a very low thermal expansion or even a thermal expansion which decreases as the temperature rises. In some embodiments, the crystal phase contains no β-spodumene and no keatite.

Some embodiments of the LAS glass-ceramic have a crystal phase content of less than 70 vol % and/or more than 45 vol %. The crystal phase consists of high quartz solid solution, which is also referred to as β-eucryptite solid solution. The average crystallite size of the high quartz solid solution may be <100 nm, optionally <80 nm, optionally <70 nm. The small crystallite size has the effect that the glass-ceramic is transparent and can also be better polished. In some variants, the average crystallite size of the high quartz solid solution can be ≤60 nm, optionally ≤50 nm. The crystal phase, the proportion thereof and the average crystallite size are determined in a known manner by X-ray diffraction analysis.

According to some embodiments provided according to the present invention, a transparent glass-ceramic is produced. By virtue of the transparency, many properties of such a glass-ceramic, in particular of course its internal quality, can be better assessed. The glass-ceramics provided according to the invention are transparent, i.e. they have an internal transmittance of at least 70% in the wavelength range of from 350 to 650 nm. B₂O₃ and/or higher fluorine contents can reduce transparency. Therefore, some variants do not contain one or both of the components mentioned. Furthermore, the glass-ceramics produced within the scope of the invention are free from pores and cracks. Within the scope of the invention, “free from pores” means a porosity of less than 1%, optionally less than 0.5%, optionally less than 0.1%. A crack is a gap, i.e. discontinuity, in an otherwise continuous structure.

To enable the production of a homogeneous glass-ceramic in a large-scale industrial production plant, it may be advantageous if the processing temperature Va of the green glass on which the glass-ceramic is based (and thus of the glass-ceramic) is a maximum of 1330° C., optionally a maximum of 1320° C. Some variants can have a processing temperature of a maximum of 1310° C. or a maximum of 1300° C. or less than 1300° C. The processing temperature Va is the temperature at which the melt has a viscosity of 10⁴ dPas. Homogeneity refers, in particular, to the homogeneity of the CTE of the glass-ceramic over a large volume and a small number, optionally freedom from inclusions such as bubbles and particles. This is a quality feature of glass-ceramics and a prerequisite for use in precision EUVL components, especially in very large precision EUVL components.

The processing temperature is determined by the composition of the glass-ceramic. Since, in particular, the glass network-forming component SiO₂ is to be regarded as a decisive component for increasing viscosity and thus the processing temperature, the maximum SiO₂ content should be selected in accordance with the abovementioned specifications.

### CTE

The glass-ceramics provided according to the invention are zero-expansion (see Tables la and lb), i.e. they have an average coefficient of thermal expansion CTE of at most 0±0.1±10⁻⁶/K in the range of from 0 to 50° C. Some variants even have an average CTE of at most 0±0.05±10⁻⁶/K in the range of from 0 to 50° C. For certain applications, it may be advantageous if the average CTE is at most 0±0.1±10⁻⁶/K over a relatively wide temperature range, for example in the range of from −30° C. to +70° C., optionally in the range of from −40° C. to +80° C. Further details on the average and differential CTE have already been described above in connection with the precision EUVL component provided according to the invention. This disclosure content is fully incorporated into the description of the glass-ceramic.

### Thermal Hysteresis

Within the scope of the invention, the glass-ceramic has a thermal hysteresis of <0.1 ppm at least in the temperature range of from 19 to 25° C., optionally at least in the temperature range of from 10° C. to 25° C., optionally at least in the temperature range of from 10° C. to 35° C. and is therefore hysteresis-free (see FIGS. 10 and 11 and FIGS. 31 to 33). In some embodiments, this freedom from hysteresis is present at least in a temperature range of from 5 to 35° C., optionally at least in the temperature range of from 5 to 45° C., optionally at least in the temperature range of from >0° C. to 45° C., optionally at least in the temperature range of from -5° C. to 50° C. The temperature range of freedom from hysteresis may be even wider, making the material or the component also suitable for applications at temperatures of up to at least 100° C. and advantageously even above that.

Further details on the thermal hysteresis have already been described above in connection with the precision EUVL component provided according to the invention. This disclosure content is fully incorporated into the description of the glass-ceramic.

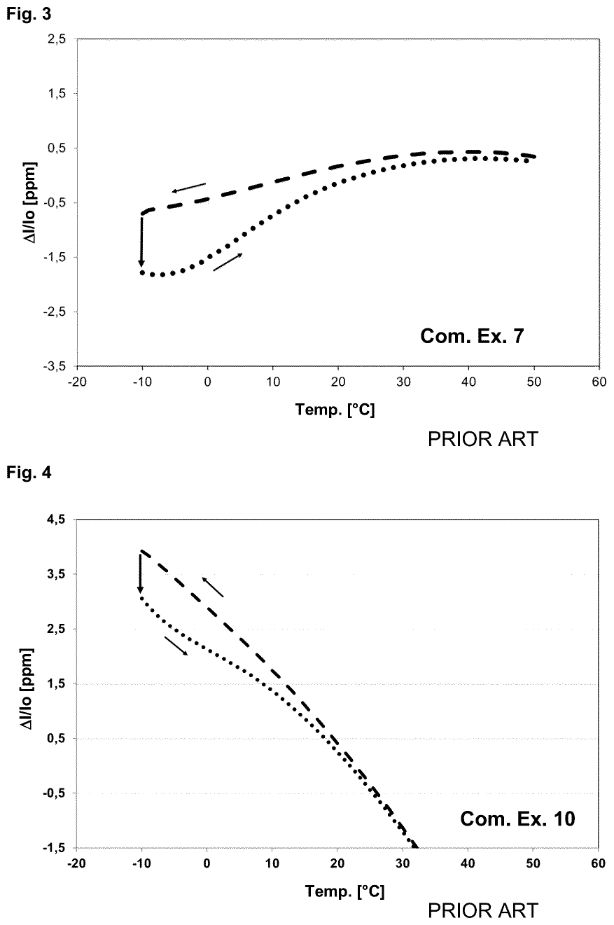

FIGS. 2 to 9 show the thermal expansion curves of known LAS glass-ceramics, the curves all being produced by the same method as the LAS glass-ceramics provided according to the invention (FIGS. 10 and 11 and FIGS. 31 to 33). In the case of the materials shown in FIGS. 3 to 8, the cooling curves (dashed lines) and heating curves (dotted lines) are in each case clearly spaced apart from one another precisely at lower temperatures. At 10° C., the difference is more than 0.1 ppm, and up to about 1 ppm in the case of individual comparative examples. In other words, the materials exhibit considerable thermal hysteresis in the relevant temperature range of at least 10° C. to 35° C.

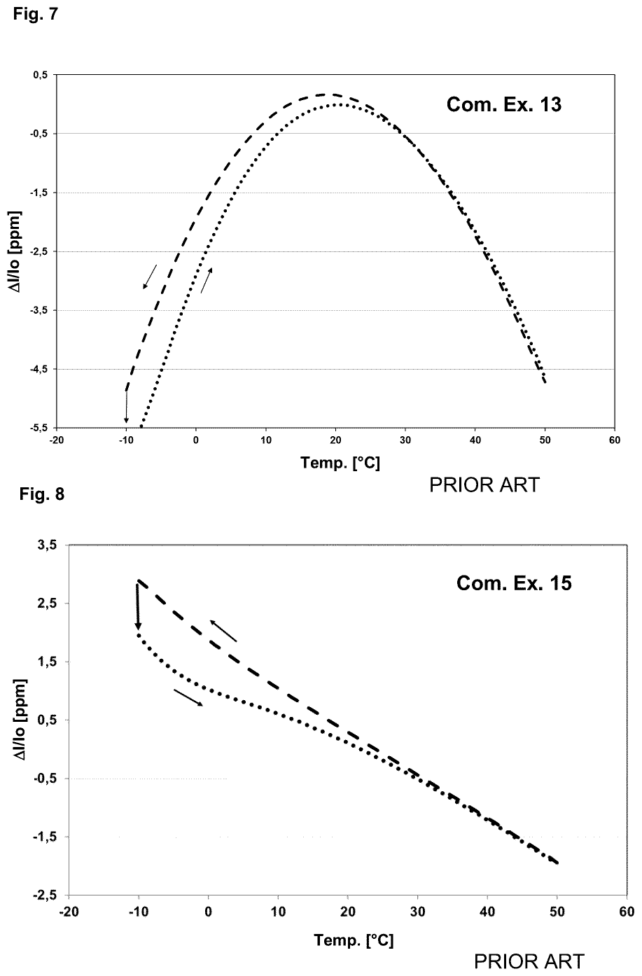

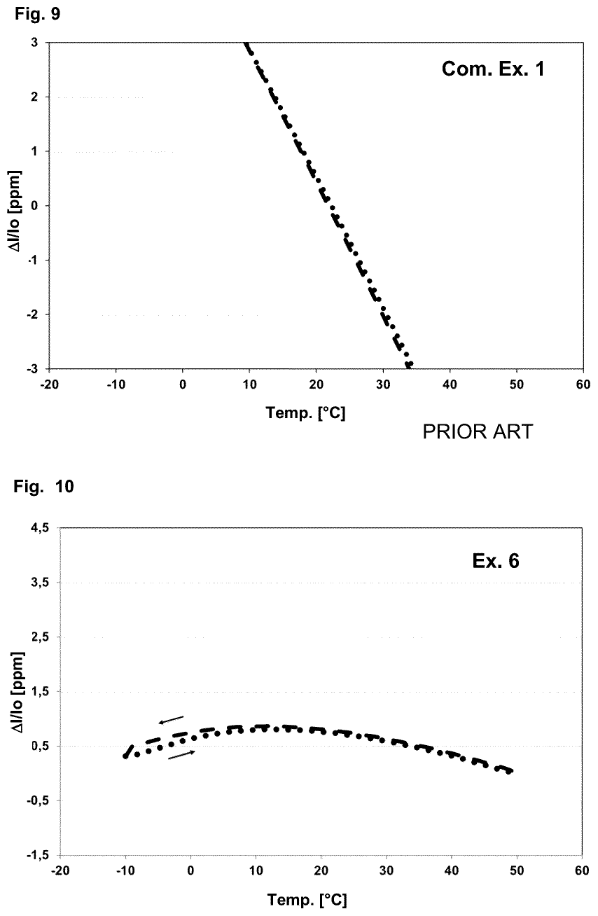

The LAS glass-ceramics investigated, which are shown in FIGS. 2 to 5 (comparative examples 7, 9 and 10 in table 2), all contain MgO and ZnO and have thermal hysteresis over wide ranges within the temperature interval 10° C. to 35° C. FIGS. 6 and 7 show the hysteresis curves of LAS glass-ceramics (comparative examples 8 and 14 in table 2) which are MgO-free but contain ZnO. Both materials exhibit strongly increasing thermal hysteresis below 15° C. FIG. 8 shows the hysteresis curve of an LAS glass-ceramic (comparative example 15 in table 2) which is ZnO-free but contains MgO. This material likewise exhibits a strongly increasing thermal hysteresis below 15° C. As can be seen in FIG. 9, this known material (comparative example 1 in table 2) has no thermal hysteresis, but the steep curve shows that it is not a zero-expansion material. The average CTE here is −0.24 ppm/K.

LAS glass-ceramics provided according to the invention have a very low content of MgO and/or ZnO or are optionally free from MgO and ZnO. As can be seen in FIGS. 10 and 11 as well as in FIGS. 31 to 33, the heating curves and the cooling curves lie one above the other at least in the temperature range of from 10° C. to 35° C. However, the materials are not only hysteresis-free in the range of from 10° C. to 35° C., but also at least in the range of from 5 to 35° C., optionally at least in the temperature range of from 5 to 45° C., optionally at least in the range of from >0° C. to 45° C. Example 7 from FIG. 11 is also hysteresis-free at least in the temperature range of from −5° C. to 50° C., optionally also at even higher and even lower temperatures.

### Index F

It may be advantageous if the expansion curve of the LAS glass-ceramic has a flat profile in the temperature range of from 0° C. to 50° C. As an indication of the extent to which the curve profile of the thermal expansion deviates from a single linear profile, the index F can be used as a measure of the flatness of the expansion curve, where F=TCL (0; 50° C.)/|expansion (0; 50° C.)|. It may thus be advantageous if the index F is <1.2, optionally <1.1, optionally at most 1.05. The closer the index F is to 1, the flatter the expansion curve. FIGS. 12, 13, 18 and 34 show that embodiments of the LAS glass-ceramic have a flat profile of the expansion curve (here F=1), both in the temperature range 0° C. to 50° C. and in the wider temperature range −30° C. to 70° C. In comparison, FIGS. 14 to 17 and 19 show that known materials exhibit a substantially steeper and curved profile of the expansion curves in the temperature ranges considered.

### Alternative index f_{T.i.}

For some variants, depending on the field of application of the component, a flat profile of the expansion curve can also be desired for another temperature interval (T.i.), optionally in the temperature range (20;40), (20;70) and/or (−10; 30). The alternative index f_{T.i.} has the unit (ppm/K) and is defined as f_{T.i.}=TCL (T)/width of the temperature interval (T.i.), where T.i. describes the respective temperature interval considered. It may be advantageous if the glass-ceramic has an alternative index f_{(20;40)}<0.024 ppm/K and/or an alternative index f_{(20;70)}<0.039 ppm/K and/or an alternative index f_{(-10;30)}<0.015 ppm/K, which can be seen in FIGS. 27 to 30, 35 and 36.

Further details on the index F and on the alternative index f_{T.i.} and on the relative change in length (dl/l₀) in the temperature ranges of from 20° C. to 30° C., from 20° C. to 35° C. and/or from 20° C. to 40° C. have already been described above in connection with the precision EUVL component provided according to the invention. This disclosure content is fully incorporated into the description of the glass-ceramic.

### Further Features

FIGS. 20 and 21 and also 37 to 41 show that some embodiments of the LAS glass-ceramic have a CTE plateau. A glass-ceramic with a plateau, i.e. with an optimized zero expansion over a wide temperature range, offers the same advantages which have already been described above in connection with the flat profile of the expansion curves and the index F and also the alternative index f_{T.i}.

It may be advantageous if the differential CTE has a plateau close to 0 ppm/K, i.e. the differential CTE is less than 0±0.025 ppm/K in a temperature interval T_{P} with a width of at least 40 K, optionally at least 50 K. The temperature interval of the CTE plateau is denoted by Tp. In some embodiments, the differential CTE can be less than 0±0.015 ppm/K in a temperature interval T_{P} with a width of at least 40 K.

FIGS. 22, 23 and 26 and also FIGS. 42 and 43, which have already been described above in connection with the precision EUVL component, show that some embodiments of the LAS glass-ceramic have CTE curves, the slope of which is advantageously very small in wide temperature ranges. It may be advantageous if the CTE-T curve in a temperature interval having a width of at least 30 K has a slope of ≤0±2.5 ppb/K², optionally ≤0±2 ppb/K², optionally ≤0 ±1.5 ppb/K², optionally ≤0±1 ppb/K², according to some variants ≤0±0.8 ppb/K², according to some variants even ≤0±0.5 ppb/K².

The feature of the low slope can be present with or without formation of an advantageous CTE plateau.

The glass-ceramic provided according to the invention or precision EUVL component made from the glass-ceramic provided according to the invention optionally has a modulus of elasticity, determined according to ASTM C 1259 (2021), of 75 GPa to 100 GPa, optionally of 80 GPa to 95 GPa. As already described above, the use of such precision EUVL components in “high-NA” EUVL units or in other EUVL units with increased wafer throughput is advantageous since, among other things, the dynamic positioning accuracy of the photomask can be increased by the higher modulus of elasticity.

Further details regarding the CTE plateau, the slope of the CTE-T curve, the zero crossing of the CTE-T curve and the adaptation of the CTE profile or the expansion profile to different application temperatures by varying the ceramization temperature and/or ceramization time (see, for example, FIGS. 24, 25, 44, 45), etc. have already been described above in connection with the precision EUVL component provided according to the invention. This disclosure content is fully incorporated into the description of the glass-ceramic.

### EXAMPLES

Tables 1a, 1b and 2 show compositions of examples of glass-ceramics provided according to the invention, especially for precision EUVL components, and compositions of comparative examples, and their properties.

The compositions stated in Table 1a were melted from commercial raw materials, such as oxides, carbonates and nitrates, in customary production processes. The green glasses produced according to Table 1a were first ceramized at the particular maximum temperature specified, for the specified time.

The production of the glass-ceramic for precision components, especially large precision components, is described for example in WO 2015/124710 A1.

Table 1a shows 23 examples (Ex.) provided according to the invention which are hysteresis-free at least in a temperature range from 10° C. to 35° C. and have zero expansion.

Examples 6, 18, 19 and 20 show an incipient thermal hysteresis only from around 0° C., examples 11, 17 and 23 only from −5° C. Examples 7, 12, 14, 15 and 22 are hysteresis-free over the entire temperature range from −5° C. to 45° C. Moreover, the index F is <1.2, meaning that the profile of the expansion curve in the temperature range of 0° C. to 50° C. is advantageously flat for all of the examples. Furthermore, the examples have a processing temperature ≤1330° C., allowing the glass-ceramics to be produced with high homogeneity in industrial-scale production plants. The processing temperatures as reported in Tables 1a, 1b and 2 were ascertained according to DIN ISO 7884−1 (2014—source: Schott Techn. Glas-Katalog).

In the case of example 5, after ceramization at not more than 780° C. over a time of 2.5 days, the average CTE was determined for further temperature intervals, with the following result: CTE (20; 300° C.): −0.17 ppm/K, CTE (20; 500° C.): −0.02 ppm/K, CTE (20; 700° C.): 0.17 ppm/K.

For example 7, the average CTE for the temperature range of 19° C. to 25° C. was determined, with the result that example 7 has a CTE (19;25) of −1.7 ppb/K.

The compositions stated in Table 1b were melted from commercial raw materials, such as oxides, carbonates and nitrates, in customary production processes, using different refining agents and refining agent combinations. In the context of the invention, As₂O₃ as a refining agent was significantly reduced, or refining agents without As₂O₃ were employed. In the case of example 7b, refined using SnO₂ and sulfate, 0.19 mol % of SO₃ in the form of Na₂SO₄ was added to the synthesis, corresponding when converted to 0.22 mol % of SO₄²⁻. In the x-ray fluorescence analysis of the green glass and of the glass-ceramic, the SO₃ content was below the detection limit of <0.02 wt %. The green glasses produced according to Table 1b were first ceramized at the particular indicated maximum temperature for the indicated time. For examples 6b and 7b, samples ceramized with different ceramization parameters (especially different maximum temperatures), as explained above already in connection with the figures, were also produced.

The production of a glass-ceramic for a precision component, especially a large precision component, is described for example in WO 2015/124710 A1.

Table 1b shows 15 examples (Ex.) of the invention which are hysteresis-free at least in a temperature range from 10° C. to 35° C. and have zero expansion. Examples 1b, 8b and 13b show an incipient thermal hysteresis only from around 5° C., examples 2b and 9b only from around −5° C. Examples 3b, 5b, 6b and 7b are hysteresis-free over the entire temperature range from −5° C. to 45° C. Moreover, the index F is <1.2, meaning that the profile of the expansion curve in the temperature range of 0° C. to 50° C. is advantageously flat for all of the examples. Furthermore, the examples have a processing temperature ≤1330° C., allowing the glass-ceramics to be produced with high homogeneity in industrial-scale production plants. The processing temperatures as reported in Tables 1a, 1b and 2 were ascertained according to DIN ISO 7884−1 (2014—source: Schott Techn. Glas-Katalog).

In the case of example 7b, after ceramization at not more than 810° C. over a time of 2.5 days, the average CTE was determined for further temperature intervals, with the following result: CTE (20; 300° C.): +0.13 ppm/K, CTE (20; 500° C.): +0.34 ppm/K, CTE (20; 700° C.): +0.59 ppm/K.

For examples 6b and 7b, the average CTE was determined for the temperature range of 19° C. to 25° C., with example 6b having a CTE (19;25) of 0.77 ppb/K and example 7b a CTE (19;25) of 0.37 ppb/K.

Example 10b was refined with SnO₂. Additionally, nitrate was present as oxidizing agent, and specifically the components BaO and Na₂O were each used as nitrate raw materials to render the melt oxidizing.

Example 15b was refined with SnO₂ SnO₂ served simultaneously as nucleating agent. A further nucleating agent was ZTO₂.

Table 2 shows comparative examples (Comp. Ex.). Comparative examples 1, 2, 5 and 6 include neither MgO nor ZnO, but the average CTE(0;50) is greater than 0±0.1×10⁻⁶/K, meaning that these comparative examples do not have zero expansion. In addition, comparative examples 1 and 2 have a processing temperature >1330° C. These materials are very viscous, and so it is not possible to use them to manufacture components having high homogeneity in industrial-scale production plants.

Comparative examples 7 to 13 and 15 all contain MgO and/or ZnO, and the majority of them have zero expansion. However, these comparative examples, at least in the temperature range of 10° C. to 35° C., show a thermal hysteresis of substantially more than 0.1 ppm. At room temperature, i.e., 22° C., this group of comparative examples have a thermal hysteresis, apart from comparative example 14. Comparative example 9, moreover, although it has zero expansion, has a disadvantageously steep expansion curve profile in the temperature range of 0° C. to 50° C., as evident from the high value for the index F.

Empty fields in the tables below, for the data relating to the composition, mean that this/these component(s) was/were not added deliberately or is/are not present.

Table 3a, for certain examples provided according to the invention from Table 1a and one comparative example, shows the calculated alternative index f_{(T.i.)} for various temperature intervals, from which it is apparent that the expansion curves of the examples in the temperature ranges designated each have a flatter profile than the comparative example.

Table 3b, for certain examples provided according to the invention from Table 1b and one comparative example, shows the calculated alternative index f_{(T.i.)} for various temperature intervals, from which it is apparent that the expansion curves of the examples in the temperature ranges designated each have a flatter profile than the comparative example.

Table 4a, for components having a composition according to example 7 provided according to the invention from Table 1a, shows the CTE homogeneity for various component sizes, from which it is apparent that the components investigated have advantageously high CTE homogeneities both in the temperature range of 0° C. to 50° C. and in the temperature range of 19 to 25° C. Furthermore, the elasticity modulus is reported (also called modulus of elasticity), ascertained according to ASTM C 1259 (2021).

Table 4b, for components having a composition according to example 6b provided according to the invention from Table 1b, shows the CTE homogeneity for various component sizes, from which it is apparent that the components investigated have advantageously high CTE homogeneities both in the temperature range of 0° C. to 50° C. and in the temperature range of 19 to 25° C. Furthermore, the elasticity modulus is reported (also called modulus of elasticity), ascertained according to ASTM C 1259 (2021).

To experts it is clear that—depending on the application temperature of the glass-ceramic or of the precision EUVL component comprising the glass-ceramic—a glass-ceramic having the desired properties, especially with regard to thermal hysteresis and/or average CTE and/or CTE homogeneity, is chosen. TABLES

TABLE 1a
Compositions, ceramization and properties (mol %)

Example No. (Ex.)

| | 1 | 2 | 3 | 4 | 5 | 6 |
|---|---|---|---|---|---|---|
| Li₂O | 8.5 | 8.6 | 8.65 | 8.75 | 9.0 | 8.7 |
| Na₂O | 0.6 | 0.5 | 0.5 | 0.4 | | 0.2 |
| K₂O | 1.65 | 1.6 | 1.65 | 1.45 | 0.75 | 0.6 |
| MgO | | | | | | |
| ZnO | | | | | | |
| CaO | 0.45 | 0.7 | 1.2 | 1.6 | 2.1 | 2.35 |
| BaO | | | | 0.4 | 0.4 | 0.75 |
| SrO | | | | | | |
| Al₂O₃ | 16.1 | 15.2 | 16.65 | 17.55 | 15.85 | 16.4 |
| SiO₂ | 68.1 | 67.95 | 66.5 | 65.1 | 65.5 | 65.2 |
| P₂O₅ | 1.35 | 2.25 | 1.65 | 1.6 | 3.05 | 2.5 |
| TiO₂ | 2.05 | 2.0 | 2.0 | 1.95 | 2.1 | 2.05 |
| ZrO₂ | 0.95 | 0.95 | 0.95 | 0.95 | 1.05 | 1.0 |
| As₂O₃ | 0.25 | 0.25 | 0.25 | 0.25 | 0.2 | 0.25 |
| Total | 100.0 | 100.0 | 100.0 | 100.0 | 100.0 | 100.0 |
| SiO₂ + (5 × Li₂O) | 110.60 | 110.95 | 109.75 | 108.85 | 110.50 | 108.70 |
| MgO + ZnO | | | | | | |
| ΣR₂O (R = Na, K, Cs, Rb) | 2.25 | 2.1 | 2.15 | 1.85 | 0.75 | 0.8 |
| ΣRO (R = Ca, Ba, Sr) | 0.45 | 0.7 | 1.2 | 2.0 | 2.5 | 3.10 |
| Va [° C.] | 1312 | 1318 | 1292 | 1271 | | 1275 |
| Ceram. temperature [° C.] | 760 | 780 | 780 | 760 | 780 | 770 |
| Ceram. time [days] | 2.5 | 2.5 | 2.5 | 2.5 | 2.5 | 2.5 |
| Cryst. phase [vol %] | 53 | 54 | 53 | 49 | 64 | 57 |
| Cryst. size [nm] | 39 | 40 | 45 | 42 | 40 | 40 |
| Av. CTE(0; +50° C.) [ppm/K] | 0.05 | 0.07 | 0.10 | 0.10 | −0.03 | 0.01 |
| TCL (0; +50° C.) | 2.47 | 3.41 | 5.22 | 5.1 | 1.64 | 0.57 |
| \|expansion at 50° C.\| | 2.47 | 3.41 | 5.22 | 5.1 | 1.64 | 0.57 |
| Index F | 1.00 | 1.00 | 1.00 | 1.00 | 1.00 | 1.00 |
| Hyst @ 45° C. [ppm] | <0.1 | <0.1 | <0.1 | <0.1 | <0.1 | <0.1 |
| Hyst @ 35° C. [ppm] | <0.1 | <0.1 | <0.1 | <0.1 | <0.1 | <0.1 |
| Hyst @ 30° C. [ppm] | <0.1 | <0.1 | <0.1 | <0.1 | <0.1 | <0.1 |
| Hyst @ 22° C. [ppm] | <0.1 | <0.1 | <0.1 | <0.1 | <0.1 | <0.1 |
| Hyst @ 10° C. [ppm] | <0.1 | <0.1 | <0.1 | <0.1 | <0.1 | <0.1 |
| Hyst @ +5° C. [ppm] | <0.1 | <0.1 | <0.1 | <0.1 | <0.1 | <0.1 |
| Hyst @ 0° C. [ppm] | | | | | | 0.1 |
| Hyst @ −5° C. [ppm] | | | | | | 0.16 |
| Ceram. temperature [° C.] | 760 | 780 | 780 | 760 | 800 | 780 |
| Ceram. time [days] | 2.5 | 2.5 | 2.5 | 2.5 | 2.5 | 2.5 |
| Av. CTE (−30; +70° C.)[ppm/K] | 0.03 | 0.06 | 0.09 | 0.08 | 0.02 | 0.01 |
| Av. CTE (−40; +80° C.)[ppm/K] | 0.02 | 0.05 | 0.08 | 0.08 | 0.004 | 0.006 |

| | Example No. (Ex.) | | | | | |
|---|---|---|---|---|---|---|
| | 7 | 8 | 9 | 10 | 11 | 12 |
| Li₂O | 9.15 | 9.0 | 8.9 | 9.25 | 8.35 | 9.3 |
| Na₂O | 0.6 | 0.45 | | 0.1 | 1.1 | 0.8 |
| K₂O | 0.9 | 0.5 | | 0.65 | | 0.2 |
| MgO | | | | | | |
| ZnO | | | | | | |
| CaO | 0.95 | 2.5 | 2.5 | 1.8 | 1.1 | |
| BaO | 0.55 | | | 0.6 | 0.85 | 1.4 |
| SrO | | | 0.6 | | 0.8 | |
| Al₂O₃ | 17.95 | 17.3 | 17.2 | 18.35 | 17.4 | 17.9 |
| SiO₂ | 64.0 | 63.05 | 64.55 | 62.55 | 66.35 | 64.1 |
| P₂O₅ | 2.6 | 3.85 | 2.9 | 3.35 | 0.8 | 2.85 |
| TiO₂ | 2.05 | 2.05 | 2.1 | 2.05 | 2.0 | 2.15 |
| ZrO₂ | 1.0 | 1.05 | 1.05 | 1.05 | 1.0 | 1.05 |
| As₂O₃ | 0.25 | 0.25 | 0.25 | 0.25 | 0.25 | 0.25 |
| Total | 100.0 | 100.0 | 100.0 | 100.0 | 100.0 | 100.0 |
| SiO₂ + (5 × Li₂O) | 109.75 | 108.05 | 109.05 | 108.80 | 108.10 | 110.60 |
| MgO + ZnO | | | | | | |
| ΣR₂O (R = Na, K, Cs, Rb) | 1.50 | 0.95 | | 0.75 | 1.1 | 1.0 |
| ΣRO (R = Ca, Ba, Sr) | 1.5 | 2.5 | 3.1 | 2.4 | 2.75 | 1.4 |
| Va [° C.] | 1267 | 1256 | 1258 | 1248 | | |
| Ceram. temperature [° C.] | 810 | 800 | 800 | 810 | 780 | 820 |
| Ceram. time [days] | 2.5 | 2.5 | 2.5 | 2.5 | 2.5 | 2.5 |
| Cryst. phase [vol %] | 58 | 62 | 64 | 64 | 52 | 60 |
| Cryst. size [nm] | 48 | 47 | 45 | 46 | 47 | 47 |
| Av. CTE(0; +50° C.) [ppm/K] | 0.007 | 0.06 | −0.08 | −0.08 | −0.03 | −0.08 |
| TCL (0; +50° C.) | 0.37 | 3 | 3.88 | 3.89 | 1.34 | 3.96 |
| \|expansion at 50° C.\| | 0.37 | 2.88 | 3.78 | 3.89 | 1.34 | 3.96 |
| Index F | 1.00 | 1.04 | 1.03 | 1.00 | 1.00 | 1.00 |
| Hyst @ 45° C. [ppm] | <0.1 | <0.1 | <0.1 | <0.1 | <0.1 | <0.1 |
| Hyst @ 35° C. [ppm] | <0.1 | <0.1 | <0.1 | <0.1 | <0.1 | <0.1 |
| Hyst @ 30° C. [ppm] | <0.1 | <0.1 | <0.1 | <0.1 | <0.1 | <0.1 |
| Hyst @ 22° C. [ppm] | <0.1 | <0.1 | <0.1 | <0.1 | <0.1 | <0.1 |
| Hyst @ 10° C. [ppm] | <0.1 | <0.1 | <0.1 | <0.1 | <0.1 | <0.1 |
| Hyst @ +5° C. [ppm] | <0.1 | <0.1 | <0.1 | <0.1 | <0.1 | <0.1 |
| Hyst @ 0° C. [ppm] | <0.1 | | | | <0.1 | <0.1 |
| Hyst @ −5° C. [ppm] | <0.1 | | | | 0.15 | <0.1 |
| Ceram. temperature [° C.] | 820 | 780 | 800 | 810 | 780 | 820 |
| Ceram. time [days] | 2.5 | 2.5 | 2.5 | 2.5 | 2.5 | 2.5 |
| Av. CTE (−30; +70° C.)[ppm/K] | 0.03 | 0.006 | −0.08 | −0.07 | −0.05 | −0.10 |
| Av. CTE (−40; +80° C.)[ppm/K] | 0.02 | −0.01 | −0.10 | −0.08 | −0.05 | −0.1 |

| | Example No. (Ex.) | | | | | |
|---|---|---|---|---|---|---|
| | 13 | 14 | 15 | 16 | 17 | 18 |
| Li₂O | 9.1 | 9.35 | 8.9 | 8.6 | 9.05 | 8.7 |
| Na₂O | 0.1 | 0.45 | 0.45 | 0.65 | 0.6 | 0.9 |
| K₂O | 0.6 | 1.1 | 0.95 | 1.65 | 0.85 | 0.3 |
| MgO | | | | | 0.25 | |
| ZnO | | | | | 0.15 | 0.45 |
| CaO | 1.3 | 1.1 | 1.25 | | 0.85 | 0.65 |
| BaO | 1.1 | 0.4 | 1.05 | | 0.45 | 1.15 |
| SrO | | | | | | |
| Al₂O₃ | 17.9 | 18.85 | 16.95 | 16.35 | 18.0 | 18.1 |
| SiO₂ | 62.0 | 61.6 | 67.15 | 67.9 | 63.75 | 64.0 |
| P₂O₅ | 4.6 | 3.95 | | 1.6 | 2.75 | 2.45 |
| TiO₂ | 2.1 | 2.0 | 2.05 | 2.05 | 2.05 | 2.1 |
| ZrO₂ | 1.05 | 1.0 | 1.05 | 1.0 | 1.05 | 1.0 |
| As₂O₃ | 0.15 | 0.2 | 0.2 | 0.2 | 0.2 | 0.2 |
| Total | 100.0 | 100.0 | 100.0 | 100.0 | 100.0 | 100.0 |
| SiO₂ + (5 × Li₂O) | 107.50 | 108.35 | 111.65 | 110.90 | 109.00 | 107.50 |
| MgO + ZnO | | | | | 0.40 | 0.45 |
| ΣR₂O (R = Na, K, Cs, Rb) | 0.70 | 1.55 | 1.4 | 2.3 | 1.45 | 1.2 |
| ΣRO (R = Ca, Ba, Sr) | 2.40 | 1.50 | 2.3 | | 1.3 | 1.8 |
| Va [° C.] | | | | | | |
| Ceram. temperature [° C.] | 790 | 815 | 815 | 770 | 830 | 815 |
| Ceram. time [days] | 2.5 | 2.5 | 2.5 | 2.5 | 2.5 | 2.5 |
| Cryst. phase [vol %] | 62 | 61 | 53 | 52 | 59 | 59 |
| Cryst. size [nm] | 46 | 50 | 46 | 39 | 48 | 48 |
| Av. CTE(0; +50° C.) [ppm/K] | 0.08 | −0.01 | 0.08 | 0.04 | 0.01 | −0.015 |
| TCL (0; +50° C.) | 4.00 | 0.58 | 4.14 | 2.07 | 0.61 | 0.74 |
| \|expansion at 50° C.\| | 4.00 | 0.54 | 4.14 | 2.07 | 0.61 | 0.74 |
| Index F | 1.00 | 1.07 | 1.00 | 1.00 | 1.00 | 1.00 |
| Hyst @ 45° C. [ppm] | <0.1 | <0.1 | <0.1 | | <0.1 | <0.1 |
| Hyst @ 35° C. [ppm] | <0.1 | <0.1 | <0.1 | | <0.1 | <0.1 |
| Hyst @ 30° C. [ppm] | <0.1 | <0.1 | <0.1 | | <0.1 | <0.1 |
| Hyst @ 22° C. [ppm] | <0.1 | <0.1 | <0.1 | | <0.1 | <0.1 |
| Hyst @ 10° C. [ppm] | <0.1 | <0.1 | <0.1 | | <0.1 | <0.1 |
| Hyst @ +5° C. [ppm] | 0.11 | <0.1 | <0.1 | | <0.1 | <0.1 |
| Hyst @ 0° C. [ppm] | 0.19 | <0.1 | <0.1 | | <0.1 | 0.11 |
| Hyst @ −5° C. [ppm] | 0.22 | <0.1 | <0.1 | | 0.13 | 0.18 |
| Ceram. temperature [° C.] | 790 | 815 | | 770 | 820 | 815 |
| Ceram. time [days] | 2.5 | 2.5 | | 2.5 | 2.5 | 2.5 |
| Av. CTE (−30; +70° C.)[ppm/K] | 0.12 | −0.02 | | 0.02 | −0.06 | −0.03 |
| Av. CTE (−40; +80° C.)[ppm/K] | 0.11 | −0.04 | | 0.01 | −0.07 | −0.04 |

| | Example No. (Ex.) | | | | |
|---|---|---|---|---|---|
| | 19 | 20 | 21 | 22 | 23 |
| Li₂O | 9.15 | 8.1 | 9.35 | 9.15 | 8.85 |
| Na₂O | 0.55 | 0.4 | 0.7 | 0.45 | 0.55 |
| K₂O | 0.85 | 1.0 | 0.25 | 0.6 | 0.85 |
| MgO | 0.30 | | | | |
| ZnO | 0.20 | | | | |
| CaO | 0.8 | 2.25 | 1.25 | 0.8 | 1.0 |
| BaO | 0.45 | | 1.1 | 0.8 | 0.70 |
| SrO | | | | | |
| Al₂O₃ | 17.75 | 15.45 | 16.85 | 16.85 | 14.45 |
| SiO₂ | 64.0 | 68.05 | 64.45 | 67.35 | 67.95 |
| P₂O₅ | 2.75 | 1.55 | 3.35 | | 2.50 |
| TiO₂ | 2.0 | 1.95 | | 3.80 | 1.95 |
| ZrO₂ | 1.0 | 1.0 | 2.5 | | 1.0 |
| As₂O₃ | 0.2 | 0.25 | 0.2 | 0.2 | 0.2 |
| Total | 100.0 | 100.0 | 100.0 | 100.0 | 100.0 |
| SiO₂ + (5 × Li₂O) | 109.75 | 108.55 | 111.20 | 113.10 | 112.20 |
| MgO + ZnO | 0.5 | | | | |
| ΣR₂O (R = Na, K, Cs, Rb) | 1.4 | 1.4 | 0.95 | | 1.4 |
| ΣRO (R = Ca, Ba, Sr) | 1.25 | 2.25 | 2.35 | | 1.7 |
| Va [° C.] | | | | | |
| Ceram. temperature [° C.] | 815 | 770 | 810 | 825 | 800 |
| Ceram. time [days] | 2.5 | 2.5 | 2.5 | 2.5 | 2.5 |
| Cryst. phase [vol %] | 61 | 51 | 62 | 63 | 59 |
| Cryst. size [nm] | 50 | 33 | 76 | 33 | 42 |
| Av. CTE(0; +50° C.) [ppm/K] | −0.075 | 0.07 | −0.075 | −0.03 | 0.035 |
| TCL (0; +50° C.) | 3.73 | 3.38 | 3.75 | 1.7 | 1.77 |
| \|expansion at 50° C.\| | 3.73 | 3.38 | 3.75 | 1.7 | 1.77 |
| Index F | 1.00 | 1.00 | 1.00 | 1.00 | 1.00 |
| Hyst @ 45° C. [ppm] | <0.1 | <0.1 | <0.1 | <0.1 | <0.1 |
| Hyst @ 35° C. [ppm] | <0.1 | <0.1 | <0.1 | <0.1 | <0.1 |
| Hyst @ 30° C. [ppm] | <0.1 | <0.1 | <0.1 | <0.1 | <0.1 |
| Hyst @ 22° C. [ppm] | <0.1 | <0.1 | <0.1 | <0.1 | <0.1 |
| Hyst @ 10° C. [ppm] | <0.1 | <0.1 | <0.1 | <0.1 | <0.1 |
| Hyst @ +5° C. [ppm] | <0.1 | <0.1 | 0.12 | <0.1 | <0.1 |
| Hyst @ 0° C. [ppm] | 0.14 | 0.1 | 0.17 | <0.1 | <0.1 |
| Hyst @ −5° C. [ppm] | 0.21 | 0.17 | 0.21 | <0.1 | 0.11 |
| Ceram. temperature [° C.] | 815 | 770 | 810 | 825 | |
| Ceram. time [days] | 2.5 | 2.5 | 2.5 | 2.5 | |
| Av. CTE (−30; +70° C.)[ppm/K] | −0.09 | 0.05 | −0.09 | −0.05 | |
| Av. CTE (−40; +80° C.)[ppm/K] | −0.10 | 0.04 | −0.10 | −0.06 | |

TABLE 1b
Compositions, ceramization and properties (mol %)

| | Example No. (Ex.) | | | | | | | |
|---|---|---|---|---|---|---|---|---|
| | 1b | 2b | 3b | 4b | 5b | 6b | 7b | 8b |
| Li₂O | 8.9 | 8.35 | 8.9 | 8.6 | 9.1 | 9.15 | 9.1 | 9.2 |
| Na₂O | | 1.1 | 0.45 | 0.7 | 0.6 | 0.6 | 0.65 | |
| K₂O | | | 1.0 | 1.65 | 0.9 | 0.85 | 0.9 | |
| MgO | | | | | | | | |
| ZnO | | | | | 0.21 | | | |
| CaO | 2.5 | 1.1 | 1.25 | | 0.9 | 0.9 | 1.05 | 2.5 |
| BaO | | 0.85 | 1.05 | | 0.5 | 0.5 | 0.55 | |
| SrO | 0.6 | 0.8 | | | | | | 0.7 |
| Al₂O₃ | 17.2 | 17.4 | 16.95 | 16.35 | 18.1 | 18.1 | 18.05 | 18.7 |
| SiO₂ | 64,35 | 66.15 | 67.2 | 67.95 | 63.8 | 63.8 | 63.7 | 62.45 |
| P₂O₅ | 2.9 | 0.8 | | 1.5 | 2.65 | 2.65 | 2.7 | 3.1 |
| TiO₂ | 2.1 | 2.0 | 2.0 | 2.05 | 2.05 | 2.0 | 2.05 | 2.0 |
| ZrO₂ | 1.05 | 1.0 | 1.0 | 1.0 | 1.0 | 1.05 | 1.05 | 1.05 |
| SnO₂ | 0.2 | | | | | 0.2 | 0.2 | 0.2 |
| Cl | | 0.2 | | | | | | 0.1 |
| Sb₂O₃ | 0.2 | 0.25 | 0.2 | 0.2 | 0.2 | 0.2 | | |
| As₂O₃ | | | | | | | | |
| Total | 100.0 | 100.0 | 100.0 | 100.0 | 100.0 | 100.0 | 100.0 | 100.0 |
| SiO₂ + (5 × Li₂O) | 108.85 | 107.90 | 111.70 | 110.95 | 109.30 | 109.55 | 109.20 | 108.45 |
| MgO + ZnO | | | | | 0.21 | | | |
| ΣR₂O (R = Na, K, Cs, Rb) | | 1.1 | 1.45 | 2.35 | 1.5 | 1.45 | 1.55 | |
| ΣRO (R = Ca, Ba, Sr) | 3.1 | 2.75 | 2.30 | | 1.4 | 1.4 | 1.60 | 3.2 |
| Va [° C.] | 1258 | | | 1312 | | | | |
| Ceram. temperature [° C.] | 800 | 790 | 815 | 800 | 820 | 820 | 825 | 830 |
| Ceram. time [days] | 2.5 | 2.5 | 2.5 | 2.5 | 2.5 | 2.5 | 3 | 3.75 |
| Cryst. phase [vol %] | 64 | 52 | 53 | 52 | 57 | 58 | 58 | 67 |
| Cryst. size [nm] | 45 | 47 | 46 | 45 | 47 | 49 | 49 | 39 |
| Av. CTE(0; +50° C.) [ppm/K] | −0.08 | 0.02 | 0.10 | 0.07 | −0.04 | 0.00 | −0.002 | 0.04 |
| TCL (0; +50° C.) | 3.88 | 1.18 | 4.14 | 3.54 | 2.19 | 0.1 | 0.08 | 4.64 |
| \|expansion at 50° C.\| | 3.78 | 1.18 | 4.14 | 3.54 | 2.19 | 0.1 | 0.08 | 4.16 |
| Index F | 1.03 | 1.00 | 1.00 | 1.00 | 1.00 | 1.00 | 1.00 | 1.12 |
| Hyst @ 45° C. [ppm] | <0.1 | <0.1 | <0.1 | <0.1 | <0.1 | <0.1 | <0.1 | <0.1 |
| Hyst @ 35° C. [ppm] | <0.1 | <0.1 | <0.1 | <0.1 | <0.1 | <0.1 | <0.1 | <0.1 |
| Hyst @ 30° C. [ppm] | <0.1 | <0.1 | <0.1 | <0.1 | <0.1 | <0.1 | <0.1 | <0.1 |
| Hyst @ 22° C. [ppm] | <0.1 | <0.1 | <0.1 | <0.1 | <0.1 | <0.1 | <0.1 | <0.1 |
| Hyst @ 10° C. [ppm] | <0.1 | <0.1 | <0.1 | <0.1 | <0.1 | <0.1 | <0.1 | <0.1 |
| Hyst @ +5° C. [ppm] | 0.12 | <0.1 | <0.1 | <0.1 | <0.1 | <0.1 | <0.1 | 0.16 |
| Hyst @ 0° C. [ppm] | 0.2 | <0.1 | <0.1 | | <0.1 | <0.1 | <0.1 | 0.26 |
| Hyst @ −5° C. [ppm] | 0.3 | 0.15 | <0.1 | | <0.1 | <0.1 | <0.1 | 0.4 |
| Ceram. temperature [° C.] | 800 | 780 | 830 | 800 | 820 | 820 | 830 | 830 |
| Ceram. time [days] | 2.5 | 2.5 | 2.5 | 2.5 | 2.5 | 2.5 | 2.5 | 3.75 |
| Av. CTE (−30; +70° C.) [ppm/K] | −0.08 | −0.05 | 0.08 | 0.05 | −0.06 | −0.01 | −0.04 | 0.18 |
| Av. CTE (-40;+80° C.) [ppm/K] | −0.10 | −0.05 | 0.08 | n.b. | −0.07 | −0.02 | −0.05 | 0.18 |

| | Example No. (Ex.) | | | | | | |
|---|---|---|---|---|---|---|---|
| | 9b | 10b | 11b | 12b | 13b | 14b | 15b |
| Li₂O | 8.95 | 8.85 | 8.9 | 8.1 | 9.35 | 9.2 | 9.0 |
| Na₂O | 0.6 | 0.4 | 0.55 | 0.4 | 0.7 | 0.45 | 0.65 |
| K₂O | 0.8 | 0.9 | 0.8 | 1.0 | 0.25 | 0.6 | 0.7 |
| MgO | 0.17 | | 0.35 | | | | |
| ZnO | 0.13 | | 0.15 | | | | |
| CaO | 1.0 | 1.3 | 0.9 | 2.3 | 1.25 | 0.8 | 1.0 |
| BaO | 0.5 | 0.85 | 0.45 | | 1.1 | 0.8 | 1.55 |
| SrO | | | | | | | |
| Al₂O₃ | 18.1 | 18.05 | 17.9 | 15.5 | 16.8 | 16.8 | 18.1 |
| SiO₂ | 63.7 | 62.3 | 63.8 | 68.1 | 64.45 | 67.3 | 64.65 |
| P₂O₅ | 2.8 | 4.0 | 2.9 | 1.5 | 3.3 | | 2.15 |
| TiO₂ | 2.0 | 2.0 | 2.0 | 1.9 | | 3.85 | |
| ZrO₂ | 1.05 | 1.05 | 1.05 | 1.0 | 2.55 | | 1.6 |
| SnO₂ | 0.2 | 0.3 | | | | | 0.6 |
| Cl | | | | | | | |
| Sb₂O₃ | | | 0.25 | 0.2 | 0.25 | 0.2 | |
| As₂O₃ | 0.025 | | | | | | |
| Total | 100.0 | 100.0 | 100.0 | 100.0 | 100.0 | 100.0 | 100.0 |
| SiO₂ + (5 × Li₂O) | 108.45 | 106.55 | 108.30 | 108.60 | 111.20 | 113.30 | 109.65 |
| MgO + ZnO | 0.30 | | 0.50 | | | | |
| ΣR₂O (R = Na, K, Cs, Rb) | 1.4 | 1.3 | 1.35 | 1.4 | 0.95 | 1.05 | 1.35 |
| ΣRO (R = Ca, Ba, Sr) | 1.5 | 2.15 | 1.35 | 2.3 | 2.35 | 1.6 | 2.55 |
| Va [° C.] | | | | | | | |
| Ceram. temperature [° C.] | 830 | 800 | 830 | 780 | 800 | 815 | 840 |
| Ceram. time [days] | 2.5 | 2.5 | 2.5 | 2.5 | 2.5 | 2.5 | 2.5 |
| Cryst. phase [vol %] | 57 | 57 | 60 | 52 | | 64 | 52 |
| Cryst. size [nm] | 50 | 51 | 49 | 33 | | 33 | 61 |
| Av. CTE(0; +50° C.) [ppm/K] | −0.008 | 0.05 | 0.06 | 0.06 | 0.02 | −0.09 | −0.10 |
| TCL (0; +50° C.) | 0.4 | 2.61 | 3.2 | 3.19 | 1.02 | 4.55 | 5.04 |
| \|expansion at 50° C.\| | 0.4 | 2.61 | 3.2 | 3.19 | 1.02 | 4.55 | 5.04 |
| Index F | 1.00 | 1.00 | 1.00 | 1.00 | 1.00 | 1.00 | 1.00 |
| Hyst @ 45° C. [ppm] | <0.1 | <0.1 | <0.1 | <0.1 | <0.1 | <0.1 | <0.1 |
| Hyst @ 35° C. [ppm] | <0.1 | <0.1 | <0.1 | <0.1 | <0.1 | <0.1 | <0.1 |
| Hyst @ 30° C. [ppm] | <0.1 | <0.1 | <0.1 | <0.1 | <0.1 | <0.1 | <0.1 |
| Hyst @ 22° C. [ppm] | <0.1 | <0.1 | <0.1 | <0.1 | <0.1 | <0.1 | <0.1 |
| Hyst @ 10° C. [ppm] | <0.1 | <0.1 | <0.1 | <0.1 | <0.1 | <0.1 | <0.1 |
| Hyst @ +5° C. [ppm] | <0.1 | <0.1 | <0.1 | <0.1 | 0.13 | <0.1 | <0.1 |
| Hyst @ 0° C. [ppm] | <0.1 | <0.1 | 0.14 | 0.1 | 0.22 | | 0.13 |
| Hyst @ −5° C. [ppm] | 0.11 | 0.11 | 0.205 | 0.17 | 0.27 | | 0.18 |
| Ceram. temperature [° C.] | 830 | 830 | 830 | 780 | | 815 | |
| Ceram. time [days] | 2.5 | 2.5 | 2.5 | 2.5 | | 2.5 | |
| Av. CTE (−30; +70° C.) [ppm/K] | 0.01 | 0.05 | 0.05 | 0.05 | | −0.03 | |
| Av. CTE (-40;+80° C.) [ppm/K] | 0.00 | 0.04 | 0.04 | 0.04 | | −0.01 | |

TABLE 2
Compositions, ceramization and properties (mol %)

| | Comparative Example No. | | | |
|---|---|---|---|---|
| | (Comp. Ex.) | | | |
| | 1 | 2 | 5 | 6 |
| Li₂O | 8.1 | 9.15 | 9.45 | 9.5 |
| Na₂O | 0.4 | 0.4 | 0.2 | 0.1 |
| K₂O | 0.15 | 0.2 | 0.7 | 0.55 |
| MgO | | | | |
| ZnO | | | | |
| CaO | 4.15 | | 2.2 | 0.4 |
| BaO | | 0.6 | | 1.75 |
| SrO | | | | |
| Al₂O₃ | 12.45 | 14.2 | 16,75 | 16.6 |
| SiO₂ | 72.3 | 71.7 | 64.15 | 65.55 |
| P₂O₅ | | 0.62 | 3.3 | 2.2 |
| TiO₂ | 1.3 | 1.75 | 2.05 | 2.1 |
| ZrO₂ | 1.0 | 1.2 | 1.0 | 1.05 |
| As₂O₃ | 0.15 | 0.15 | 0.2 | 0.2 |
| Total | 100.0 | 100.0 | 100.0 | 100.0 |
| SiO₂ + (5 × Li₂O) | | | | |
| MgO + ZnO | | | | |
| ΣR₂O (R = Na, K, Cs, Rb) | 0.55 | 0.6 | 0.9 | 0.65 |
| ΣRO (R = Ca, Ba, Sr) | 4.15 | 0.6 | 2.2 | 2.15 |
| Va [° C.] | 1345 | 1340 | | |
| Ceram. temperature [° C.] | 760 | | 800 | 800 |
| Ceram. time [days] | 10 | | 2.5 | 2.5 |
| Cryst. phase [vol %] | 60 | | 66 | 58 |
| Cryst. size [nm] | 63 | | 45 | 47 |
| Av. CTE(0; +50° C.) [ppm/K] | −0.25 | | −0.27 | −0.46 |
| TCL (0; +50° C.) | | | | |
| \|expansion at 50° C.\| | | | | |
| Index F | | | | |
| Hyst @ 45° C. [ppm] | | | | |
| Hyst @ 35° C. [ppm] | | | | |
| Hyst @ 30° C. [ppm] | | | | |
| Hyst @ 22° C. [ppm] | <0.1 | | | |
| Hyst @ 10° C. [ppm] | <0.1 | | | |
| Hyst @ +5° C. [ppm] | <0.1 | | | |
| Hyst @ 0° C. [ppm] | 0.13 | | | |
| Hyst @ −5° C. [ppm] | 0.24 | | | |
| Ceram. temperature [° C.] | | | | |
| Ceram. time [days] | | | | |
| Av. CTE (−30; +70° C.)[ppm/K] | | | | |
| Av. CTE (−40; +80° C.)[ppm/K] | | | | |

| | Comparative Example No. | | | | | |
|---|---|---|---|---|---|---|
| | (Comp. Ex.) | | | | | |
| | 7 | 8 | 9 | 10 | 11 | 12 |
| Li₂O | 8.5 | 7.78 | 9.32 | 9.2 | 9.4 | 9.0 |
| Na₂O | 0.1 | 0.8 | | 0.1 | 0.2 | 0.1 |
| K₂O | 0.5 | | | | | |
| MgO | 1.8 | | 1.2 | 1.6 | 1.2 | 1.6 |
| ZnO | 1.3 | 1.8 | 0.4 | 0.6 | 0.6 | 0.4 |
| CaO | | 2.42 | 1.0 | 1.2 | 1.0 | 1.3 |
| BaO | | 1.07 | 0.36 | 0.4 | 0.3 | 0.5 |
| SrO | | | | | | |
| Al₂O₃ | 16.9 | 15.39 | 19.11 | 16.2 | 19.0 | 16.4 |
| SiO₂ | 64.3 | 65.42 | 61.4 | 63.3 | 61.4 | 63.9 |
| P₂O₅ | 3.4 | 2.47 | 3.97 | 3.8 | 3.9 | 3.5 |
| TiO₂ | 1.9 | 1.67 | 1.92 | 2.2 | 1.9 | 2.1 |
| ZrO₂ | 1.1 | 0.92 | 1.07 | 1.1 | 1.1 | 1.2 |
| As₂O₃ | 0.2 | 0.26 | 0.25 | 0.2 | 0.2 | 0.1 |
| Total | 100.0 | 100.0 | 100.0 | 100.0 | 100.0 | 100.1 |
| SiO₂ + (5 × Li₂O) | | | | | | |
| MgO + ZnO | 3.1 | 1.8 | 1.6 | 2.2 | 1.8 | 2.0 |
| ΣR₂O (R = Na, K, Cs, Rb) | 0.6 | 0.8 | | 0.1 | 0.2 | 0.1 |
| ΣRO (R = Ca, Ba, Sr) | | 3.49 | 1.36 | 1.6 | 1.3 | 1.8 |
| Va [° C.] | | | | | | |
| Ceram. temperature [° C.] | 810 | | | 760 | 810 | 760 |
| Ceram. time [days] | 10 | | | 10 | 5 | 10 |
| Cryst. phase [vol %] | 76 | | | | | |
| Cryst. size [nm] | 72 | | | | | |
| Av. CTE(0; +50° C.) [ppm/K] | 0.03 | 0.02 | 0.002 | −0.15 | 0.03 | −0.05 |
| TCL (0; +50° C.) | | | 1.19 | 3.68 | 1.32 | 0.35 |
| \|expansion at 50° C.\| | | | 0.11 | 3.68 | 1.28 | 0.35 |
| Index F | | | 10.82 | 1.00 | 1.03 | 1.00 |
| Hyst @ 45° C. [ppm] | 0.11 | <0.1 | <0.1 | <0.1 | <0.1 | <0.1 |
| Hyst @ 35° C. [ppm] | 0.14 | <0.1 | 0.12 | <0.1 | <0.1 | <0.1 |
| Hyst @ 30° C. [ppm] | 0.18 | <0.1 | 0.16 | <0.1 | 0.1 | 0.11 |
| Hyst @ 22° C. [ppm] | 0.27 | 0.14 | 0.24 | 0.14 | 0.16 | 0.17 |
| Hyst @ 10° C. [ppm] | 0.61 | 0.42 | 0.54 | 0.38 | 0.85 | 0.43 |
| Hyst @ +5° C. [ppm] | 0.85 | 0.61 | 0.74 | 0.56 | 0.61 | 0.61 |
| Hyst @ 0° C. [ppm] | 1.1 | 0.81 | 0.92 | 0.76 | 0.85 | 0.82 |
| Hyst @ −5° C. [ppm] | 1.2 | 0.96 | 1.16 | 0.93 | 1.04 | 0.97 |
| Ceram. temperature [° C.] | | | | | | |
| Ceram. time [days] | | | | | | |
| Av. CTE (−30; +70° C.)[ppm/K] | | | | | | |
| Av. CTE (−40; +80° C.)[ppm/K] | | | | | | |

| | Comparative Example No. | |
|---|---|---|
| | (Comp. Ex.) | |
| | 13 | 15 |
| Li₂O | 8.4 | 9.4 |
| Na₂O | 0.05 | 0.1 |
| K₂O | | 0.6 |
| MgO | | 1.8 |
| ZnO | 0.95 | |
| CaO | 2.3 | |
| BaO | | |
| SrO | | |
| Al₂O₃ | 16.55 | 17 |
| SiO₂ | 65.15 | 64.4 |
| P₂O₅ | 3.4 | 3.5 |
| TiO₂ | 2.0 | 1.95 |
| ZrO₂ | 1.1 | 1.05 |
| As₂O₃ | 0.15 | 0.2 |
| Total | 100.0 | 100.0 |
| SiO₂ + (5 × Li₂O) | | |
| MgO + ZnO | 0.95 | 1.8 |
| ΣR₂O (R = Na, K, Cs, Rb) | 0.05 | 0.7 |
| ΣRO (R = Ca, Ba, Sr) | 2.25 | |
| Va [° C.] | | |
| Ceram. temperature [° C.] | 770 | 790 |
| Ceram. time [days] | 5 | 5 |
| Cryst. phase [vol %] | 73 | 74 |
| Cryst. size [nm] | 43 | 56 |
| Av. CTE(0; +50° C.) [ppm/K] | −0.03 | −0.06 |
| TCL (0; +50° C.) | | |
| \|expansion at 50° C.\| | | |
| Index F | | |
| Hyst @ 45° C. [ppm] | <0.1 | <0.1 |
| Hyst @ 35° C. [ppm] | <0.1 | <0.1 |
| Hyst @ 30° C. [ppm] | <0.1 | <0.1 |
| Hyst @ 22° C. [ppm] | 0.13 | 0.16 |
| Hyst @ 10° C. [ppm] | 0.44 | 0.44 |
| Hyst @ +5° C. [ppm] | 0.67 | 0.63 |
| Hyst @ 0° C. [ppm] | 0.97 | 0.85 |
| Hyst @ −5° C. [ppm] | 1.3 | 1.0 |
| Ceram. temperature [° C.] | | |
| Ceram. time [days] | | |
| Av. CTE (−30; +70° C.)[ppm/K] | | |
| Av. CTE (−40; +80° C.)[ppm/K] | | |

TABLE 3a
Alternative index f_{T.i.} for selected
Ex. from Table 1a and Comp. Ex.

| f_{T.i.} | Ti-dop. | Ex. | Ex. | Ex. | Ex. | Ex. | Ex. |
|---|---|---|---|---|---|---|---|
| [ppm/K] | SiO₂ | 6 | 7 | 12 | 14 | 17 | 18 |
| 20-40° C. | 0.024 | 0.010 | 0.009 | | 0.014 | 0.012 | 0.016 |
| 20-70° C. | 0.039 | 0.011 | 0.010 | 0.023 | 0.038 | 0.014 | 0.022 |
| −10-30° C. | 0.015 | | 0.004 | 0.011 | 0.006 | | |

TABLE 3b
Alternative index f_{T.i}. for selected
Ex. from Table 1b and Comp. Ex.

| f_{T.i.} | Ti-dop. | | | |
|---|---|---|---|---|
| [ppm/K] | SiO₂ | Ex. 6b | Ex. 7b | Ex. 9b |
| 20-40° C. | 0.024 | 0.004 | 0.0015 | 0.007 |
| 20-70° C. | 0.039 | 0.0036 | 0.005 | 0.023 |
| −10-30° C. | 0.015 | 0.003 | 0.012 | |

### CTE Homogeneity

The components on which tests for determining the respective CTE homogeneity were carried out were produced by taking the measures for increasing CTE homogeneity which are stated in WO 2015/124710 A1.

In accordance with the compositions stated in connection with the glass-ceramics of example 7 in Table 1a and example 6b in Table 1b, the green glasses were first melted in a 28 m 3 melting tank over a period of several days, the temperature being kept at about 1600° C. The decomposition of As₂O₃ or Sb₂O₃ gives rise to refining gases which entrain small gaseous inclusions and homogenize the melt. During the refining phase and during a subsequent cooling phase, the glass melt is further homogenized. In particular, by controlling the temperature of the tank surface, convection of the melt is induced in order to promote homogenization. During a subsequent cooling phase, which may likewise last several days, the temperature of the glass melt is reduced to approximately 1400° C. and it is then poured into molds having an edge length of 1.7 m and a height of 500 mm.

Ceramization took place under the following conditions:

First, the respective green glass block (or blank) was heated to a temperature between 630 and 680° C. at a heating rate of 0.5° C./h. The heating rate was then reduced to 0.01° C./h and heating was continued until a temperature between 770 to 830° C. was reached. This temperature was maintained for around 60 hours. The blanks were then cooled to room temperature at a cooling rate of −1° C./h.

After removal of the edge regions, blocks in the following dimensions were cut from the glass-ceramics produced in this way:
500×500×100 mm
700×700×200 mm
1400×1400×300 mm

The CTE homogeneity of the ceramized blocks obtained was determined as described below.

To determine the CTE homogeneity(0:50) and the CTE homogeneity(19:25) in the components, 64 samples were in each case cut from the respective glass-ceramic component, these being measured separately. The CTE(0;50) was determined for each of the 64 samples of a component and the CTE(19;25) was determined for a further 64 samples. The thermal expansion of a sample taken was determined by a static method in which the length of the respective sample was determined at the start and at the end of the specific temperature interval, i.e., from 0° C. to 50° C. or from 19° C. to 25° C., and the average expansion coefficient α or CTE was calculated from the difference in length. The CTE is then reported as the average for this temperature interval, e.g., for the temperature interval from 0° C. to 50° C. as CTE(0;50) or α(0;50) or for the temperature interval from 19° C. to 25° C. as CTE(19;25). Subsequently, the difference between the highest and lowest CTE(0;50) or the highest and the lowest CTE(19;25) was ascertained (peak-to-valley value). The lower this difference is (e.g., 3 ppb), the lower the CTE variance within the components investigated and the higher the CTE homogeneity.

The CTE homogeneities determined for the temperature ranges from 0 to 50° C. and 19 to 25° C. are summarized in Tables 4a and 4b.

TABLE 4a

| | Example 7-1 | | Example 7-2 | | Example 7-3 | |
|---|---|---|---|---|---|---|
| Dimensions of glass- | (500 × | | (700 × | | (1400 × | |
| ceramic component | 500 × | | 700 × | | 1400 × | |
| (Width × Depth × | 100) mm | | 200) mm | | 300) mm | |
| Height) | | | | | | |
| Modulus of elasticity | 90 | GPa | 90 | GPa | 90 | GPa |
| Average CTE(0; 50) | 0.007 | | 0.007 | | 0.007 | |
| [ppm/K] | | | | | | |
| CTE homogeneity(0; 50) | 3 | ppb/K | 4 | ppb/K | 5 | ppb/K |
| Average CTE (19; 25) | −0.002 | | −0.002 | | −0.002 | |
| [ppm/K] | | | | | | |
| CTE | 2.5 | ppb/K | 3 | ppb/K | 4 | ppb/K |
| homogeneity(19; 25) | | | | | | |
| Inclusions > 0.3 mm | | | | | | |
| Average number per | 1 | | 1 | | 3 | |
| 100 cm³ | | | | | | |

| | | | |
|---|---|---|---|
| Maximum size [mm] | 0.4 | 0.4 | 1.5 |

TABLE 4b

| | Example 6b-1 | | Example 6b-2 | | Example 6b-3 | |
|---|---|---|---|---|---|---|
| Dimensions of glass- | (500 × | | (700 × | | (1400 × | |
| ceramic component | 500 × | | 700 × | | 1400 × | |
| (Width × Depth × | 100) mm | | 200) mm | | 300) mm | |
| Height) | | | | | | |
| Modulus of elasticity | 90 | GPa | 90 | GPa | 90 | GPa |
| Average CTE (0; 50) | 0.000 | | 0.000 | | 0.000 | |
| [ppm/K] | | | | | | |
| CTE | 3 | ppb/K | 4 | ppb/K | 5 | ppb/K |
| homogeneity(0; 50) | | | | | | |
| Average CTE (19; 25) | 0.001 | | 0.001 | | 0.001 | |
| [ppm/K] | | | | | | |
| CTE | 2.5 | ppb/K | 3 | ppb/K | 4.5 | ppb/K |
| homogeneity(19; 25) | | | | | | |
| Inclusions > 0.3 mm | | | | | | |
| Average number per | 1 | | 1 | | 3 | |
| 100 cm³ | | | | | | |

| | | | |
|---|---|---|---|
| Maximum size [mm] | 0.4 | 0.4 | 1.5 |

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A precision extreme ultraviolet lithography (EUVL) component having an average coefficient of thermal expansion (CTE) in a range from 0 to 50° C. of at most 0±0.1×10⁻⁶/K, and a thermal hysteresis of <0.1 ppm at least in the temperature range from 19 to 25° C., and an index F of <1.2, wherein F=TCL (0; 50° C.)/|expansion (0; 50° C.)|, wherein TCL is a total change of length.

2. The precision EUVL component of claim 1, wherein a CTE-T curve in a temperature interval having a width of at least 30 K has a slope of at most 0±2.5 ppb/K².

3. The precision EUVL component of claim 1, wherein a differential CTE in a temperature interval T_{P} having a width of at least 40 K is less than 0±0.025 ppm/K.

4. The precision EUVL component of claim 1, having a CTE homogeneity(0;50) of at most 5 ppb/K and/or a CTE homogeneity(19;25) of at most 5 ppb/K.

5. The precision EUVL of claim 1, having a thermal hysteresis of <0.1 ppm at least in a temperature range from 5° C. to 45° C.

6. The precision EUVL component of claim 1, having a relative change in length (dl/l₀) of ≤|0.10| ppm in a temperature range from 20° C. to 30° C. and/or a relative change in length (dl/l₀) of ≤|0.17| ppm in a temperature range from 20° C. to 35° C.

7. The precision EUVL component of claim 1, having a relative change in length (dl/l₀) of ≤|0.30| ppm in a temperature range from 20° C. to 40° C.

8. The precision EUVL component of claim 1, comprising at least one inorganic material selected from the group consisting of doped quartz glass, glass-ceramic, ceramic, Ti-doped quartz glass, lithium aluminum silicate glass-ceramic, and cordierite.

9. The precision EUVL component of claim 1, wherein the precision EUVL component is selected from the group consisting of a photomask, a reticle, a photomask substrate, a reticle mask blank, a mask blank, a photomask carrier, a reticle stage, a mirror, a minor carrier, a wafer carrier, and a wafer stage.

10. A precision extreme ultraviolet lithography (EUVL) component having an average coefficient of thermal expansion (CTE) in a range from 0 to 50° C. of at most 0±0.1×10⁻⁶/K and a thermal hysteresis of <0.1 ppm at least in a temperature range from 19 to 25° C., and an alternative index f_{T.i.} selected from the group consisting of alternative index f_{(20;40)}<0.024 ppm/K, alternative index f_{(20;70)}<0.039 ppm/K, and alternative index f_{(-10;30)}<0.015 ppm/K.

11. The precision EUVL component of claim 10, wherein a CTE-T curve in a temperature interval having a width of at least 30 K has a slope of at most 0±2.5 ppb/K².

12. The precision EUVL component of claim 10, wherein a differential CTE in a temperature interval TP having a width of at least 40 K is less than 0±0.025 ppm/K.

13. The precision EUVL component of claim 10, having a CTE homogeneity(0;50) of at most 5 ppb/K and/or a CTE homogeneity(19;25) of at most 5 ppb/K.

14. The precision EUVL of claim 10, having a thermal hysteresis of <0.1 ppm at least in a temperature range from 5° C. to 45° C.

15. The precision EUVL component of claim 10, having a relative change in length (dl/l₀) of ≤|0.10| ppm in a temperature range from 20° C. to 30° C. and/or a relative change in length (dl/l₀) of ≤|0.17| ppm in a temperature range from 20° C. to 35° C.

16. The precision EUVL component of claim 10, having a relative change in length (dl/l₀) of ≤|0.30| ppm in a temperature range from 20° C. to 40° C.

17. The precision EUVL component of claim 10, comprising at least one inorganic material selected from the group consisting of doped quartz glass, glass-ceramic, ceramic, Ti-doped quartz glass, lithium aluminum silicate glass-ceramic, and cordierite.

18. The precision EUVL component of claim 10, wherein the precision EUVL component is selected from the group consisting of a photomask, a reticle, a photomask substrate, a reticle mask blank, a mask blank, a photomask carrier, a reticle stage, a mirror, a mirror carrier, a wafer carrier, and a wafer stage.
